(19) United States
(12) Patent Application Publication
(10) Pub. No.: US 2024/0324212 A1
(43) Pub. Date: Sep. 26, 2024

(54) SEMICONDUCTOR STORAGE DEVICE AND METHOD FOR MANUFACTURING SEMICONDUCTOR STORAGE DEVICE

(71) Applicant: Kioxia Corporation, Tokyo (JP)

(72) Inventor: Katsuyuki KITAMOTO, Yokkaichi Mie (JP)

(73) Assignee: Kioxia Corporation, Tokyo (JP)

(21) Appl. No.: 18/593,097

(22) Filed: Mar. 1, 2024

(30) Foreign Application Priority Data
Mar. 20, 2023 (JP) 2023-043809

(51) Int. Cl. H10B 43/27; H10B 41/10; H10B 41/27; H10B 41/40; H10B 43/10; H10B 43/40

(52) U.S. Cl. CPC H10B 43/27; H10B 41/10; H10B 41/27; H10B 41/40; H10B 43/10; H10B 43/40

(57) ABSTRACT

A semiconductor storage device includes: a stacked body that has a plurality of conductive layers and a plurality of first insulating layers stacked alternately and includes a first region and a second region; one or more first pillars extending in a stacking direction of the stacked body within the first region of the stacked body; and a second pillar extending in the stacking direction within the second region of the stacked body, in which each of the first and second pillars include a semiconductor layer, a second insulating layer, a third insulating layer, and a fourth insulating layer interposed between the second and third insulating layers, the second insulating layer covers a sidewall of the semiconductor layer, the fourth insulating layer covers a sidewall of the second insulating layer and contains a different material from the second and third insulating layers, the third insulating layer covers a sidewall of the fourth insulating layer, an intersection of at least one of the plurality of conductive layers and the first pillar functions as a memory cell, and the third insulating layer of the second pillar is thicker than the third insulating layer of the first pillar in a plane perpendicular to the stacking direction.

### CROSS-REFERENCE TO RELATED APPLICATION(S)

This application is based upon and claims the benefit of priority from Japanese Patent Application No. 2023-043809, filed Mar. 20, 2023, the entire contents of which are incorporated herein by reference.

### FIELD

Embodiments described herein relate generally to semiconductor storage devices and methods for manufacturing semiconductor storage devices.

### BACKGROUND

In semiconductor storage devices such as three-dimensional nonvolatile memories, memory cells are three-dimensionally formed in a stacked body in which a plurality of conductive layers are stacked. To lead out the conductive layers, a plurality of contacts are respectively connected to portions where the plurality of conductive layers are processed in a stepped shape. A plurality of dummy pillars that support the stacked body are located in the stacked body. When contact occurs between the contacts and the pillars, in some cases, formation defects of a contact may occur.

### DESCRIPTION OF THE DRAWINGS

FIG. 1 is a block diagram of a semiconductor storage device according to at least one embodiment;

FIG. 2 is an equivalent circuit diagram illustrating a configuration example of a memory cell array provided in the semiconductor storage device according to at least one embodiment;

FIG. 3 is a cross-sectional view illustrating a schematic configuration example of a semiconductor storage device according to a first embodiment;

FIGS. 4A to 4E are diagrams illustrating a configuration example of the semiconductor storage device according to the first embodiment;

FIGS. 5A to 5C are diagrams illustrating a configuration example of the semiconductor storage device according to the first embodiment;

FIGS. 6A to 6E are diagrams sequentially illustrating a portion of a procedure of a method for manufacturing the semiconductor storage device according to the first embodiment;

FIGS. 7A to 7C are diagrams sequentially illustrating a portion of the procedure of the method for manufacturing the semiconductor storage device according to the first embodiment;

FIGS. 8A and 8B are diagrams sequentially illustrating a portion of the procedure of the method for manufacturing the semiconductor storage device according to the first embodiment;

FIGS. 9A to 9D are diagrams sequentially illustrating a portion of the procedure of the method for manufacturing the semiconductor storage device according to the first embodiment;

FIGS. 10A to 10C are diagrams sequentially illustrating a portion of the procedure of the method for manufacturing the semiconductor storage device according to the first embodiment;

FIGS. 11A to 11D are diagrams sequentially illustrating a portion of the procedure of the method for manufacturing the semiconductor storage device according to the first embodiment;

FIGS. 12A to 12D are diagrams sequentially illustrating a portion of the procedure of the method for manufacturing the semiconductor storage device according to the first embodiment;

FIGS. 13A to 13Ed are diagrams sequentially illustrating a portion of the procedure of the method for manufacturing the semiconductor storage device according to the first embodiment;

FIGS. 14A to 14C are diagrams sequentially illustrating a portion of the procedure of the method for manufacturing the semiconductor storage device according to the first embodiment;

FIGS. 15A to 15D are diagrams sequentially illustrating a portion of the procedure of the method for manufacturing the semiconductor storage device according to the first embodiment;

FIGS. 16A to 16C are diagrams sequentially illustrating a portion of the procedure of the method for manufacturing the semiconductor storage device according to the first embodiment;

FIGS. 17A to 17D are cross-sectional views illustrating an example where a contact hole being in contact with a columnar portion is formed according to the first embodiment and Comparative Example;

FIG. 18 is an XY cross-sectional view illustrating a configuration example of a semiconductor storage device according to Modified Example 1 of the first embodiment;

FIG. 19 is an XY cross-sectional view illustrating another configuration example of the semiconductor storage device according to Modified Example 1 of the first embodiment;

FIG. 20 is an XY cross-sectional view illustrating a configuration example of a semiconductor storage device according to Modified Example 2 of the first embodiment;

FIGS. 21A to 21F are cross-sectional views illustrating an example where a slit that is in contact with a columnar portion is formed according to Modified Example 2 of the first embodiment and Comparative Example;

FIGS. 22A to 22D are diagrams sequentially illustrating a portion of a procedure of a method for manufacturing a semiconductor storage device according to Modified Example 3 of the first embodiment;

FIGS. 23A to 23D are diagrams sequentially illustrating a portion of the procedure of the method for manufacturing the semiconductor storage device according to Modified Example 3 of the first embodiment;

FIGS. 24A to 24Ed are diagrams sequentially illustrating a portion of the procedure of the method for manufacturing the semiconductor storage device according to Modified Example 3 of the first embodiment;

FIGS. 25A to 25E are diagrams illustrating a configuration example of a semiconductor storage device according to a second embodiment;

FIGS. 26A to 26D are diagrams sequentially illustrating a portion of a procedure of a method for manufacturing the semiconductor storage device according to the second embodiment;

FIGS. 27A to 27D are diagrams sequentially illustrating a portion of the procedure of the method for manufacturing the semiconductor storage device according to the second embodiment;

FIGS. 28A to 28D are diagrams sequentially illustrating a portion of the procedure of the method for manufacturing the semiconductor storage device according to the second embodiment;

FIGS. 29A to 29Ed are diagrams sequentially illustrating a portion of the procedure of the method for manufacturing the semiconductor storage device according to the second embodiment;

FIGS. 30A to 30C are diagrams illustrating a configuration example of a semiconductor storage device according to a third embodiment;

FIGS. 31Aa to 31C are diagrams illustrating a configuration example of the semiconductor storage device according to the third embodiment;

FIGS. 32A to 32D are diagrams sequentially illustrating a portion of a procedure of a method for manufacturing the semiconductor storage device according to the third embodiment;

FIGS. 33A to 33Cg are diagrams sequentially illustrating a portion of the procedure of the method for manufacturing the semiconductor storage device according to the third embodiment;

FIGS. 34Ab to 34Bg are diagrams sequentially illustrating a portion of the procedure of the method for manufacturing the semiconductor storage device according to the third embodiment;

FIGS. 35Ab to 35Bg are diagrams sequentially illustrating a portion of the procedure of the method for manufacturing the semiconductor storage device according to the third embodiment; and

FIG. 36 is a cross-sectional view illustrating a schematic configuration example of a semiconductor storage device according to another embodiment.

### DETAILED DESCRIPTION

At least one embodiment provides a semiconductor storage device and a method for manufacturing the semiconductor storage device capable of preventing formation defects of a contact due to contact between the contact and the pillar.

In general, according to at least one embodiment, there is provided a semiconductor storage device including: a stacked body that a plurality of conductive layers and a plurality of first insulating layers stacked alternately and includes a first region and a second region; one or more first pillars extending in a stacking direction of the stacked body within the first region of the stacked body; and a second pillar extending in the stacking direction within the second region of the stacked body, in which each of the first and second pillars include a semiconductor layer, a second insulating layer, a third insulating layer, and a fourth insulating layer interposed between the second and third insulating layers, the second insulating layer covers a sidewall of the semiconductor layer, the fourth insulating layer covers a sidewall of the second insulating layer and contains a different material from the second and third insulating layers, the third insulating layer covers a sidewall of the fourth insulating layer, an intersection of at least one of the plurality of conductive layers and the first pillar functions as a memory cell, and the third insulating layer of the second pillar is thicker than the third insulating layer of the first pillar in a plane perpendicular to the stacking direction.

Embodiments of the present disclosure will be described in detail below with reference to the drawings. It should be noted that the present disclosure is not limited to embodiments described below. Components in the embodiments described below include those that can be easily imagined by those skilled in the art or those that are substantially the same.

### EMBODIMENT

Hereinafter, configurations common to all embodiments of the specification will be described with reference to the drawings.

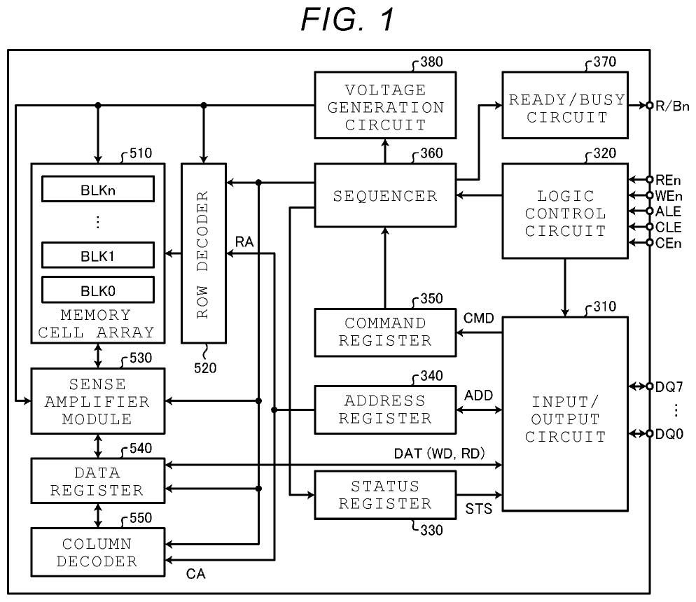

FIG. 1 is a block diagram of a semiconductor storage device according to an embodiment. As illustrated in FIG. 1, the semiconductor storage device includes an input/output circuit 310, a logic control circuit 320, a status register 330, an address register 340, a command register 350, a sequencer 360, a ready/busy circuit 370, a voltage generation circuit 380, a memory cell array 510, a row decoder 520, a sense amplifier module 530, a data register 540, and a column decoder 550.

The input/output circuit 310 controls input and output of a signal DQ to and from an external device such as a memory controller (not illustrated) controlling the semiconductor storage device. The input/output circuit 310 includes an input circuit and an output circuit (not illustrated).

The input circuit transmits data DAT such as write data WD received from the external device to the data register 540, transmits an address ADD to the address register 340, and transmits a command CMD to the command register 350.

The output circuit transmits status information STS received from the status register 330, the data DAT such as read data RD received from the data register 540, and the address from the address register 340 to the external device.

The logic control circuit 320 receives, for example, a chip enable signal CEn, a command latch enable signal CLE, an address latch enable signal ALE, a write enable signal WEn, and a read enable signal REn from the external device. The logic control circuit 320 controls the input/output circuit 310 and the sequencer 360 according to the received signal.

The status register 330 temporarily stores the status information STS in, for example, a write operation, a read operation, and an erasing operation of data and notifies the external device whether the operation ended normally.

The address register 340 temporarily stores the address ADD received from the external device via the input/output circuit 310. The address register 340 transfers a row address RA to the row decoder 520 and a column address CA to the column decoder 550.

The command register 350 temporarily stores the command CMD received from the external device via the input/output circuit 310 and transfers the command CMD to the sequencer 360.

The sequencer 360 controls operations of the entire semiconductor storage device. More specifically, the sequencer 360 controls, for example, the status register 330, the ready/busy circuit 370, the voltage generation circuit 380, the row decoder 520, the sense amplifier module 530, the data register 540, the column decoder 550, and the like, and executes the write operation, the read operation, the erasing operation, and the like according to the command CMD held by the command register 350.

The ready/busy circuit 370 transmits a ready/busy signal R/Bn to the external device according to an operating status of the sequencer 360.

The voltage generation circuit 380 generates voltages necessary for the write operation, the read operation, and the erasing operation under the control of the sequencer 360, and supplies the generated voltages to, for example, the memory cell array 510, the row decoder 520, the sense amplifier module 530, and the like. The row decoder 520 and the sense amplifier module 530 apply the voltage supplied from the voltage generation circuit 380 to memory cells in the memory cell array 510.

The memory cell array 510 includes a plurality of blocks BLK (BLK0 to BLKn). n is an integer of 2 or more. The block BLK is a set of a plurality of memory cells associated with bit lines and word lines, and is, for example, a data erase unit. The memory cell is configured as a transistor, for example, and stores nonvolatile data.

By including such memory cells, the semiconductor storage device of the embodiment is configured as, for example, a NAND type nonvolatile memory.

The row decoder 520 decodes the row address RA. The row decoder 520 selects one of the blocks BLK based on a decoding result. The row decoder 520 applies the necessary voltage to the block BLK.

The sense amplifier module 530 senses data read from the memory cell array 510 during the read operation. The sense amplifier module 530 also transmits the read data RD to the data register 540. During the write operation, the sense amplifier module 530 transmits the write data WD to the memory cell array 510.

The data register 540 includes a plurality of latch circuits. The latch circuit stores the write data WD and the read data RD. For example, in the write operation, the data register 540 temporarily stores the write data WD received from the input/output circuit 310 and transmits the write data WD to the sense amplifier module 530. For example, in the read operation, the data register 540 temporarily stores the read data RD received from the sense amplifier module 530 and transmits the read data RD to the input/output circuit 310.

The column decoder 550 decodes the column address CA during the write operation, the read operation, and the erasing operation, for example, and selects the latch circuit in the data register 540 according to the decoding result.

It should be noted that the group of circuits located around the memory cell array 510 is also referred to as a peripheral circuit. The peripheral circuit includes at least the row decoder 520, the sense amplifier module 530, the data register 540, and the column decoder 550. The peripheral circuit may include the status register 330, the address register 340, the command register 350, and the sequencer 360, and may further include the input/output circuit 310, the logic control circuit 320, the ready/busy circuit 370, and the voltage generation circuit 380.

As described above, the semiconductor storage device of the embodiment includes the memory cell array 510 including the plurality of memory cells and the peripheral circuit operating the plurality of memory cells.

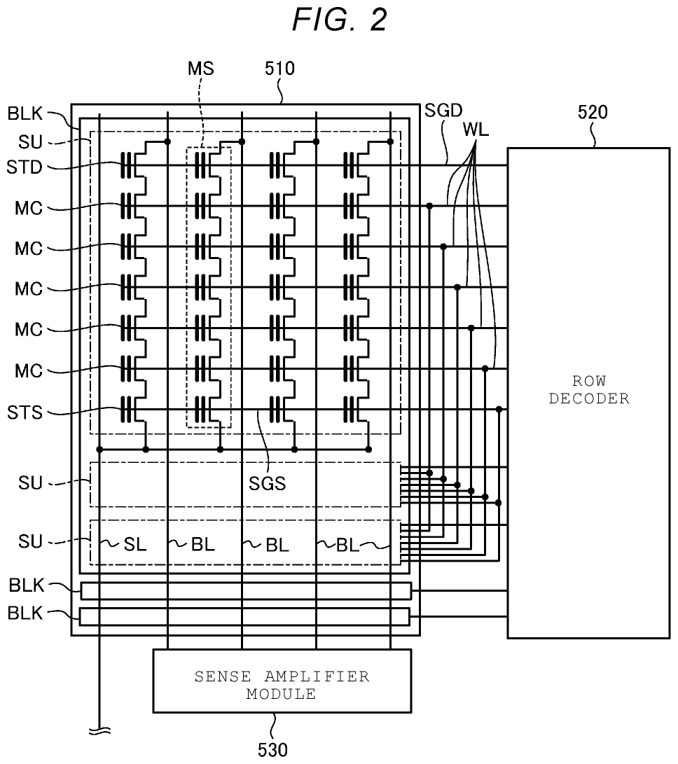

FIG. 2 is an equivalent circuit diagram illustrating a configuration example of the memory cell array 510 provided in the semiconductor storage device according to the embodiment.

The memory cell array 510 includes the plurality of blocks BLK as described above. Each of the plurality of blocks BLK includes a plurality of string units SU. Each of the plurality of string units SU includes a plurality of memory strings MS. One end of each of the plurality of memory strings MS is connected to the peripheral circuit such as the sense amplifier module 530 via the bit line BL. The other end of each of the plurality of memory strings MS is connected to the peripheral circuit via a common source line SL.

The memory string MS includes a drain select transistor STD connected in series between the bit line BL and the source line SL, a plurality of memory cells MC, and a source select transistor STS. Hereinafter, the drain select transistor STD and the source select transistor STS may be simply referred to as select transistors (STD, STS).

The memory cell MC is, for example, a field effect transistor (FET) including a charge storage layer in a gate insulating layer. The threshold voltage of the memory cell MC changes according to the amount of charges in the charge storage layer. By providing one or more threshold voltages, the memory cell MC may be able to store one or more bits of data. A word line WL is connected to each gate electrode of the plurality of memory cells MC corresponding to one memory string MS. The word lines WL are commonly connected to all memory strings MS in one block BLK.

The select transistor (STD, STS) is, for example, the field effect transistor. Select gate lines (SGD, SGS) are connected to the gate electrodes of the select transistors (STD, STS), respectively. A drain selection line SGD connected to the drain select transistor STD is provided corresponding to the string unit SU, and is commonly connected to all memory strings MS in one string unit SU. A source selection line SGS connected to the source select transistor STS is commonly connected to all memory strings MS in one block BLK.

One end of each of the word line WL and the select gate lines (SGD, SGS) is connected to the peripheral circuit such as the row decoder 520.

### First Embodiment

A first embodiment will be described in detail below with reference to the drawings.

### (Configuration Example of Semiconductor Storage Device)

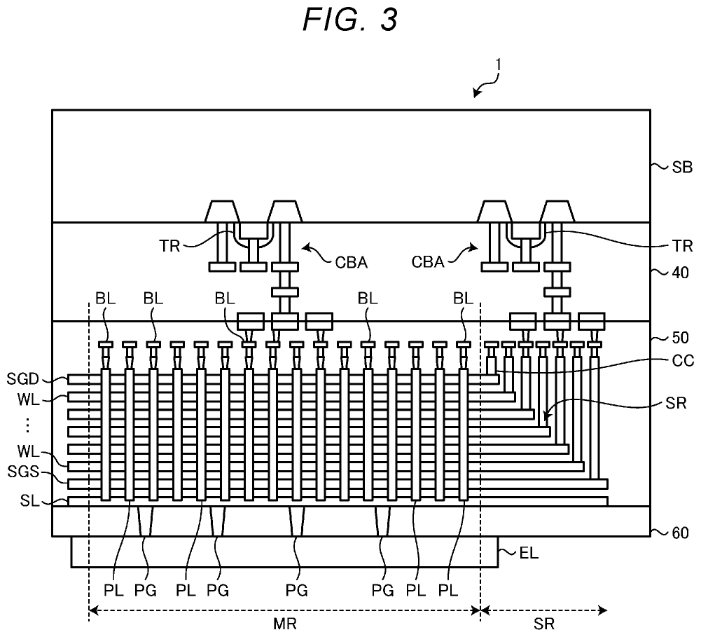

FIG. 3 is a cross-sectional view illustrating a schematic configuration example of a semiconductor storage device 1 according to the first embodiment. However, in FIG. 3, hatching is omitted considering the ease of viewing the drawings.

As illustrated in FIG. 3, the semiconductor storage device 1 includes an electrode film EL, a source line SL, a plurality of word lines WL, and select gate lines SGD and SGS in this order from the bottom of the paper. The semiconductor storage device 1 includes a peripheral circuit CBA provided on a semiconductor substrate SB above the select gate line SGD.

The source line SL is disposed on the electrode film EL while interposing an insulating layer 50 therebetween. A plurality of plugs PG are located in the insulating layer 50, and electrical connection is maintained between the source line SL and the electrode film EL via the plugs PG. Accordingly, a source voltage can be applied from the voltage generation circuit 380 (refer to FIG. 1) to the source line SL via the electrode film EL and the plug PG.

One or more select gate lines SGS, the plurality of word lines WL, and one or more select gate lines SGD are stacked in this order on the source line SL. A memory region MR is disposed at the center in the direction in which the plurality of word lines WL extend, and a stepped region SR is disposed at the end in the direction in which the plurality of word lines WL extends.

In the memory region MR, a plurality of pillars PL penetrating the word lines WL and the like in the stacking direction are located. The plurality of memory cells MC (refer to FIG. 2) are formed at an intersection of the pillar PL and the word line WL. Accordingly, the semiconductor storage device 1 is configured as a three-dimensional nonvolatile memory in which the memory cells MC are three-dimensionally located in, for example, the memory region MR.

As such, the memory region MR is an example of a physical configuration corresponding to the above-described memory cell array 510 (refer to FIG. 2). The pillar PL is an example of a physical configuration corresponding to the above-described memory string MS (refer to FIG. 2) in which the memory cells MC and the like are connected in series.

In a physical configuration of the semiconductor storage device 1, the pillar PL is electrically connected to the peripheral circuit CBA via the bit line BL disposed above the pillar PL.

In the stepped region SR, the plurality of word lines WL and the select gate lines SGD and SGS are processed into a stepped shape and terminated. Contacts CC connected to the word lines WL and the like of each level are located in a terrace portion of each step formed by the word lines WL and the like.

The word lines WL and the select gate lines SGD and SGS stacked in the plurality of layers are individually led out by the contacts CC. From the contacts CC, the write voltage, the read voltage, and the like are applied to the memory cell MC provided in the memory region MR in the center of the plurality of word lines WL via the word line WL at the same height position as the memory cell MC.

The plurality of word lines WL, the select gate lines SGD and SGS, the pillars PL, and the contacts CC are covered with the insulating layer 50. The insulating layer 50 also extends around the plurality of word lines WL and the like.

The semiconductor substrate SB above the insulating layer 50 is, for example, a silicon substrate. On the surface of the semiconductor substrate SB, the peripheral circuit CBA such as the above-described row decoder 520 and the sense amplifier module 530 (refer to FIG. 1) including transistors TR and wirings is located.

Various voltages applied to the memory cells MC from the contacts CC are controlled by the peripheral circuit CBA electrically connected to the contacts CC. Data read from the memory cells MC located in the height direction of the pillar PL is read to the sense amplifier module 530 of the peripheral circuit CBA. Accordingly, the peripheral circuit CBA controls electrical operations of the memory cell MC.

The peripheral circuit CBA is covered with an insulating layer 40, and the semiconductor storage device 1 includes configurations such as the plurality of word lines WL, the pillars PL, and the contacts CC, and the peripheral circuit CBA, by bonding the insulating layer 40 to the insulating layer 50 covering the plurality of word lines WL, and the like.

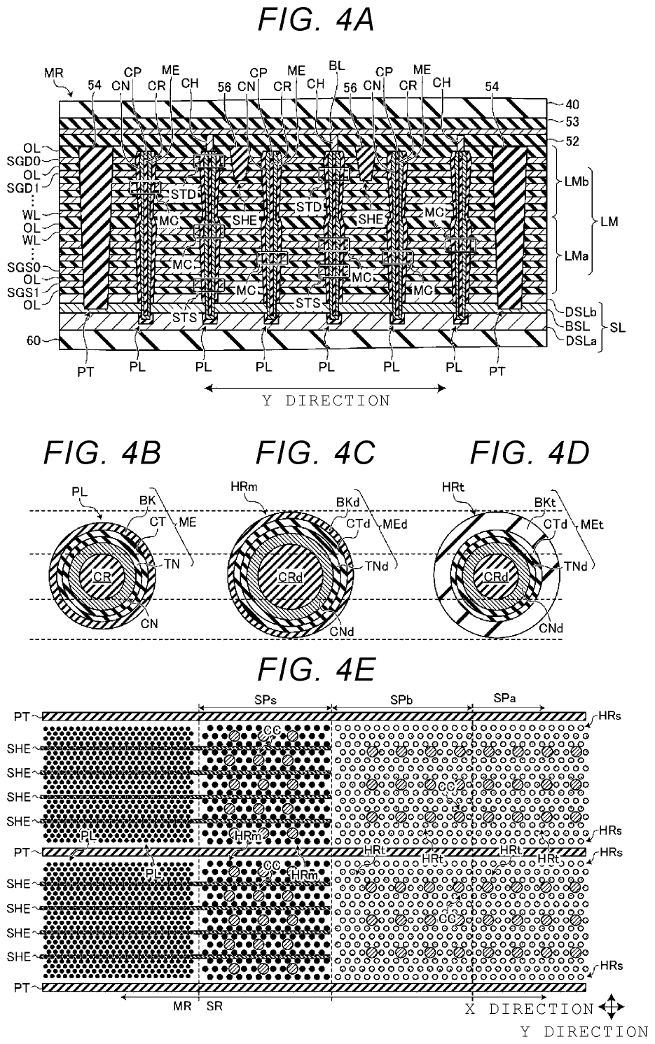

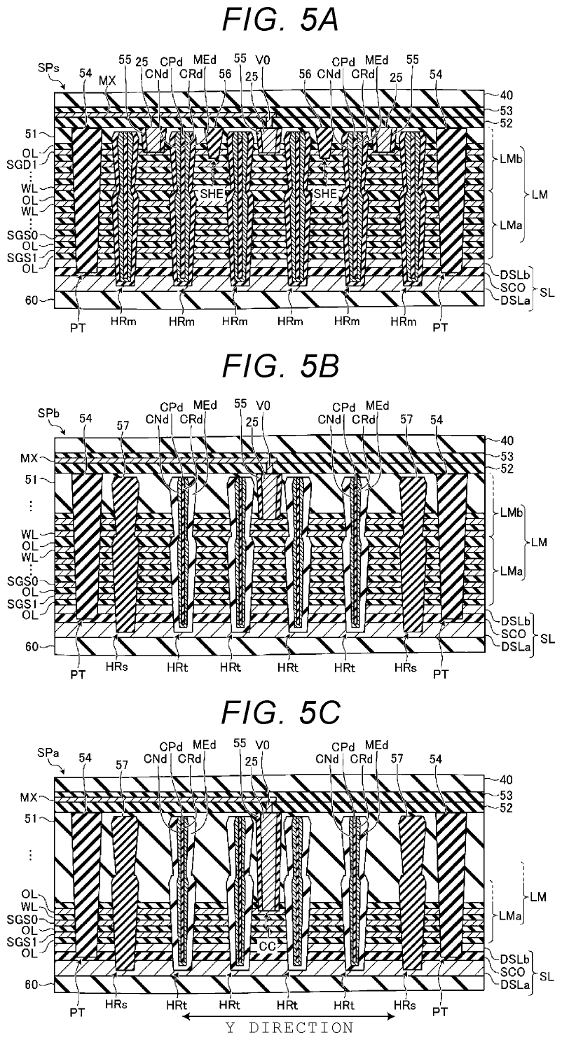

Next, a detailed configuration example of the semiconductor storage device 1 will be described with reference to FIGS. 4A to 5C. FIGS. 4A to 5C are diagrams illustrating a configuration example of the semiconductor storage device 1 according to the first embodiment.

More specifically, FIG. 4A is a cross-sectional view along a Y direction including the memory region MR of the semiconductor storage device 1. In FIG. 4A, the structure below an insulating layer 60 and above the insulating layer 40 is omitted.

FIG. 4B is an XY cross-sectional view of a pillar PL at the height position of a freely selected word line WL. FIG. 4C is an XY cross-sectional view of a columnar portion HRm at the same height position as the cross section illustrated in FIG. 4B. FIG. 4D is an XY cross-sectional view of a columnar portion HRt at the same height position as the cross section illustrated in FIGS. 4B and 4C.

FIG. 4E is an XY cross-sectional view of a partial region of a stacked body LM at the height of the select gate line SGD.

FIGS. 5A to 5C are cross-sectional views along the Y direction including the stepped region SR of the semiconductor storage device 1. FIG. 5A illustrates a cross section at a stepped portion SPs provided in the stepped region SR. FIG. 5B illustrates a cross section at a stepped portion SPb provided in the stepped region SR. FIG. 5C illustrates a cross section at a stepped portion SPa provided in the stepped region SR. It should be noted that, in FIGS. 5A to 5C, the structures below the insulating layer 60 and above the insulating layer 40 are omitted.

It should be noted that the diagrams illustrated in FIGS. 4A to 5C are only schematic diagrams, and the number and layout of each configuration illustrated in the cross-sectional views in FIGS. 4A and 5A to 5C, and the XY cross-sectional view in FIG. 4E do not necessarily match.

In the specification, both an X direction and a Y direction are directions along a plane of the word line WL, and the X direction and the Y direction are orthogonal to each other. The electrical lead-out direction of the word line WL may be referred to as a first direction, and the first direction is a direction along the X direction. The direction intersecting the first direction may be referred to as a second direction, and the second direction is a direction along the Y direction. However, since the semiconductor storage device 1 may include manufacturing errors, the first direction and the second direction are not necessarily orthogonal to each other.

In the specification, the direction in which the terrace surfaces of the word lines WL at each step in the stepped region SR face is defined as an upward direction.

As illustrated in FIG. 4A, the source line SL has a multilayer structure in which, for example, a lower source line DSLa, an intermediate source line BSL, and an upper source line DSLb are stacked in this order on the insulating layer 60. It should be noted that the intermediate source line BSL is located below the memory region MR of the stacked body LM.

The lower source line DSLa, the intermediate source line BSL, and the upper source line DSLb are, for example, polysilicon layers. Among the polysilicon layers, at least the intermediate source line BSL may be a conductive polysilicon layer or the like in which impurities are diffused.

The stacked body LM is disposed on the source line SL. The stacked body LM includes stacked bodies LMa and LMb in which the plurality of word lines WL and a plurality of insulating layers OL are alternately stacked one layer by one layer.

The stacked body LMa as a first stacked body is disposed above the source line SL. Plurality of select gate lines SGS0 and SGS1 are located in this order from the upper layer side of the stacked body LMa, further below the lowermost word line WL of the stacked body LMa, while interposing the insulating layer OL therebetween. The stacked body LMb as a second stacked body is disposed on the stacked body LMa. A plurality of select gate lines SGD0 and SGD1 are located in this order from the upper layer side of the stacked body LMb, further above the uppermost word line WL of the stacked body LMb, while interposing the insulating layer OL therebetween.

However, the number of stacked word lines WL and stacked select gate lines SGD and SGS as the conductive layers in the stacked body LM is freely selected. The word line WL and the select gate lines SGD and SGS are, for example, a tungsten layer or a molybdenum layer. The insulating layer OL as a first insulating layer is, for example, a silicon oxide layer.

The uppermost insulating layer OL of each of the stacked bodies LMa and LMb is thicker than, for example, the other insulating layers OL in the stacked bodies LMa and LMb. The uppermost insulating layer OL of the stacked body LMa is in contact with the lowermost word line WL of the stacked body LMb, and insulating layers 52 and 53 are located in this order on the uppermost insulating layer OL of the stacked body LMb. The insulating layers 52 and 53 configure a portion of the above-described insulating layer 50, and an upper surface of the insulating layer 53 is in contact with the lower surface of the insulating layer 40 on the peripheral circuit CBA side.

As illustrated in FIG. 4E, the stepped region SR provided in the stacked body LM is formed by processing the word line WL and the select gate lines SGD and SGS into a stepped shape, so that the stepped portions SPs, SPb, and SPa are acquired.

The stepped portion SPs is the uppermost layer portion of the stacked body LM, that is, a portion where the select gate line SGD is processed into a stepped shape. The stepped portion SPb is a portion of the upper layer of the stacked body LM except for the select gate line SGD, that is, a portion where the word line WL of the stacked body LMb is processed into a stepped shape. The stepped portion SPa is a portion of the lower layer of the stacked body LM, that is, a portion where the word line WL and the select gate line SGS of the stacked body LMa are processed into a stepped shape.

The stepped portions SPs, SPb, and SPa are located in the stepped region SR in this order to gradually increase the distance from the memory region MR. That is, as the distance from the memory area MR increases, the height positions of the terrace portions of the stepped portions SPs, SPb, and SPa decrease.

It should be noted that among the stepped portions SPs, SPb, and SPa, the stepped portion SPa provided in the stacked body LMa is an example of a first stepped portion, and the stepped portions SPs and SPb provided in the stacked body LMb are examples of a second stepped portion.

As illustrated in FIGS. 4A and 4E, the stacked body LM is divided in the Y direction by a plurality of plate-like portions PT.

That is, each of the plate-like portions PT is aligned with each other in the Y direction and extends in the direction along the stacking direction of the stacked body LM and the X direction. As such, the plate-like portion PT extends continuously in the stacked body LM from one end of the stacked body LM in the X direction to the other end. The plate-like portion PT penetrates the stacked body LM and the upper source line DSLb, to reach the intermediate source line BSL in the memory region MR. Each of the plate-like portions PT is configured as a single insulating layer 54 such as a silicon oxide layer.

The plate-like portion PT has a taper shape, for example, such that the width in the Y direction decreases from the upper end toward the lower end. Alternatively, the plate-like portion PT has a bowing shape in which the width in the Y direction is maximized at a predetermined position between the upper end and the lower end.

In the memory region MR and the stepped portion SPs of the stepped region SR, a plurality of separation layers SHE penetrating the upper layer portion of the stacked body LM and extending in the direction along the X direction are located between the plate-like portions PT adjacent in the Y direction. The separation layers SHE are insulating layers 56 such as silicon oxide layers penetrating the select gate lines SGD0 and SGD1 to reach the insulating layer OL directly under the select gate line SGD1.

In other words, the separation layer SHE penetrating the upper layer portion of the stacked body LM extends from the memory region MR and the stepped portion SPs in the X direction between the plate-like portions PT, so that the upper layer portion of the stacked body LM is partitioned into the select gate lines SGD0 and SGD1.

It should be noted that the region between the adjacent plate-like portions PT in the Y direction is an example of a physical configuration corresponding to one block BLK (refer to FIG. 2) described above. The region partitioned into the pattern of the select gate lines SGD0 and SGD1 by the separation layer SHE between the adjacent plate-like portions PT is an example of a physical configuration corresponding to the above-described string unit SU (refer to FIG. 2).

As illustrated in FIG. 4A, the plurality of pillars PL penetrating the stacked body LM, the upper source line DSLb, and the intermediate source line BSL to reach the lower source line DSLa are dispersed and located in the memory region MR.

The plurality of pillars PL as first pillars are located, for example, in a staggered arrangement when viewed from the stacking direction of the stacked body LM. Each pillar PL has, for example, a circular shape, an elliptical shape, an oval shape, or the like as a cross-sectional shape in the direction along the layer direction of the stacked body LM, that is, in the direction along the XY plane.

The pillar PL has a taper shape in which the diameter and cross-sectional area decrease from the upper layer side to the lower layer side in the portion penetrating the stacked body LMa and the portion penetrating the stacked body LMb, respectively. Alternatively, the pillar PL has a bowing shape in which the diameter and cross-sectional area are maximized at a predetermined position between the upper layer side and the lower layer side in the portion penetrating the stacked body LMa and the portion penetrating the stacked body LMb, respectively.

Each of the plurality of pillars PL includes a memory layer ME extending in the stacking direction in the stacked body LM, a channel layer CN penetrating the stacked body LM and connected to the intermediate source line BSL, a cap layer CP at the upper end of the pillar PL, and a core layer CR that is a core material of the pillar PL.

As illustrated in FIG. 4B, the memory layer ME has a multilayer structure in which a block insulating layer BK, a charge storage layer CT, and a tunnel insulating layer TN are stacked in this order from the outer peripheral side of the pillar PL. More specifically, the memory layer ME is disposed on the side surface of the pillar PL except for the depth position of the intermediate source line BSL. The memory layer ME is also disposed on the bottom surface of the pillar PL to reach the depth of the lower source line DSLa.

The channel layer CN penetrates the stacked body LM, the upper source line DSLb, and the intermediate source line BSL in the memory layer ME, to reach the depth of the lower source line DSLa. More specifically, the channel layer CN is disposed on the side surface and the bottom surface of the pillar PL while interposing the memory layer ME therebetween. However, a portion of the channel layer CN is in contact with the intermediate source line BSL on the side surface, and accordingly, is electrically connected to the source line SL including the intermediate source line BSL. The core layer CR is filled further in the channel layer CN.

Each of the plurality of pillars PL has the cap layer CP connected to the channel layer CN at the upper end. The cap layer CP is connected to the bit line BL disposed in the insulating layer 53 via a plug CH disposed in the insulating layer 52. The bit line BL extends above the stacked body LM in the direction along the Y direction, for example, to intersect the drawing direction of the word line WL.

In FIG. 4A, the plug CH is connected only to one pillar PL in each partition separated by the separation layer SHE. The other pillars PL are connected to other bit lines BL extending in the direction along the Y direction in parallel to the bit line BL illustrated in FIG. 4A at positions different from the cross section illustrated in FIG. 4A via the plug CH (not illustrated in FIG. 4A).

The block insulating layer BK, the tunnel insulating layer TN, and the core layer CR of the memory layer ME are, for example, silicon oxide layers. The charge storage layer CT of the memory layer ME is, for example, a silicon nitride layer. The channel layer CN and the cap layer CP are, for example, semiconductor layers such as polysilicon layers or amorphous silicon layers.

With the above configuration, the memory cells MC are formed in the portions of the side surfaces of the pillars PL that face the respective word lines WL. By applying the predetermined voltage from the word line WL, data is written to and read from the memory cell MC.

With the above configuration, the select gates STD are formed in the portions where the side surfaces of the pillars PL face the select gate lines SGD0 and SGD1 located above the word line WL. The select gates STS are formed in the portions where the side surfaces of the pillars PL face the select gate lines SGS0 and SGS1 located below the word line WL.

By applying predetermined voltages from the select gate lines SGD and SGS, the select gates STD and STS are turned on or off, and the memory cells MC of the pillars PL to which the select gates STD and STS belong are in a selected state or an unselected state.

As illustrated in FIG. 4E, in some cases, some of the plurality of pillars PL may be located at positions overlapping with the above-described separation layer SHE. Since a partial configuration of the pillar PL in the portion overlapping with the separation layer SHE is defected, such a pillar PL may be a dummy pillar that does not have a function of the memory cell MC and the like.

Accordingly, the periodicity of the pillar PL arrangement can be maintained and the pillars PL can be located with high density in the memory region MR. By maintaining the periodicity of the pillar PL arrangement, the processing accuracy of the pillar PL can be improved by decreasing the difference in dimensional conversion between the pillars PL or the like.

As illustrated in FIGS. 5A to 5C, in the stepped region SR, the stepped portions SPs, SPb, and SPa are covered with the insulating layer 51. The insulating layer 51 reaches, for example, the height position of the uppermost layer of the stacked body LM, and the insulating layers 52 and 53 also cover the upper surface of the insulating layer 51. As described above, the insulating layer 51 also configures a portion of the insulating layer 50 of FIG. 1.

In the stepped region SR, the source line SL includes an intermediate insulating layer SCO interposed between the upper source line DSLb and the lower source line DSLa instead of the intermediate source line BSL. The intermediate insulating layer SCO is, for example, a silicon oxide layer. Therefore, in the stepped region SR, the plate-like portion PT penetrates the insulating layer 51, the stacked body LM, and the upper source line DSLb to reach the intermediate insulating layer SCO.

The contacts CC and the plurality of the columnar portions HRm, HRt, and HRs are located in the stepped region SR. As described later, the columnar portions HRm, HRt, and HRs have a role of supporting the configuration of the stacked body LM, when the stacked body LM is formed from a stacked body in which a sacrifice layer and an insulating layer are stacked, and does not contribute to the function of the semiconductor storage device 1.

Each contact CC penetrates the insulating layer 51 and is connected to the word line WL or the select gate lines SGD and SGS directly below the insulating layer OL configuring each step of the stepped portions SPs, SPb, and SPa.

Each contact CC has, for example, a taper shape in which the diameter and cross-sectional area become small from the upper end toward the lower end. Alternatively, the contact CC has a bowing shape in which the diameter and cross-sectional area are maximized at a predetermined position between the upper end and the lower end.

The contact CC includes the insulating layer 55 covering the outer periphery of the contact CC and the conductive layer 25 such as a tungsten layer filled in the insulating layer 55. The conductive layer 25 is connected to an upper layer wiring MX disposed in the insulating layer 53 via a plug V0 disposed in the insulating layer 52. The upper layer wiring MX is electrically connected to the above-described peripheral circuit CBA (refer to FIG. 3).

As illustrated in FIG. 4E, the contacts CC connected to the select gate lines SGD0 and SGD1 are disposed in respective regions of the select gate lines SGD0 and SGD1 separated by the above-described separation layer SHE. That is, the contact CC connected to the select gate line SGD of one layer is disposed in each of the regions interposed between the separation layers SHE and the regions interposed between the separation layers SHE and the plate-like portions PT.

In the above-described stepped portions SPb and SPa where the plurality of word lines WL and the select gate lines SGS are processed into a stepped shape, for example, as described above, as the distance from the memory area MR increases, the word lines WL and the select gate lines SGS configuring the terrace surfaces of the stepped portions SPb and SPa change to a lower layer side one layer by one layer, and the stepped portions SPb and SPa may be configured so that the layers also gradually change in the Y direction.

That is, in some cases, the layers of the word line WL and the select gate line SGS configuring the terrace surface aligned at the same position in the X direction may be different from each other in the Y direction. FIG. 4E illustrates an example where the terrace surfaces of three layers that are continuous in the stacking direction of the word line WL and the select gate line SGS are aligned at the same position in the X direction. According to the example illustrated in FIG. 4E, three contacts CC are also aligned at the same position in the X direction to be connected to the word line WL and the select gate line SGS of each layer.

With the above configuration, the word line WL in each layer and the select gate lines SGD and SGS in the layers above and below the word line WL can be electrically led out. That is, with the above configuration, by applying the predetermined voltage to the memory cell MC from the peripheral circuit CBA via the upper layer wiring MX, the contact CC, the word line WL, and the like, the memory cell MC can be operated as a storage element.

As illustrated in FIG. 5A, the stepped portion SPs is a portion where each pair of the select gate line SGD and the insulating layer OL of the stacked body LMb is processed into a stepped shape. In the stepped portion SPs, the plurality of columnar portions HRm penetrating the insulating layer 51, the stacked bodies LMb and LMa, the upper source line DSLb, and the intermediate insulating layer SCO to reach the lower source line DSLa are dispersed and located.

The plurality of columnar portions HRm serving as third pillars are located, for example, in a grid shape or in a staggered shape when viewed from the stacking direction of the stacked body LM, while avoiding interference with the plate-like portions PT and the contacts CC. Each columnar portion HRm has, for example, a circular shape, an elliptical shape, an oval shape, or the like as a cross-sectional shape in the direction along the XY plane.

The columnar portion HRm has a taper shape in which the diameter and cross-sectional area become small from the upper layer side toward the lower layer side in the portion penetrating the stacked body LMa and the portion penetrating the stacked body LMb, respectively. Alternatively, the columnar portion HRm has a bowing shape in which the diameter and cross-sectional area are maximized at a predetermined position between the upper layer side and the lower layer side in the portion penetrating the stacked body LMa and the portion penetrating the stacked body LMb, respectively.

Each of the plurality of columnar portions HRm has the same layer structure as the pillar PL described above. However, the plurality of columnar portions HRm are in a floating state as a whole, and have no electrical function in the semiconductor storage device 1, as described above.

As the columnar portion HRm is disposed while avoiding interference with the plate-like portion PT and the contact CC as described above, influence of the columnar portion HRm having the same layer structure as the pillar PL caused by contact with the plate-like portion PT and the contact CC is ped.

The columnar portion HRm has the same layer structure as the pillar PL, and includes dummy layers MEd, CNd, and CRd extending in the stacking direction in the stacked body LM.

As illustrated in FIG. 4C, the dummy layer MEd has a multilayer structure in which dummy layers BKd, CTd, and TNd are stacked in this order from the outer peripheral side of the columnar portion HRm. In other words, the dummy layer MEd corresponds to the memory layer ME of the pillar PL described above. The dummy layers BKd, CTd, and TNd provided in the dummy layer MEd correspond to the block insulating layer BK, the charge storage layer CT, and the tunnel insulating layer TN of the pillar PL, respectively.

However, the dummy layer MEd is disposed without interruption on the side surface of the columnar portion HRm from the upper source line DSLb to the lower source line DSLa. The dummy layer MEd is also disposed at the lower end of the columnar portion HRm.

The dummy layer CNd penetrates the stacked body LM, the upper source line DSLb, and the intermediate insulating layer SCO in the dummy layer MEd to reach the depth of the lower source line DSLa. The dummy layer CNd corresponds to the channel layer CN of the pillar PL described above.

However, the dummy layer MEd is disposed on the side surface of the dummy layer CNd from the upper source line DSLb to the lower source line DSLa, and the dummy layer CNd is not in direct contact with the intermediate insulating layer SCO. The dummy layer CRd is filled further in the dummy layer CNd. The dummy layer CRd corresponds to the core layer CR of the pillar PL described above.

As illustrated in FIGS. 4B and 4C, the cross-sectional area and diameter of the columnar portion HRm in the direction along the XY plane are larger than the cross-sectional area and diameter of the pillar PL in the direction along the XY plane at the same height position of the stacked body LM.

The thickness of each layer except for the core layer CR of the pillar PL and the corresponding dummy layer CRd of the columnar portion HRm is substantially equal at the same height position of the stacked body LM. That is, the respective thicknesses of the block insulating layer BK, the charge storage layer CT, the tunnel insulating layer TN, and the channel layer CN of the pillar PL are substantially the same as thicknesses of the corresponding dummy layers BKd, CTd, TNd, and CNd of the columnar portion HRm.

On the other hand, at the same height position of the stacked body LM, the cross-sectional area and diameter of the dummy layer CRd of the columnar portion HRm in the direction along the XY plane are larger than the cross-sectional area and diameter of the corresponding core layer CR of the pillar PL.

As illustrated in FIG. 5A, each of the plurality of columnar portions HRm include a dummy layer CPd at the upper end. The dummy layer CPd corresponds to the cap layer CP of the pillar PL described above. It should be noted that the columnar portion HRm may not include the dummy layer CPd.

Each layer provided in the columnar portion HRm contains the same type of material as each corresponding layer of the pillar PL. That is, the dummy layers BKd and TNd of the dummy layer MEd and dummy layer CRd are, for example, silicon oxide layers. The dummy layer CTd is, for example, a silicon nitride layer. The dummy layers CNd and CPd are, for example, semiconductor layers such as polysilicon layers or amorphous silicon layers. Herein, the semiconductor layer provided in the dummy layer CNd and the like has higher Young's modulus than the materials contained in the other dummy layers MEd and CRd such that the semiconductor layer is hard and difficult to deform.

As illustrated in FIGS. 5B and 5C, the stepped portion SPb is the portion in which each pair of the word line WL and the insulating layer OL is processed into a stepped shape among each layer provided in the stacked body LMb. The stepped portion SPa is the portion where each pair of the word line WL and the insulating layer OL or one pair of the select gate line SGS and the insulating layer OL are processed into a stepped shape among each layer provided in the stacked body LMa.

In the stepped portions SPb and SPa, the columnar portions HRt and HRs penetrating the insulating layer 51, the stacked bodies LMb and LMa, the upper source line DSLb, and the intermediate insulating layer SCO to reach the lower source line DSLa are located.

The plurality of columnar portions HRt serving as second pillars are dispersed and located over the entire stepped portions SPb and SPa except for the position adjacent to the plate-like portion PT. Here, the plurality of columnar portions HRt are located in, for example, a grid shape or a staggered shape when viewed from the stacking direction of the stacked body LM while avoiding interference with the contacts CC. Each columnar portion HRt has, for example, a circular shape, an elliptical shape, an oval shape, or the like as a cross-sectional shape in the direction along the XY plane.

The columnar portion HRt has a taper shape in which the diameter and cross-sectional area become small from the upper layer side toward the lower layer side in a portion serving as a first sub-pillar penetrating the stacked body LMa and a portion serving as a second sub-pillar penetrating the stacked body LMb. Alternatively, the columnar portion HRt has a bowing shape in which the diameter and cross-sectional area are maximized at a predetermined position between the upper layer side and the lower layer side in the portion penetrating the stacked body LMa and the portion penetrating the stacked body LMb.

Each of the plurality of columnar portions HRt also has the same layer structure as the pillar PL described above. The plurality of columnar portions HRt are also in a floating state as a whole, and have no electrical function in the semiconductor storage device 1 as described above.

As described above, the columnar portion HRt is disposed without being adjacent to the plate-like portion PT and while avoiding interference with the contact CC, so that influence of the columnar portion HRt having the layer structure similar to that of the pillar PL caused by contact with the plate-like portion PT and the contact CC is reduced.

The columnar portion HRt has the same layer structure as the pillar PL, and includes dummy layers MEt, CNd, and CRd extending in the stacking direction in the stacked body LM.

As illustrated in FIG. 4D, the dummy layer MEt has a multilayer structure in which dummy layers BKt, CTd, and TNd are stacked in this order from the outer peripheral side of the columnar portion HRt. In other words, the dummy layer MEt corresponds to the memory layer ME of the pillar PL described above. The dummy layers BKt, CTd, and TNd provided in the dummy layer MEt correspond to the block insulating layer BK, the charge storage layer CT, and the tunnel insulating layer TN of the pillar PL, respectively.

However, the dummy layer MEt includes the dummy layer BKt that is thicker than the block insulating layer BK of the corresponding pillar PL. The dummy layer MEt is disposed without interruption on the side surface of the columnar portion HRt from the upper source line DSLb to the lower source line DSLa. The dummy layer MEt is also disposed at the lower end of the columnar portion HRt.

The dummy layer CNd corresponding to the channel layer CN of the pillar PL penetrates the stacked body LM, the upper source line DSLb, and the intermediate insulating layer SCO in the dummy layer MEt, like the dummy layer CNd of the columnar portion HRm described above to reach the depth of the lower source line DSLa.

However, the dummy layer MEt is disposed on the side surface of the dummy layer CNd from the upper source line DSLb to the lower source line DSLa, and the dummy layer CNd is not in direct contact with the intermediate insulating layer SCO. The dummy layer CRd corresponding to the core layer CR of the pillar PL is filled further in the dummy layer CNd.

As illustrated in FIGS. 4B to 4D, the cross-sectional area and diameter of the columnar portion HRt in the direction along the XY plane are substantially equal to those of the columnar portion HRm in the direction along the XY plane at the same height position of the stacked body LM. Therefore, the cross-sectional area and diameter of the columnar portion HRt in the direction along the XY plane are larger than the cross-sectional area and diameter of the pillar PL in the direction along the XY plane at the same height position of the stacked body LM.

The thickness of each layer except for the block layer BK of the pillar PL and the corresponding dummy layer BKt of the columnar portion HRt is substantially equal at the same height position of the stacked body LM. In other words, the respective thicknesses of the charge storage layer CT, the tunnel insulating layer TN, and the channel layer CN of the pillar PL are substantially equal to the respective thicknesses of the corresponding dummy layers CTd, TNd, and CNd of the columnar portion HRt. At the same height position of the stacked body LM, the cross-sectional area and diameter of the dummy layer CRd of the columnar portion HRt in the direction along the XY plane are substantially equal to the cross-sectional area and diameter of the corresponding core layer CR of the pillar PL.

On the other hand, the thickness of the dummy layer BKt that the columnar portion HRt includes over the entire stacking direction is thicker than the corresponding block insulating layer BK of the pillar PL. Similarly, the thickness of the dummy layer BKt of the columnar portion HRt is thicker than the dummy layer BKd of the above-described columnar portion HRm.

Herein, as an example, when the diameter of the lower end of the portion penetrating the stacked body LMb in the columnar portion HRt having a taper shape or a bowing shape in each of the portions penetrating the stacked body LMa and the stacked body LMb is 110 nm, the dummy layer BKt of the columnar portion HRt can be configured to be thicker than the block insulating layer BK of the pillar PL and the dummy layer BKd of the columnar portion HRm in a range of 5 nm or more and 10 nm or less.

As illustrated in FIGS. 5B and 5C, each of the plurality of columnar portions HRt also includes the dummy layer CPd corresponding to the cap layer CP of the pillar PL at the upper end. It should be noted that the columnar portion HRt may not include the dummy layer CPd.

Each layer provided in the columnar portion HRt contains the same type of material as each layer of the corresponding pillar PL. That is, the dummy layers BKt and TNd of the dummy layer MEt and the dummy layer CRd are, for example, silicon oxide layers. The dummy layer CTd is, for example, a silicon nitride layer. The dummy layers CNd and CPd are, for example, semiconductor layers such as polysilicon layers or amorphous silicon layers.

It should be noted that the tunnel insulating layer TN of the pillar PL and the dummy layer TNd of the columnar portions HRm and HRt are examples of a second insulating layer. The charge storage layer CT of the pillar PL and the dummy layer CTd of the columnar portions HRm and HRt are examples of a fourth insulating layer. The block insulating layer BK of the pillar PL, the dummy layer BKd of the columnar portion HRm, and the dummy layer BKt of the columnar portion HRt are examples of a third insulating layer.

In the stepped portions SPb and SPa, the columnar portions HRs as fourth pillars are located on both sides of the plate-like portion PT in the Y direction, and in the direction along the X direction adjacent to the plate-like portion PT. Each columnar portion HRs has, for example, a circular shape, an elliptical shape, an oval shape, or the like as a cross-sectional shape in the direction along the XY plane.

The columnar portion HRs has a taper shape in which the diameter and cross-sectional area decrease from the upper layer side to the lower layer side in the portion penetrating the stacked body LMa and the portion penetrating the stacked body LMb, respectively. Alternatively, the columnar portion HRs has a bowing shape in which the diameter and cross-sectional area are maximized at a predetermined position between the upper layer side and the lower layer side in the portion penetrating the stacked body LMa and the portion penetrating the stacked body LMb, respectively.

The cross-sectional area and diameter of the columnar portion HRs in the direction along the XY plane are substantially equal to the cross-sectional area and diameter of the columnar portions HRm and HRt in the direction along the XY plane at the same height position of the stacked body LM. Therefore, the cross-sectional area and diameter of the columnar portion HRs in the direction along the XY plane are larger than the cross-sectional area and diameter of the pillar PL in the direction along the XY plane at the same height position of the stacked body LM.

Each columnar portion HRs is a single insulating layer 57 as a fifth insulating layer such as a silicon oxide layer. Therefore, the columnar portion HRs cannot have any electrical influence on other configurations, and can interfere with the adjacent plate-like portion PT. This is because, in the stepped portions SPb and SPa, instead of the columnar portion HRm, the columnar portion HRs is disposed at a position adjacent to the plate-like portion PT.

More specifically, in the plate-like portion PT, the portion disposed in the insulating layer 51 tends to have a larger curvature of the taper shape or the bowing shape than the portion disposed in the stacked body LM. That is, when the plate-like portion PT has a taper shape, the difference between the width of the upper end and the width of the lower end of the plate-like portion PT in the insulating layer 51 tends to become large. When the plate-like portion PT has a bowing shape, the difference between the maximum width of the plate-like portion PT and the width of the upper and lower ends of the plate-like portion PT in the insulating layer 51 tends to become large.

As the length of the stacked body LM extending in the stacked direction in the insulating layer 51 increases, the curvature of the taper shape or the bowing shape of the plate-like portion PT tends to be further increased. That is, in the stepped region SR, compared to the stepped portion SPs in which each layer on the upper layer side of the stacked body LM is processed into a stepped shape, in the stepped portions SPb and SPa in which each layer on the lower layer side of the stacked body LM is processed into a stepped shape, a taper shape or a bowing shape of the plate-like portion PT tends to become more significant.

As described above, in the stepped portions SPb and SPa where the maximum width of the plate-like portion PT tends to increase, since the columnar portion n HRt is not disposed adjacent to the plate-like portion PT, the interference with the plate-like portion PT is reduced.

As described above, in principle, the position of the upper end of the columnar portion HRt is determined to avoid interference with the contact CC.

However, the columnar portion HRt extends long in the stacking direction. Similarly, the contacts CC located in the stepped portions SPb and SPa also extend long in the stacking direction to be connected to each layer of the stacked body LMa, which is the lower layer portion of the stacked body LM. Therefore, misalignment may occur in at least one of the columnar portion HRt and the contact CC, or incline may occur due to stress from other layers.

Therefore, interference with the contact CC may occur in the lower structure of the columnar portion HRt. When the columnar portion HRt and the contact CC have a bowing shape, the maximum diameter portion of the bowing shape of at least one of the columnar portion HRt and the contact CC may interfere with the other.

As described above, the columnar portion HRt includes the relatively thick dummy layer BKt on the outermost periphery. Therefore, even when the columnar portion HRt and the contact CC interfere with each other, the contact portion of the columnar portion HRt with the contact CC can be limited to the dummy layer BKt, which is a silicon oxide layer or the like. Therefore, the influence due to the contact between the columnar portion HRt and the contact CC is reduced.

As described above, in the lower stepped portions SPb and SPa of the stepped region SR, the columnar portion HRs which is the insulating layer 57 is disposed in the vicinity of the plate-like portion PT to allow interference with the plate-like portion PT. In the stepped portions SPb and SPa, the columnar portions HRt which alleviate the influence of the interference with the contacts CC are dispersed and located.

On the other hand, in the stepped portion SPs of the uppermost layer of the stacked body LM, since it is easy to reduce the interference with the plate-like portion PT and the contact CC, the columnar portions HRm including the dummy layer CNd that is the semiconductor layer having a high Young's modulus have the same layer structure as the pillars PL and are dispersed and located over the entire stepped portion SPs including the vicinity of the plate-like portion PT.

Accordingly, a supporting function when forming the stacked body LM from the stacked body in which the sacrifice layer and the insulating layer are stacked can be enhanced.

It should be noted that, as described above, at the same height position of the stacked body LM, the cross-sectional area of the columnar portions HRm, HRt, and HRs in the direction along the XY plane is larger than, for example, the cross-sectional area of the pillar PL in the direction along the XY plane. The pitch between the plurality of columnar portions HRm, the pitch between the plurality of columnar portions HRt, and the pitch between the plurality of columnar portions HRs are larger than, for example, the pitch between the plurality of pillars PL. The arrangement density of the columnar portions HRm, HRt, and HRs per unit area of the word line WL in the stacked body LM is larger than the arrangement density of the pillars PL per unit area of the word line WL.

As such, for example, by configuring the cross-sectional area of the pillar PL to be smaller than that of the columnar portions HRm, HRt, and HRs and forming a narrow pitch, a large number of memory cells MC can be located with high density in the stacked body LM having a predetermined size, so that the storage capacity of the semiconductor storage device 1 can be increased. On the other hand, since the columnar portions HRm, HRt, and HRs are used only to support the stacked body LM, the manufacturing load can be reduced by not having a precise structure such as the pillar PL with a small cross-sectional area and a narrow pitch.

### (Method for Manufacturing Semiconductor Storage Device)

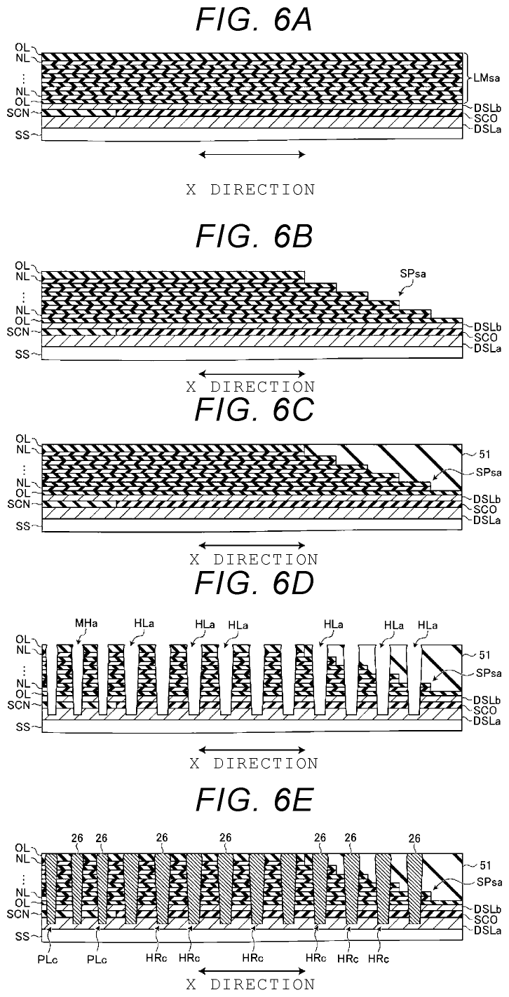

Next, a method for manufacturing the semiconductor storage device 1 of the first embodiment will be described with reference to FIGS. 6A to 16C. FIGS. 6A to 16C are diagrams sequentially illustrating a portion of a procedure of the method for manufacturing the semiconductor storage device 1 according to the first embodiment.

First, FIGS. 6A to 6E illustrate an aspect where a stacked body LMsa, which is the lower layer portion of the stacked body LM before the word line WL is formed, and various configurations are formed on the stacked body LMsa. FIGS. 6A to 6E are cross-sectional views along the X direction of the regions that later become the memory region MR and the stepped region SR.

As illustrated in FIG. 6A, the lower source line DSLa, an intermediate sacrifice layer SCN or the intermediate insulating layer SCO, and the upper source line DSLb are formed in this order on a supporting substrate SS.

As the supporting substrate SS, a semiconductor substrate such as a silicon substrate, an insulating substrate such as a ceramic substrate, a conductive substrate such as an alumina substrate, and the like can be used. The above-described insulating layer 60 (refer to FIG. 3) may be formed on the upper surface side of the supporting substrate SS.

The intermediate sacrifice layer SCN is formed in the region on the supporting substrate SS that later becomes the memory region MR, and the intermediate insulating layer SCO is formed in the region on the supporting substrate SS that later becomes the stepped region SR. The intermediate sacrifice layer SCN is, for example, a silicon nitride layer or the like and is a layer that is later replaced with a polysilicon layer or the like to become the intermediate source line BSL. As described above, the intermediate insulating layer SCO is, for example, a silicon oxide layer.

The stacked body LMsa as the first stacked body is formed in which a plurality of insulating layers NL as the first insulating layers and a plurality of insulating layers OL as the second insulating layers are alternately stacked one layer by one layer on the upper source line DSLb. The insulating layer NL is, for example, a silicon nitride layer and functions as a sacrifice layer that is later replaced with a conductive material to become the word line WL or the select gate line SGS.

As illustrated in FIG. 6B, in a partial region of the stacked body LMsa, the insulating layer NL and the insulating layer OL are processed into a stepped shape to form a stepped portion SPsa. The stepped portion SPsa as the first stepped portion is formed by repeating slimming of a mask pattern such as a photoresist layer and or the like and etching of the insulating layer NL and the insulating layer OL of the stacked body LMsa multiple times.

That is, the mask pattern is formed on the upper surface of the stacked body LMsa, and, for example, the insulating layer NL and the insulating layer OL of the exposed portions are etched and removed one layer by one layer. By treatment using oxygen plasma or the like, the end of the mask pattern is retreated to newly expose the upper surface of the stacked body LMsa, and the insulating layer NL and the insulating layer OL are further etched and removed one layer by one layer. The stepped portion SPsa is formed by repeating such processing multiple times.

As illustrated in FIG. 6C, the insulating layer 51 covers the stepped portion SPsa and to reach the height of the upper surface of the stacked body LMsa. The insulating layer 51 is also formed in the outer region of the stepped portion SPsa.

As illustrated in FIG. 6D, for example, a plurality of memory holes MHa and a plurality of holes HLa extending in the stacking direction of the stacked body LMsa are formed collectively. The memory hole MHa is formed in the region that later becomes the memory region MR, and is the portion that becomes the lower structure of the pillar PL. The hole HLa as a first sub-hole is the portion that is formed in the region that later becomes the stepped region SR to become the lower structure of any of the columnar portions HRm, HRt, and HRS.

More specifically, the plurality of memory holes MHa penetrate the stacked body LMsa, the upper source line DSLb, and the intermediate sacrifice layer SCN to reach the lower source line DSLa. The plurality of holes HLa penetrate the insulating layer 51, the stacked body LMsa, the upper source line DSLb, and the intermediate insulating layer SCO to reach the lower source line DSLa.

As illustrated in FIG. 6E, the memory hole MHa and the hole HLa are filled with a sacrifice layer 26 such as an amorphous silicon layer.

Accordingly, a pillar PLC in which the plurality of memory holes MHa are filled with the sacrifice layer 26 is formed in the region that later becomes the memory region MR. In the region that later becomes the stepped region SR, a columnar portion HRc in which the plurality of holes HLa are filled with the sacrifice layer 26 is formed.

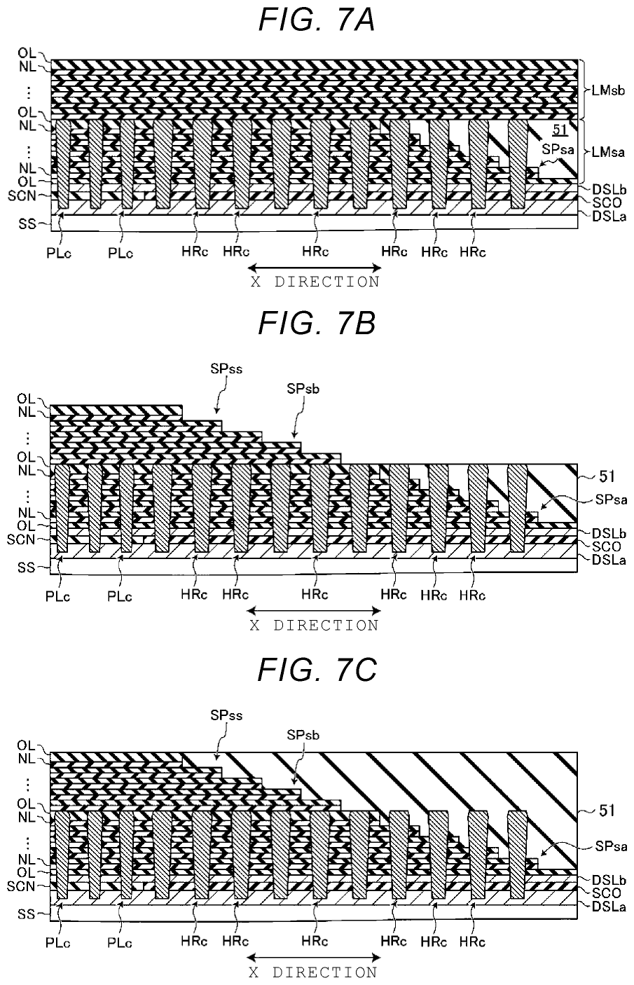

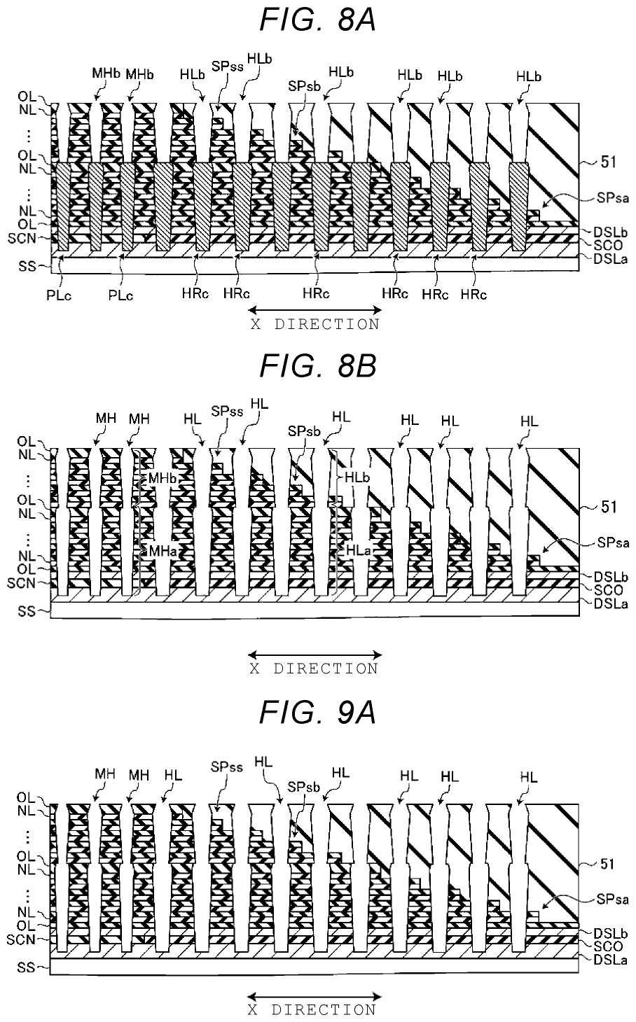

Next, FIGS. 7A to 8B illustrate an aspect where a stacked body LMsb, which is the upper layer portion of the stacked body LM, is formed before the word line WL is formed.

Similarly to FIGS. 6A to 6E described above, FIGS. 7A to 8B are cross-sectional views along the X direction of regions that later become the memory region MR and the stepped region SR.

As illustrated in FIG. 7A, the stacked body LMsb as a second stacked body covers from above the stacked body LMsa and the insulating layer 51 of the stepped portion SPsa, and is formed such that the plurality of insulating layers NL and the plurality of insulating layers OL are alternately stacked one layer by one layer. The insulating layer (sacrifice layer) NL of the stacked body LMsb is later replaced with a conductive layer and becomes the word line WL or the select gate line SGD.

As illustrated in FIG. 7B, in a partial region of the stacked body LMsb, the insulating layer NL and the insulating layer OL are processed into a stepped shape to form stepped portions SPsb and SPss. The stepped portions SPsb and SPss as the second stepped portion are formed by repeating slimming of the mask pattern such as a photoresist layer and etching of the insulating layer NL and the insulating layer OL of the stacked body LMsb multiple times, similarly to the process illustrated in FIG. 7B described above.

Here, the uppermost step of the stepped portion SPsa and the lowermost step of the stepped portion SPsb are brought close to each other to form the stepped portions SPsb and SPss. Accordingly, the stepped portions SPsa, SPsb, and SPss are continuous from the lower layer side to the upper layer side of the stacked bodies LMsa and LMsb. By removing the stacked body LMsb on the insulating layer 51 covering the stepped portion SPsb, the upper end of the columnar portion HRc formed in the stepped portion SPsa is exposed on the upper surface of the insulating layer 51.

As illustrated in FIG. 7C, the insulating layer 51 covers the stepped portions SPsb and SPss and to cover the insulating layer 51 formed in the stepped portion SPsa. Accordingly, the insulating layer 51 reaches the height of the upper surface of the stacked body LMsb.

As illustrated in FIG. 8A, for example, a plurality of memory holes MHb and a plurality of holes HLb extending in the stacking direction at the height of the stacked body LMsb are formed collectively. The memory hole MHb is disposed in the region that later becomes memory region MR, and is the portion that becomes the upper structure of the pillar PL. The hole HLb as a second sub-hole is disposed at the position overlapping with the stepped portions SPsa, SPsb, and SPss in the stacking direction, and is the portion that becomes the upper structure of any of the columnar portions HRm, HRt, and HRS.

More specifically, the plurality of memory holes MHb penetrate the stacked body LMsb to reach the upper ends of the pillars PLC formed in the stacked body LMsa, respectively. The plurality of holes HLb penetrate the insulating layer 51 and the stacked body LMsb to reach the upper ends of the columnar portions HRc formed in the stacked body LMsa, respectively.

As illustrated in FIG. 8B, the sacrifice layer 26 is removed from the pillar PLC and the columnar portion HRC connected to the lower ends of the memory hole MHb and the hole HLb through the memory hole MHb and the hole HLb, respectively.

Accordingly, the memory holes MHa are opened at the bottoms of the plurality of memory holes MHb, and a plurality of memory holes MH are formed by penetrating the insulating layer 51, the stacked bodies LMsb and LMsa, the upper source line DSLb, and the intermediate sacrifice layer SCN, to reach the lower source line DSLa.

The holes HLa are opened at the bottoms of the plurality of holes HLb, and a plurality of holes HL are formed by penetrating the insulating layer 51, the stacked bodies LMsb and LMsa, the upper source line DSLb, and the intermediate insulating layer SCO, to reach the lower source line DSLa.

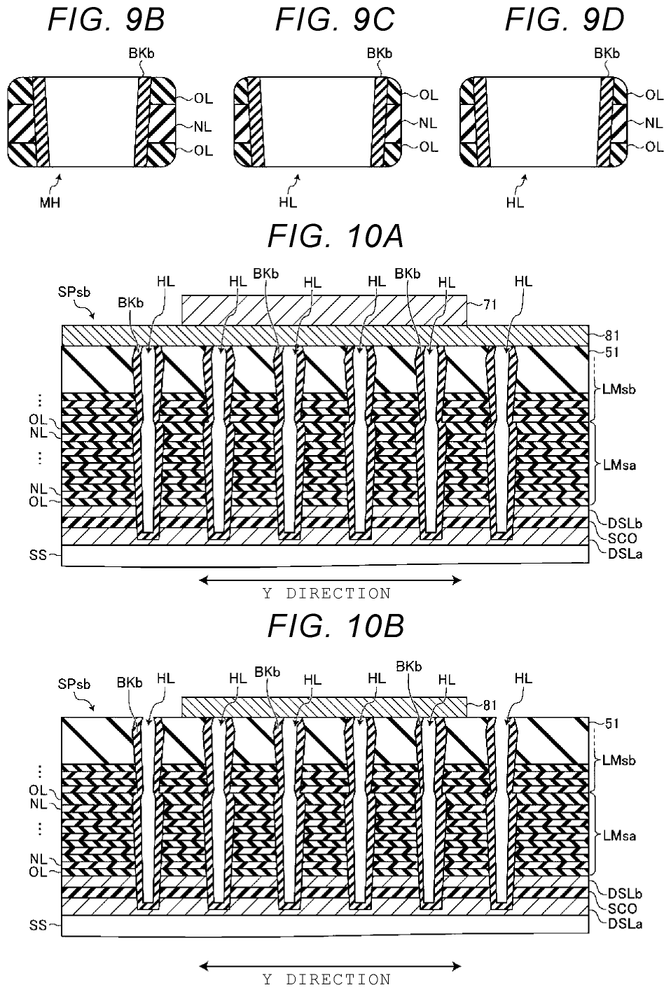

Next, FIGS. 9A to 13Ed illustrate an aspect where a structure such as a multilayer structure is formed in the memory hole MH and the hole HL.

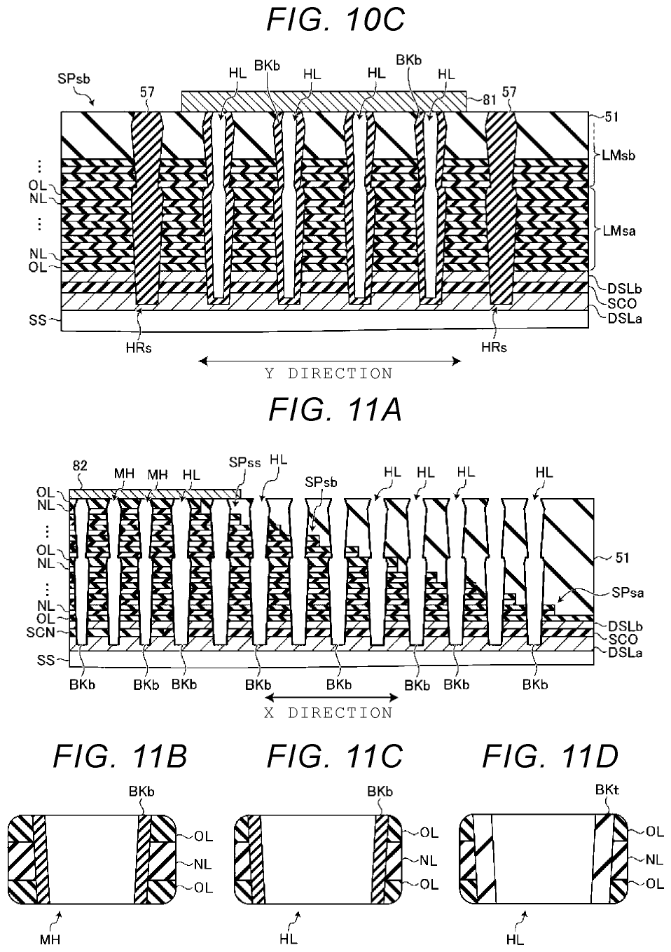

Similarly to the above-described FIGS. 8A and 8B and the like, FIGS. 9A to 12A except for FIGS. 10A to 10C are cross-sectional views along the X direction of the regions that later become the memory region MR and the stepped region SR. FIGS. 9B to 9D, 11B to 11D, and 12B to 12D are enlarged cross-sectional views in the Y direction of the memory hole MH as a first hole, the hole HL as a third hole to be processed into the columnar portion HRm, and the hole HL as a second hole to be processed into the columnar portion HRt, respectively, at the freely selected height position of the insulating layer NL.

That is, FIGS. 9C, 11C, and 12C are enlarged cross-sectional views of the hole HL formed in the stepped portion SPss, and FIGS. 9D, 11D, and 12D are enlarged cross-sectional views of the holes HL formed in the stepped portion SPsb and SPsa.

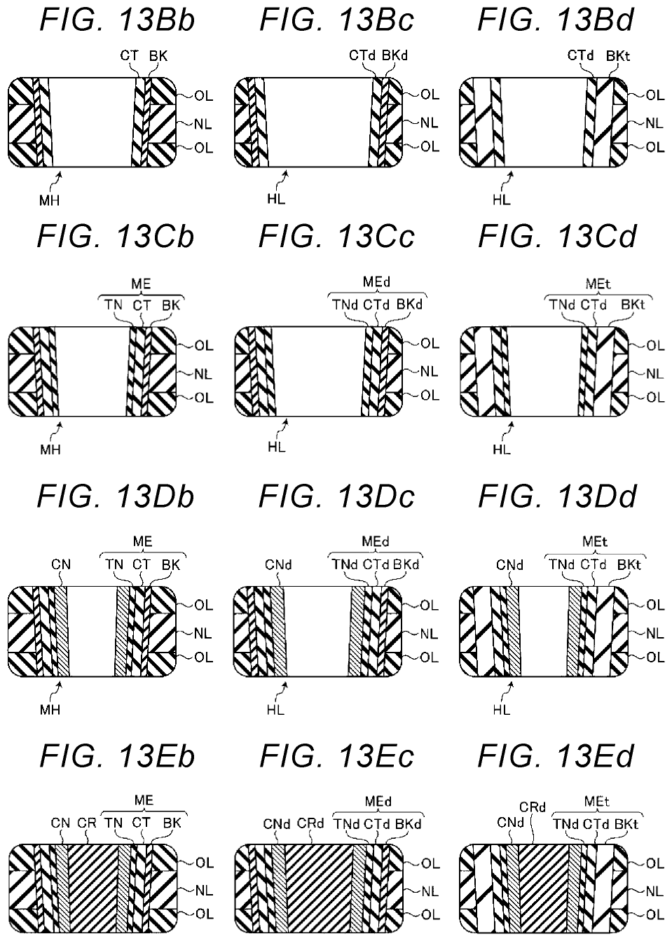

Similarly to FIGS. 8A and 8B and the like described above, FIG. 13A is a cross-sectional view along the X direction of the regions that later become the memory region MR and the stepped region SR. FIGS. 13Bb to 13Eb, FIGS. 13Bc to 13Ec, and FIGS. 13Bd to 13Ed are enlarged cross-sectional views in the Y direction of the memory hole MH, the hole HL to be processed into the columnar portion HRm, and the hole HL to be processed into the columnar portion HRt at the freely selected height position of the insulating layer NL, respectively.

As illustrated in FIG. 9A, each of the holes HL formed in the stepped portions SPss, SPsb, and SPsa and the memory hole MH formed in the region that later becomes the memory region MR is opened on the upper surface of the stacked body LMsb.

As illustrated in FIGS. 9B to 9D, an insulating layer BKb such as a silicon oxide layer is formed on the sidewalls of the memory hole MH and the hole HL opened on the upper surface of the stacked body LMsb. The insulating layer BKb as the third insulating layer is a layer of which a portion in the memory hole MH becomes the block insulating layer BK, of which a portion in some of the holes HL becomes the dummy layer BKd, and of which the entire portion in the rest of the holes HL becomes the dummy layer BKt. It should be noted that the insulating layer BKb is thicker than the block insulating layer BK that is eventually provided in the pillar PL.

It should be noted that the insulating layer BKb is also formed on the upper surface of the stacked body LMsb and the bottom surfaces of the memory hole MH and the hole HL.

FIGS. 10A to 10C are cross-sectional views along the Y direction of the region that later becomes the stepped region SR. More specifically, FIGS. 10A to 10C are cross-sectional views of the stepped portion SPsb, which corresponds to FIG. 5B described above. Therefore, the plate-like portions PT will be formed later in the vicinity of both ends of the cross section in the left-right direction of the paper illustrated in FIGS. 10A to 10C. Among the plurality of holes HL illustrated in FIGS. 10A to 10C, the holes HL at both ends in the left-right direction of the paper are processed into the columnar portions HRs, and will be adjacent to the plate-like portions PT that is later formed.

In the process illustrated in FIGS. 10A to 10C below, among the plurality of holes HL, the holes HL that later become the columnar portions HRm and HRt, and the memory hole MH that is formed in the region that later becomes the memory region MR are protected with a resist pattern or the like, and then, the hole HL as a fourth hole that is to be adjacent to the plate-like portion PT to be formed later is processed to form the columnar portion HRS.

However, it is undesirable for liquid resist to flow into the deep hole HL and memory hole MH during resist pattern formation. This is because there is a concern that the resist in the hole HL and the memory hole MH may remain without being removed during exposure and development of the resist. Therefore, for example, before forming the resist pattern, a layer prevents the resist liquid from flowing into the hole HL and the memory hole MH.

As illustrated in FIG. 10A, the insulating layer BKb is formed on the sidewalls and bottom surfaces of the plurality of holes HL opened in the stepped portion SPsb, respectively, by the process illustrated in FIGS. 9A to 9D described above. A CVD-carbon layer 81 covers the hole HL. Although not illustrated, the CVD-carbon layer 81 also covers the memory hole MH formed in the region that later becomes the memory region MR.

A resist pattern 71 having openings at the positions overlapping in the stacking direction with the holes HL at both ends in the left-right direction of the paper among the plurality of holes HL is formed on the stacked body LMsb while interposing the CVD-carbon layer 81 therebetween. Although not illustrated, the resist pattern 71 is also formed at the position overlapping in the stacking direction with the memory hole MH formed in the region that later becomes the memory region MR.

Herein, the CVD-carbon layer 81 is an organic layer formed by, for example, a chemical vapor deposition (CVD) method using a carbon-containing gas. The CVD-carbon layer 81 has better hardness than, for example, a photoresist layer which is also an organic layer and can be removed by ashing using oxygen plasma or the like.

By adjusting a step coverage when forming the CVD-carbon layer 81, the CVD-carbon layer 81 covering the upper surface of the hole HL can be formed without getting into the hole HL. As such, by forming the resist pattern 71 with the CVD-carbon layer 81 interposed, the resist liquid can be prevented from flowing into the hole HL.

As illustrated in FIG. 10B, the CVD-carbon layer 81 is etched by using the resist pattern 71 as a mask to expose the holes HL at both ends of the CVD-carbon layer 81 in the left-right direction of the paper. It should be noted that the resist pattern 71 and the CVD-carbon layer 81 are both organic layers made of the same type of material. Therefore, when the CVD-carbon layer 81 is processed as described above, the resist pattern 71 is also etched and removed, so that the resist pattern 71 may be removed when the processing of the CVD-carbon layer 81 is completed.

As illustrated in FIG. 10C, the hole HL exposed from the CVD-carbon layer 81 is filled with the insulating layer 57 such as a silicon oxide layer. Here, the insulating layer 57 is filled into the hole HL through the insulating layer BKb formed on the sidewall and bottom surface of the hole HL. Accordingly, the columnar portions HRs are formed at positions that will be adjacent to the plate-like portions PT that will be formed later.

It should be noted that the insulating layer BKb is thinner than the volume of the insulating layer 57 filled into the hole HL, and the insulating layers BKb and 57 are both of the same type of silicon oxide layer or the like. Therefore, after filling the insulating layer 57, the insulating layers BKb and 57 may not have a clear interface and may be indistinguishable from each other. From now on, illustration of the insulating layer BKb formed in the hole HL will be omitted.

After that, the remaining CVD-carbon layer 81 is removed by, for example, ashing using oxygen plasma.

As illustrated in FIG. 11A, a CVD-carbon layer 82 covering the plurality of memory holes MH and the hole HL formed in the stepped portion SPss is formed. The holes HL remaining in the stepped portions SPsb and SPsa are exposed from the CVD-carbon layer 82. The upper surfaces of the columnar portions HRs formed in the stepped portions SPsb and SPsa are also exposed from the CVD-carbon layer 82, but since the columnar portions HRs are, for example, single insulating layers 57, there is no influence from the subsequent processing.

It should be noted that the above-described pattern of the CVD-carbon layer 82 can be obtained by patterning the CVD-carbon layer 82 using, for example, the resist pattern (not illustrated).

As illustrated in FIG. 11D, the dummy layer BKt that is thicker than the above-described insulating layer BKb is formed by further forming a silicon oxide layer or the like on the sidewall of the hole HL formed in the stepped portions SPsb and SPsa and exposed from the CVD-carbon layer 82. The dummy layer BKt is also formed on the upper surface of the stacked body LMsb and on the bottom surfaces of the holes HL of the stepped portions SPsb and SPsa.

As illustrated in FIGS. 11B and 11C, additional silicon oxide layer or the like is not formed in the memory hole MH covered with the CVD-carbon layer 82 and the hole HL in the stepped portion SPss, and the insulating layer BKb is maintained with the original layer thickness in the memory hole MH and the hole HL.

After that, the CVD-carbon layer 82 is removed by, for example, ashing using oxygen plasma.

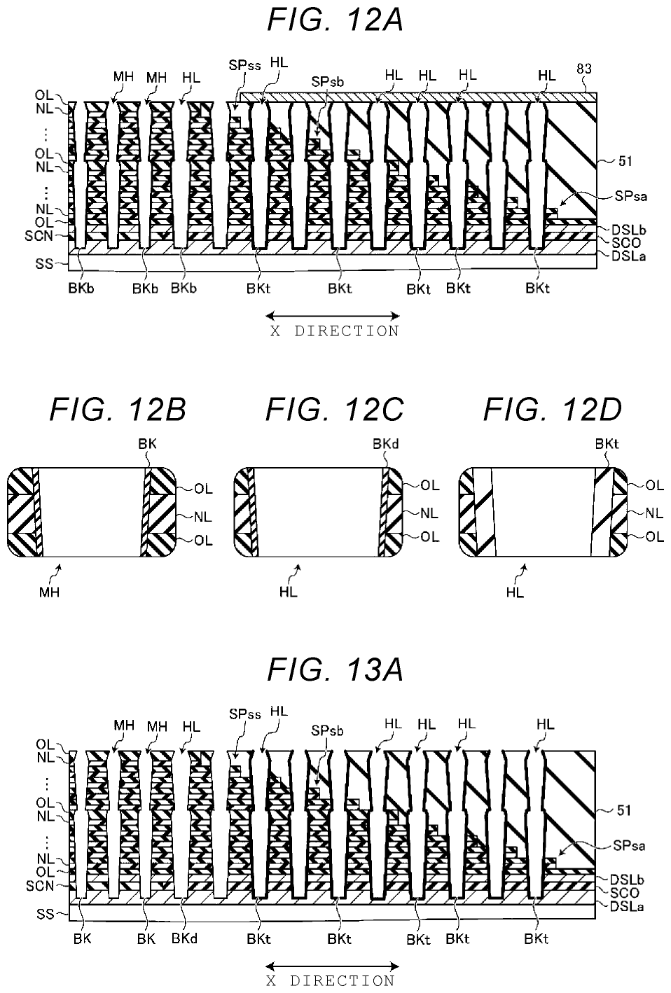

As illustrated in FIG. 12A, a CVD-carbon layer 83 covers the holes HL formed in the stepped portions SPsb and SPsa. The plurality of memory holes MH and the hole HL formed in the stepped portion SPss are exposed from the CVD-carbon layer 83.

As illustrated in FIGS. 12B and 12C, the insulating layer BKb on the sidewalls of the memory hole MH exposed from the CVD-carbon layer 83 and the hole HL formed in the stepped portion SPss and exposed from the CVD-carbon layer 83 is slimmed and thinned. Such slimming can be performed, for example, by wet treatment or the like.

Accordingly, the block insulating layer BK is formed on the sidewall of the memory hole MH. The dummy layer BKd is formed on the sidewall of the hole HL of the stepped portion SPss.

When forming the memory hole MH and the like, in some cases, the sidewall of the memory hole MH may be unevenly formed. As described above, by first forming the insulating layer BKb that is thicker than the block insulating layer BK, and then thinning the block insulating layer BK to an appropriate layer thickness by slimming, the unevenness on the inner wall surface of the block insulating layer BK transferred from the unevenness of the sidewall of the memory hole MH can be reduced.

As illustrated in FIG. 12D, the holes HL formed in the stepped portions SPsb and SPsa and covered with the CVD-carbon layer 83 are not subjected to the slimming process of the dummy layer BKt. Therefore, the dummy layer BKt is maintained with the original layer thickness in the holes HL of the stepped portions SPsb and SPsa.

After that, the CVD-carbon layer 83 is removed by, for example, ashing using oxygen plasma.

As described above, by additionally forming silicon oxide in the holes HL of the stepped portions SPsb and SPsa and slimming the insulating layer BKb in the memory hole MH and the hole HL of the stepped portion SPss, the layer thickness of the dummy layer BKt and the layer thickness of the block insulating layer BK and the dummy layer BKd have a predetermined layer thickness difference.

As an example, when the diameter of the lower end of the hole HLb penetrating the stacked body LMsb is 110 nm, as described above, the dummy layer BKt can be thicker than the block insulating layer BK and the dummy layer BKd in a range of 5 nm or more and 10 nm or less.

As illustrated in FIG. 13A, after the CVD-carbon layer 83 is removed, the memory hole MH in which the block insulating layer BK is formed and the holes HL in which the respective dummy layers BKd and BKt are formed are opened again on the upper surface of the stacked body LMsb.

As illustrated in FIGS. 13Bb to 13Bd, a silicon nitride layer or the like is formed on each of the sidewalls of the memory holes MH and the holes HL. Accordingly, the charge storage layer CT is formed on the sidewall of the memory hole MH while interposing the block insulating layer BK therebetween. The dummy layer CTd is formed on the sidewall of the hole HL while interposing the dummy layer BKd or the dummy layer BKt therebetween, respectively. The charge storage layer CT and the dummy layer CTd as fifth insulating layers are also formed on the upper surface of the stacked body LMsb and the like.

As illustrated in FIGS. 13Cb to 13Cd, a silicon oxide layer or the like is formed on each of the sidewalls of the memory holes MH and the holes HL.

Accordingly, the tunnel insulating layer TN is formed on the sidewall of the memory hole MH while interposing the block insulating layer BK and the charge storage layer CT therebetween. Accordingly, the memory layer ME including the block insulating layer BK, the charge storage layer CT, and the tunnel insulating layer TN is formed on the sidewall of the memory hole MH.

The dummy layer TNd is formed on the sidewall of the hole HL while interposing the dummy layer BKd or the dummy layer BKt, and the dummy layer CTd therebetween, respectively. Accordingly, the dummy layer MEd or the dummy layer MEt including the dummy layer BKd or the dummy layer BKt, the dummy layer CTd, and the dummy layer TNd is formed on each of the sidewalls of the holes HL.

It should be noted that the tunnel insulating layer TN and dummy layer TNd as fourth insulating layers are also formed on the upper surface of the stacked body LMsb and the like.

As illustrated in FIGS. 13Db to 13Dd, a semiconductor layer such as a polysilicon layer or an amorphous silicon layer is formed on the sidewalls of each of the memory holes MH and the holes HL. Accordingly, the channel layer CN is formed on the sidewall of the memory hole MH while interposing the memory layer ME therebetween. The dummy layer CNd is formed on the sidewall of the hole HL while interposing the dummy layer MEd or the dummy layer MEt therebetween. The channel layer CN and the dummy layer CNd are also formed on the upper surface of the stacked body LMsb and the like.

As illustrated in FIGS. 13Eb to 13Ed, the gaps remaining in the memory hole MH and the hole HL are filled with a silicon oxide layer or the like.

The cross-sectional area and diameter of the memory hole MH in the direction along the XY plane are smaller than the cross-sectional area and diameter of the hole HL. The gap in the hole HL in which a multilayer structure including the dummy layer BKt is formed on the sidewall is smaller than the gap in the hole HL in which a multilayer structure including the dummy layer BKd is formed on the sidewall, and for example, the size of the gap is substantially the same size as the gap remaining in the memory hole MH.

Therefore, the gaps in the memory hole MH and the gaps in the hole HL including the dummy layer BKt on the sidewall are filled with a silicon oxide layer or the like earlier than in the hole HL including the dummy layer BKd on the sidewall.

A multilayer structure including the dummy layer BKd on the sidewall is formed, and the hole HL with the largest remaining gap takes the longest time to be filled with a silicon oxide layer or the like. Therefore, even after the memory hole MH and the hole HL including the dummy layer BKt on the sidewall are substantially completely filled with a silicon oxide layer and the like, the filling process with a silicon oxide layer and the like is continued until the hole HL including the dummy layer BKd on the sidewall is substantially completely filled with a silicon oxide layer or the like.

By the above processing, the core layer CR is formed in the memory hole MH, and the dummy layer CRd is formed in the hole HL. The core layer CR and the dummy layer CRd are also formed on the upper surface of the stacked body LMsb and the like.

It should be noted that, as described above, the layer thickness difference between the block insulating layer BK, and the dummy layer BKd and the dummy layer BKt can be specified, for example, according to the diameter of the lower end of the hole HLb penetrating the stacked body LMsb portion among the holes HL in which the dummy layer BKt is formed. Accordingly, when the dummy layers CTd, TNd, CNd, and the like are sequentially formed in the hole HL in which the dummy layer BKt thicker than the others is formed, the lower end of the hole HLb is blocked without all the layers being formed, and thus, for example, the voids or the like in the hole HLa penetrating the stacked body LMsa portion can be prevented.

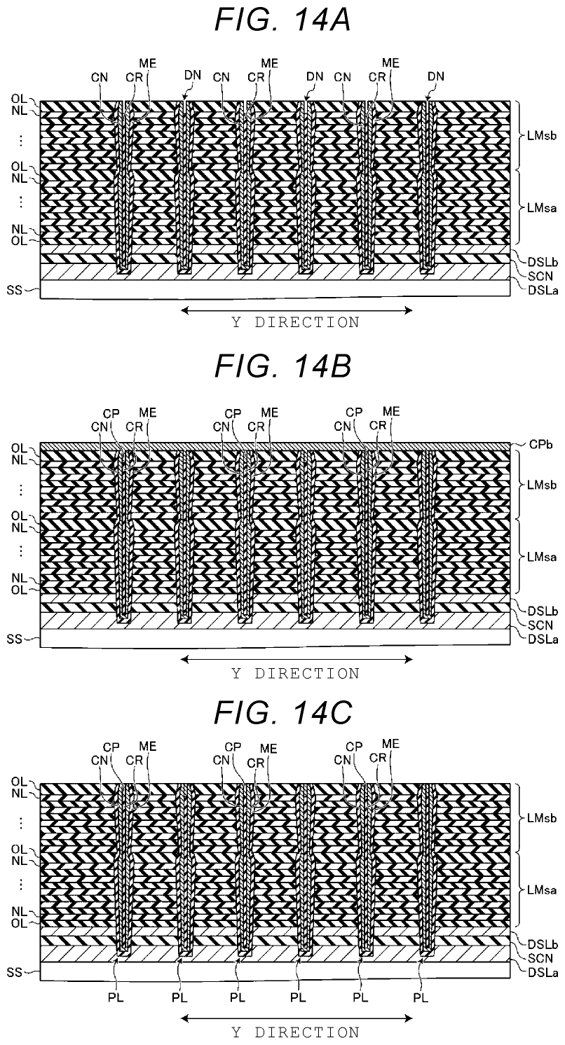

Next, FIGS. 14A to 14C illustrate an aspect where the memory layer ME, the channel layer CN, and the core layer CR formed in this order on the upper surface of the stacked body LMsb are processed to form the pillar PL including the cap layer CP at the upper end.

FIGS. 14A to 14C are cross-sectional views along the Y direction of the region that later becomes the memory region MR and corresponds to FIG. 4A described above. Therefore, the plate-like portions PT will be formed later in the vicinity of both ends of the cross sections illustrated in FIGS. 14A to 14C in the left-right direction of the paper.

As illustrated in FIG. 14A, the core layer CR on the upper surface of the stacked body LMsb is etched back to be removed from the upper surface of the stacked body LMsb. Here, excessive etch back is performed on the core layer CR to retreat the core layer CR at the upper end of the memory hole MH in the depth direction of the memory hole MH. As a result, the core layer CR at the upper end of the memory hole MH is removed, and, for example, a cavity DN having substantially the same diameter as the removed core layer CR is formed.

As illustrated in FIG. 14B, a semiconductor layer CPb is formed in the cavity DN at the upper end of the memory hole MH. The semiconductor layer CPb is a layer that later becomes the cap layer CP. The semiconductor layer CPb is also formed on the upper surface of the stacked body LMsb.

As illustrated in FIG. 14C, the semiconductor layer CPb on the upper surface of the stacked body LMsb is removed by CMP or the like, and the cap layer CP is formed at the upper end of the memory hole MH. The insulating layer OL, which is the uppermost layer of the stacked body LMsb thinned by CMP or the like, is further stacked.

As a result, the pillar PL of which the upper end including the cap layer CP is buried in the uppermost insulating layer OL is formed. However, here, the memory layer ME covers the entire sidewall of the pillar PL, and the sidewall of the channel layer CN is not exposed.

It should be noted that also in the region that later becomes the stepped region SR, the above-described processing illustrated in FIGS. 14A to 14C is performed in parallel, and thus, the columnar portions HRm and HRt each including the dummy layer CPd at the upper end are formed. However, since the columnar portions HRm and HRt have a dummy configuration that does not contribute to the function of the semiconductor storage device 1, the dummy layer CPd may not be formed in the columnar portions HRm and HRt. Here, the cavities DN of the columnar portions HRm and HRt can be backfilled with a silicon oxide layer or the like.

The columnar portion HRs is entirely configured with, for example, a single insulating layer 57, and the above-described cavity DN is not formed at the upper end of the columnar portion HRS. Therefore, the structure corresponding to the cap layer CP is not formed either.

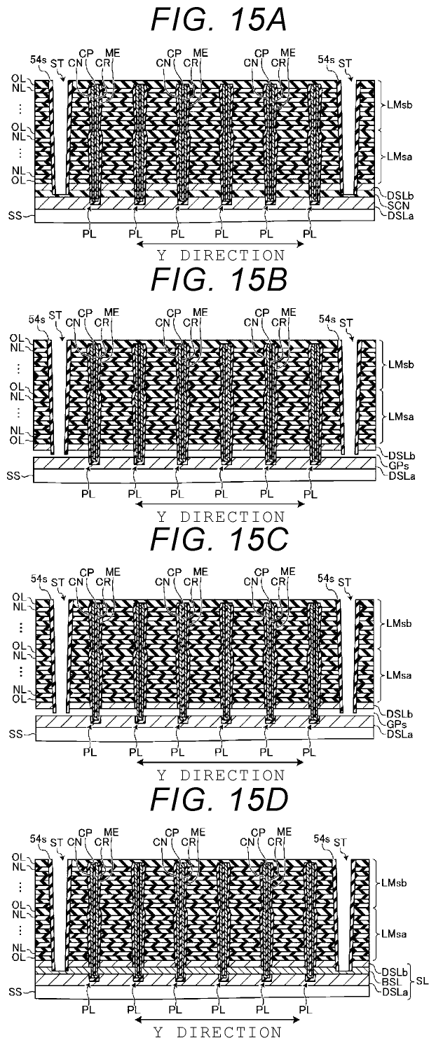

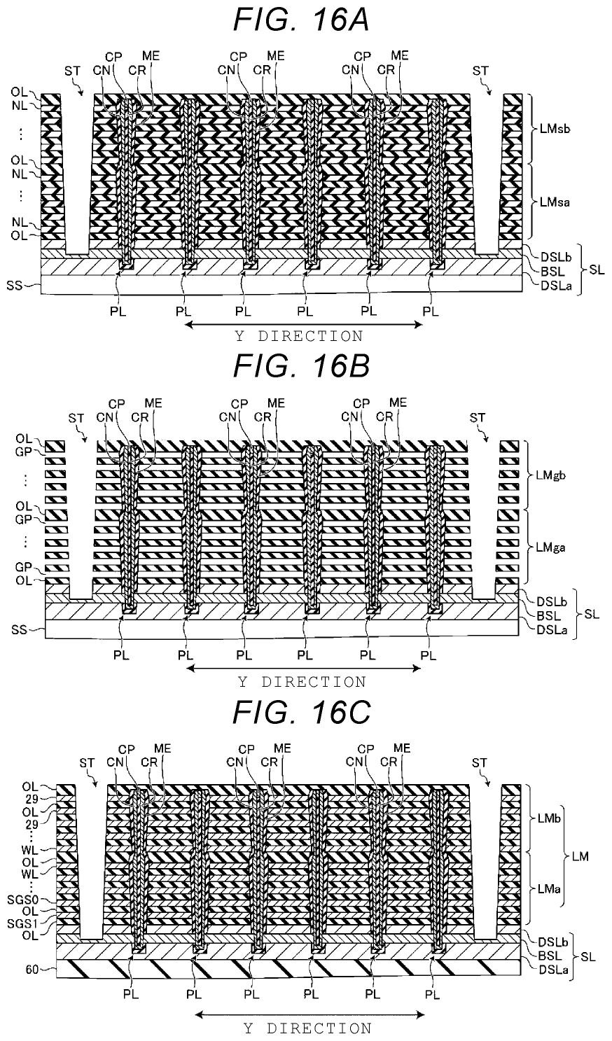

Next, FIGS. 15A to 16C illustrate an aspect where the source line SL and word line WL are formed. FIGS. 15A to 16C are cross-sectional views along the Y direction of the region that later becomes the memory region MR, similarly to FIGS. 14A to 14C described above.

As illustrated in FIG. 15A, a slit ST penetrating the stacked bodies LMsb and LMsa and the upper source line DSLb to reach the intermediate sacrifice layer SCN is formed. An insulating layer 54s is formed on the sidewall of the slit ST facing each other in the Y direction.

The slit ST has a tapered or bowed vertical cross section in the Y direction, and also extends in the direction along the X direction within the stacked bodies LMsa and LMsb. Therefore, in the stepped region SR (not illustrated), the lower end of the slit ST reaches the intermediate insulating layer SCO.

Here, due to the difference in hardness between the stacked bodies LMsa and LMsb in which the plurality of insulating layers NL and OL are alternately stacked and the insulating layer 51 which is a single layer such as a silicon oxide layer, the curvature of the taper shape or the bowing shape of the slit ST is more significant in the stepped portions SPss, SPsb, and SPsa covered with the insulating layer 51.

From the stepped portion SPss to the stepped portion SPsb and further to the stepped portion SPsa, the length of the slit ST extending in the insulating layer 51 in the stacking direction of the stacked bodies LMsa and LMsb increases. Therefore, from the stepped portion SPss to the stepped portion SPsa, the curvature of the taper shape or the bowing shape of the slit ST increases.

As illustrated in FIG. 15B, for example, a removing liquid for the intermediate sacrifice layer SCN such as hot phosphoric acid is poured into the slit ST of which the sidewall is protected by the insulating layer 54s to remove the intermediate sacrifice layer SCN interposed between the lower source line DSLa and the upper source line DSLb.

Accordingly, the gap layer GPs is formed between the lower source line DSLa and the upper source line DSLb. A portion of the memory layer ME at the outer periphery of the pillar PL is exposed within the gap layer GPS.

Here, since the sidewall of the slit ST is protected by the insulating layer 54s, the insulating layer NL in the stacked bodies LMsa and LMsb is also not removed. In the stepped region SR (not illustrated), there is no sacrifice layer SCN between the lower source line DSLa and the upper source line DSLb, and the gap layer GPs is not formed.

As illustrated in FIG. 15C, a chemical solution is appropriately poured into the gap layer GPs through the slit ST, and the block insulating layer BK, the charge storage layer CT, the charge storage layer CT, and the tunnel insulating layer TN (refer to FIG. 13Eb) of the memory layer ME exposed in the gap layer GPs are sequentially removed. Accordingly, the memory layer ME is removed from a portion of the sidewall of the pillar PL, and a portion of the inner channel layer CN is exposed within the gap layer GPS.

As illustrated in FIG. 15D, a raw material gas such as amorphous silicon is injected into the slit ST of which the sidewall is protected by the insulating layer 54s, and the gap layer GPs is filled with amorphous silicon or the like. The supporting substrate SS is heat-treated to make amorphous silicon filled within the gap layer GPs into a polycrystalline state to form the intermediate source line BSL containing polysilicon or the like.

Accordingly, a portion of the channel layer CN of the pillar PL is connected to the source line SL on the side surface via the intermediate source line BSL.

Here, in the stepped region SR (not illustrated), gap layer GPs is not formed between the lower source line DSLa and the upper source line DSLb. Therefore, for example, the dummy layer MEd of the columnar portions HRm and HRt is not removed, and the intermediate source line BSL is not formed.

It is preferable that the columnar portions HRm and HRt, which are dummy pillars, have no electrical connection with the source line SL. As described above, in the stepped region SR except for the memory region MR, by disposing the intermediate insulating layer SCO instead of the intermediate sacrifice layer SCN between the lower source line DSLa and the upper source line DSLb, the columnar portions HRm and HRt are prevented from being electrically connected with the source line SL.

As illustrated in FIG. 16A, the insulating layer 54s on the sidewall of the slit ST is once removed.

As illustrated in FIG. 16B, a removing liquid for the insulating layer NL such as hot phosphoric acid is poured into the stacked bodies LMsa and LMsb from the slit ST to remove the insulating layer NL of the stacked bodies LMsa and LMsb. Accordingly, stacked bodies LMga and LMgb including a plurality of gap layers GP from which the insulating layer NL between the insulating layers OL is removed are formed.

It should be noted that the stacked bodies LMga and LMgb including the plurality of gap layers GP have a fragile structure. In the region that later becomes the memory region MR, the plurality of pillars PL support the fragile stacked bodies LMga and LMgb. On the other hand, in the stepped portions SPss, SPsb, and SPsa, the plurality of columnar portions HRm, HRt, and HRs support the stacked bodies LMga and LMgb. In such configurations, the columnar portions HRm and HRt including the dummy layer CNd, which is a semiconductor layer or the like having high Young's modulus, can support the stacked bodies LMga and LMgb more firmly.

Such support structure of the pillar PL and the columnar portions HRm, HRt, and HRs prevents bending of the remaining insulating layer OL and distortion or collapsing of the insulating layer OL while supporting the stacked bodies LMga and LMgb.

As illustrated in FIG. 16C, a raw material gas of a conductive material such as tungsten or molybdenum is injected into the stacked bodies LMga and LMgb from the slit ST, and thus, the gap layer GP of the stacked bodies LMga and LMgb is filled with the conductive material to form the plurality of word lines WL and the like. Accordingly, the stacked body LM including the stacked bodies LMa and LMb is formed in which the plurality of word lines WL and the like and the plurality of insulating layers OL are alternately stacked one layer by one layer.

It should be noted that the uppermost and the second uppermost conductive layer 29 of the stacked body LMb are partitioned into patterns of the plurality of select gate lines SGD by forming the separation layer SHE penetrating the uppermost and the second uppermost conductive layer 29 later.

As described above, the process of forming the intermediate source line BSL from the intermediate sacrifice layer SCN and the process of forming the word line WL from the insulating layer NL are also called replacement processes.

After that, the slit ST is filled with the insulating layer 54 to form the plate-like portion PT. By forming a groove penetrating one or the plurality of conductive layers 29 including the uppermost conductive layer 29 of the stacked body LMb and filling the groove with the insulating layer 56, the separation layer SHE partitioning the conductive layers 29 into patterns of the select gate lines SGD is formed.

The plurality of contact holes are formed collectively to penetrate the insulating layer 51 and reach the word lines WL and the select gate lines SGD and SGS configuring each step of the stepped portions SPs, SPb, and SPa, respectively, and the insulating layer 55 and the conductive layer 25 are formed within the contact hole. Accordingly, the contacts CC respectively connected to the plurality of word lines WL and the select gate lines SGD and SGS are formed.

Subsequently, the insulating layer 52 is formed on the upper surface of the stacked body LM and the upper surface of the insulating layer 51 covering the stepped region SR, and the plug V0 penetrates the insulating layer 52 and to be connected to the contact CC. The plug CH penetrates the insulating layer 52 and to be connected to the pillar PL. The insulating layer 53 is formed on the insulating layer 52, and the upper layer wiring MX, the bit line BL, and the like connected to the plugs V0 and CH are formed. On the upper surface of the insulating layer 53, electrode pads and the like are formed for electrical connection with the peripheral circuit CBA.

It should be noted that the plugs V0 and CH, the upper layer wiring MX, the bit line BL, and the like may be formed collectively by using, for example, a dual damascene method.

The peripheral circuit CBA is formed on the semiconductor substrate SB that is separated from the supporting substrate SS on which the stacked body LM is formed, and covered with the insulating layer 40. In the insulating layer 40, contacts, vias, wiring, and the like lead out the peripheral circuit CBA to the surface of the insulating layer 40 and are connected to electrode pads, or the like formed on the upper surface of the insulating layer 40.

Subsequently, the supporting substrate SS and the semiconductor substrate SB are bonded to each other with the respective insulating layers 50 and 40, and the electrode pads in the insulating layers 50 and 40 are connected. After that, the supporting substrate SS is polished and removed to expose the source line SL, and the electrode film EL is connected via the insulating layer 60 in which the plug PG is formed.

By the above processing, the semiconductor storage device 1 of the first embodiment is manufactured.

### (Overview)

In the process for manufacturing the semiconductor storage device such as a three-dimensional nonvolatile memory, the sacrifice layer within the stacked body may be replaced with the conductive layer to form the stacked body in which the conductive layer and the insulating layer are stacked. Here, the columnar portion may be disposed, for example, in the stepped region, to support the fragile stacked body including the plurality of gap layers during the replacement process. The columnar portion has the structure in which, for example, the hole penetrating the stacked body is filled with the insulating layer such as a silicon oxide layer.

However, when the columnar portion is made of the insulating layer or the like, the insulating layer configuring the columnar portion may contract due to thermal treatment in the following manufacturing process. Due to contraction of the plurality of columnar portions, the entire region in which the columnar portions are disposed may sink in the stacking direction of the stacked body compared to other regions such as the memory region supported by the pillars. In other words, the upper surface of the semiconductor storage device that is being manufactured becomes uneven.

Accordingly, in a process or the like using lithography technology, for example, the aim may not be accurate in a sunken region, and normal exposure may not be performed. For example, in the process of polishing and removing the conductive material buried in the hole or groove from the upper surface of the stacked body, residual conductive material may be left in the sunken region.

Therefore, it is conceivable that the columnar portions are configured with a material having higher Young's modulus and being harder than, for example, a silicon oxide layer. Here, for example, when the layer structure of the columnar portion is same as the layer structure of the pillar including the channel layer or the like having high Young's modulus, the columnar portion and the pillar can be formed collectively and conveniently.

However, when forming the slit for performing the replacement process on the stacked body, or when forming the contact hole connected to the word line and the like in the stepped region, the slit or the contact hole may be in contact with the columnar portion.

The contact between the slit and the columnar portion may be caused by misalignment when forming the slit or the columnar portion, expansion of the width of the slit in the insulating layer covering the stepped portion, or incline of the columnar portion due to stress acting between the respective components of the semiconductor storage device.

The contact between the contact hole and the columnar portion may be caused by misalignment when forming the contact hole or the columnar portion or incline of the contact hole or the columnar portion due to stress acting between the respective components of the semiconductor storage device.

As described above, for example, when the columnar portion has the same layer structure as the pillar, the problem of the decrease in breakdown voltage between the plurality of word lines occurs due to the contact between the slit or the contact hole and the columnar portion.

That is, the same type of material as the sacrifice layer to be replaced when forming the stacked body including the plurality of conductive layers may be used for the charge storage layer of the pillar. If the columnar portion contains a nitride layer or the like corresponding to the charge storage layer, when forming the slits for performing the replacement process on the stacked body, there is a concern that the nitride layer of the columnar portion is exposed into the slit due to the contact between the slit and the columnar portion. Here, when the replacement process is performed through the slit, the nitride layer of the columnar portion will also be replaced with the conductive layer through the exposed portion, and there is a concern that the breakdown voltage between the plurality of word lines becomes insufficient.

There is a concern that the formation conditions for the contact hole have low selectivity with respect to the nitride layer, and the nitride layer in the columnar portion is removed due to contact with the contact hole. After that, in some cases, when the conductive layer is filled with the contact hole, the gap in the columnar portion formed when the nitride layer is removed is also filled with the conductive layer, and thus, the breakdown voltage between the plurality of word lines becomes insufficient.

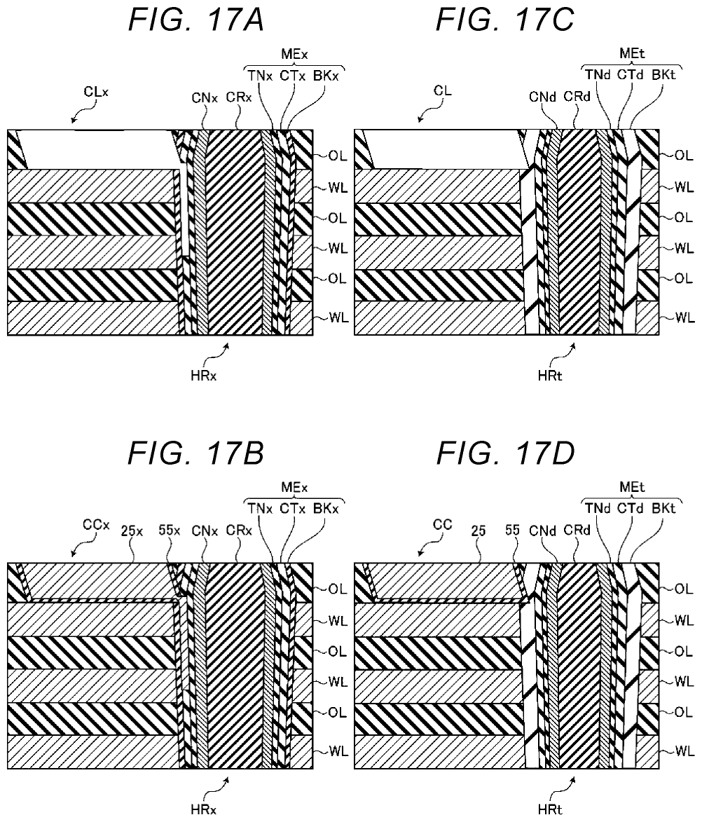

According to the semiconductor storage device 1 of the first embodiment, the columnar portion HRt includes the dummy layer BKt that is thicker than the block insulating layer BK of the pillar PL. Accordingly, even when, for example, contact with the contact CC occurs, the dummy layer CTd of the columnar portion HRt, which is a silicon nitride layer, is not removed. The situation is illustrated in FIGS. 17A to 17D.

FIGS. 17A to 17D are cross-sectional views illustrating an example where the contact holes CL being in contact with columnar portions HRt and HRx according to the first embodiment and Comparative Example are formed.

As illustrated in FIG. 17A, the columnar portion HRx of Comparative Example includes dummy layers MEx, CNx, and CRx corresponding to each layer of the pillar PL. All dummy layers TNx, CTx, and BKx provided in the dummy layer MEx of the columnar portion HRx have approximately the same thickness as, for example, the tunnel insulating layer TN, the charge storage layer CT, and the block insulating layer BK of the pillar PL.

When the contact hole CLx is contact with the columnar portion HRx, the contact hole CLx breaks through the relatively thin dummy layer BKx of the columnar portion HRx to reach the dummy layer CTx, which is a silicon nitride layer or the like. As described above, since the formation conditions for the contact hole CLx may have low selectivity with respect to a silicon nitride layer, when the contact hole CLx reaches the dummy layer CTx, etching and removing of the dummy layer CTx is proceeded in the depth direction within the columnar portion HRx.

As illustrated in FIG. 17B, a contact CCx is formed by sequentially forming an insulating layer 55x and a conductive layer 25x within a contact hole CLx. Here, in some cases, the gap in the columnar portion HRx formed by removing the dummy layer CTx is filled with a portion of the conductive layer 25x. The conductive layer 25x extends in the depth direction within the columnar portion HRx across not only the word line WL to which the contact CCx is to be connected but also the height positions of the plurality of word lines WL. Therefore, the breakdown voltage between the plurality of word lines WL becomes insufficient.

As illustrated in FIG. 17C, the columnar portion HRt of the first embodiment has the relatively thick dummy layer BKt. Therefore, even when the contact hole CL is in contact with the columnar portion HRt, the contact hole CL remains within the relatively thick dummy layer BKt of the columnar portion HRt and thus does not reach the dummy layer CTd.

As illustrated in FIG. 17D, even when the contact CC is formed by sequentially forming the insulating layer 55 and the conductive layer 25 within the contact hole CL, since the conductive layer 25 of the contact CC does not enter into the columnar portion HRt, the breakdown voltage between the plurality of word lines WL is maintained.

As such, according to the above configuration, the formation defects of the contact CC due to contact between the contact CC and the columnar portion HRt can be prevented.

According to the semiconductor storage device 1 of the first embodiment, the columnar portion HRm includes the dummy layer BKd that is thinner than the dummy layer BKt of the columnar portion HRt. In the stepped portion SPs where the columnar portion HRm is disposed, the contact CC is connected to the select gate line SGD disposed at the relatively shallow position of the stacked body LM. Therefore, the risk of contact between the columnar portion HRm and the contact CC is low, and the columnar portion HRm can include the relatively thin dummy layer BKd.

According to the semiconductor storage device 1 of the first embodiment, on both sides of the plurality of plate-like portions PT in the Y direction at the positions overlapping with the stepped portion SPa in the stacking direction, the plurality of columnar portions HRs are located in the direction along the X direction adjacent to the plurality of plate-like portions PT.

As described above, in the stepped portions SPb and SPa where the word line WL and the select gate line SGS on the lower layer side of the stacked body LM are processed into a stepped shape, the curvature of the taper shape or the bowing shape of the plate-like portion PT increases, and thus, the width of the plate-like portion PT in the Y direction increases. Therefore, the columnar portion HRs, which is a single insulating layer 57 or the like, is disposed at the position adjacent to the plate-like portion PT. Accordingly, the stacked bodies LMga and LMgb can be supported by the columnar portion HRs while allowing interference with the plate-like portion PT.

According to the method for manufacturing the semiconductor storage device 1 of the first embodiment, the insulating layer BKb covering the sidewalls of the memory hole MH and the holes HL of the stepped portions SPsb and SPsa is formed, and thus, the thickness of the insulating layer BKb covering the sidewall of the memory hole MH is reduced. Accordingly, the dummy layer BKt of the columnar portion HRt can be thicker than the block insulating layer BK of the pillar PL.

According to the method for manufacturing the semiconductor storage device 1 of the first embodiment, after the insulating layer BKb is formed in the memory hole MH, the formation of the insulating layer in the holes HL of the stepped portions SPsb and SPsa is continued, and the insulating layer BKt in the hole HL is thicker than the insulating layer BKb inside the memory hole MH.

As such, in addition to slimming of the insulating layer BKb in the memory hole MH, by additionally forming the insulating layer in the holes HL of the stepped portions SPsb and SPsa, the layer thickness difference of the dummy layer BKt of the columnar portion HRt with respect to the block insulating layer BK of the pillar PL can be freely controlled. Therefore, the dummy layer BKt can have a desired thickness without depending on the thickness of the block insulating layer BK of the pillar PL.

### Modified Example 1

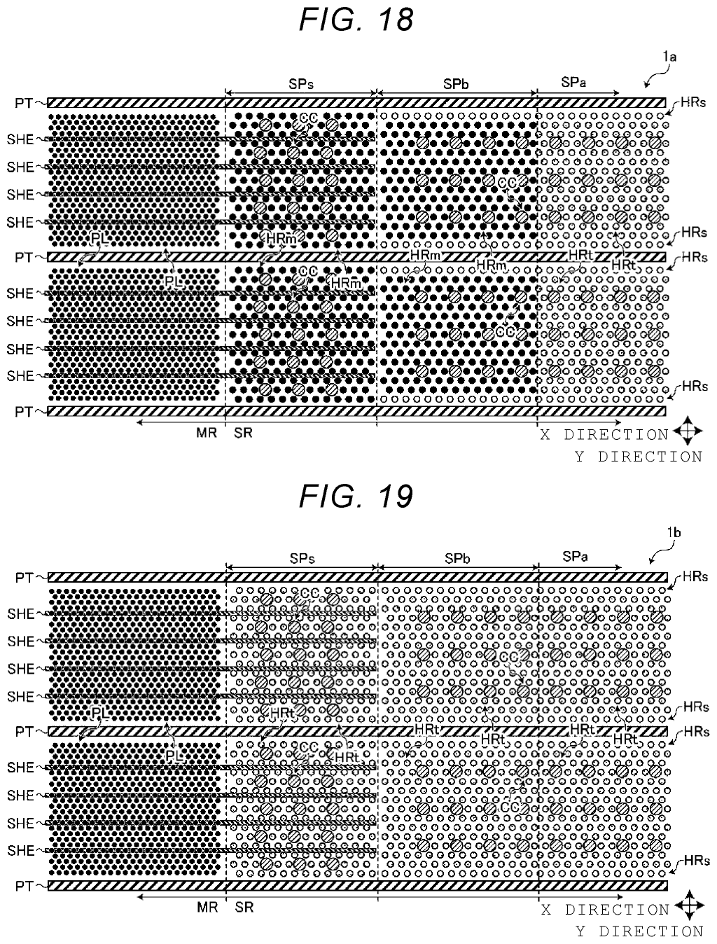

Next, semiconductor storage devices 1a and 1b of Modified Example 1 of the first embodiment will be described with reference to FIGS. 18 and 19. In the semiconductor storage devices 1a and 1b of Modified Example 1, the arrangement positions of the columnar portions HRm and HRt in the stepped portions SPs, SPb and SPa are different from those in the first embodiment described above.

In the following drawings, the same configurations as those in the first embodiment described above are denoted by the same reference numerals, and the description thereof may be omitted.

In the first embodiment described above, the columnar portion HRm is disposed in the stepped portion SPs where the risk of contact with the contact CC is relatively low, and the columnar portion HRt is disposed in the stepped portion SPb and SPa where the risk of contact with the contact CC is relatively high.

However, depending on the degree of width expansion of the plate-like portion PT in the insulating layer 51 in the Y direction, due to the level of stress and the like between the respective components of the semiconductor storage device 1, the risk of contact between the columnar portions HRm and HRt in the respective stepped portions SPs, SPb, and SPa and the contact CC can vary. Therefore, the arrangement positions of the columnar portions HRm and HRt may be changed as appropriate according to the risk of contact with the contact CC.

FIG. 18 is an XY cross-sectional view illustrating a configuration example of the semiconductor storage device 1a according to Modified Example 1 of the first embodiment. More specifically, FIG. 18 is an XY cross-sectional view of a partial region of the stacked body LM at the height position of the select gate line SGD of the semiconductor storage device 1a.

As illustrated in FIG. 18, when the risk of contact with the contact CC in the stepped portion SPb is relatively low, the columnar portion HRm may be disposed in the stepped portion SPb in addition to the stepped portion SPs. Here, similarly to the first embodiment described above, for example, the columnar portion HRs may be disposed at a position adjacent to the plate-like portion PT, and the columnar portions HRm may be dispersed and located over the entire stepped portion SPb except for the position of the columnar portion HRS.

FIG. 19 is an XY cross-sectional view illustrating another configuration example of the semiconductor storage device 1b according to Modified Example 1 of the first embodiment. More specifically, FIG. 19 is an XY cross-sectional view of a partial region of the stacked body LM at the height position of the select gate line SGD of the semiconductor storage device 1b.

As illustrated in FIG. 19, in cases where the risk of contact with the contact CC in the stepped portion SPs is relatively high, the columnar portion HRt may be disposed in the stepped portion SPs in addition to the stepped portions SPb and SPa. Here, similarly to the first embodiment described above, the columnar portions HRt can be dispersed and located over the entire stepped portion SPs, for example, including the position adjacent to the plate-like portion PT.

It should be noted that in the example illustrated in FIG. 19, the columnar portions HRt having the same configuration are located over the entire stepped portions SPs, SPb, and SPa, except for the partial region adjacent to the plate-like portion PT. Accordingly, the process of differently creating the columnar portion HRm and the columnar portion HRt is not required, and the manufacturing process of the semiconductor storage device 1b can be simplified.

Therefore, the columnar portions HRt may be located over the entire stepped portions SPs, SPb, and SPa, not limited to the region where the risk of contact with the contact CC in the stepped portion SPs is relatively high.

According to the semiconductor storage device 1a of Modified Example 1, the plurality of columnar portions HRm are dispersed and located in the plurality of stepped portions SPs and SPb of the stacked body LMb including the stepped portion SPs where one or more select gate lines SGD are processed into a stepped shape. Accordingly, the same effects as the semiconductor storage device 1 of the first embodiment described above are achieved.

According to the semiconductor storage device 1b of Modified Example 1, the plurality of columnar portions HRt are dispersed and located in the stepped portions SPs, SPb, and SPa except for the region adjacent to the plurality of plate-like portions PT on both sides in the Y direction. Accordingly, the same effects as the semiconductor storage device 1 of the first embodiment described above are achieved.

### Modified Example 2

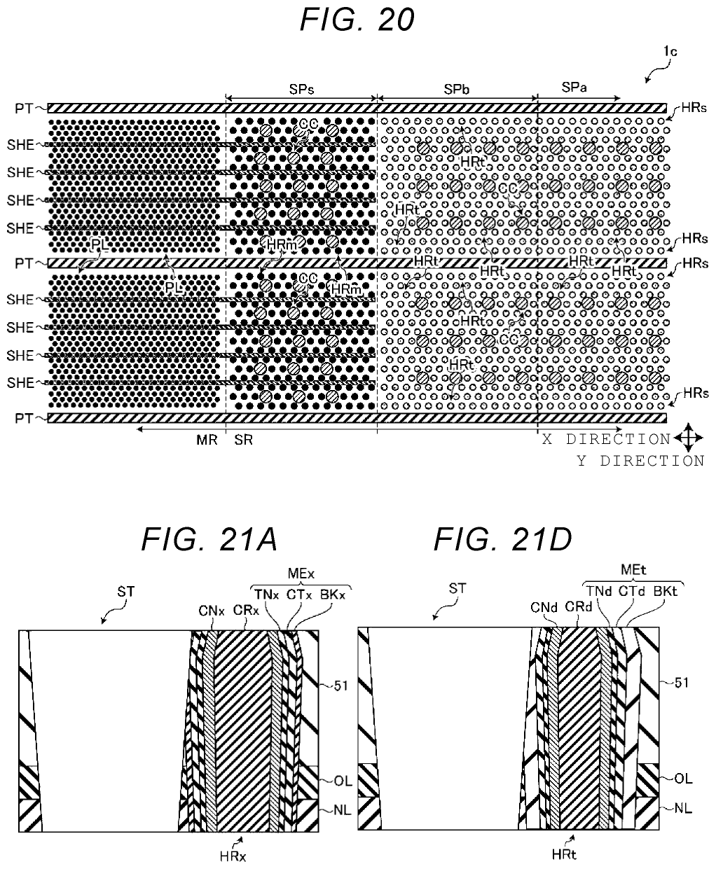

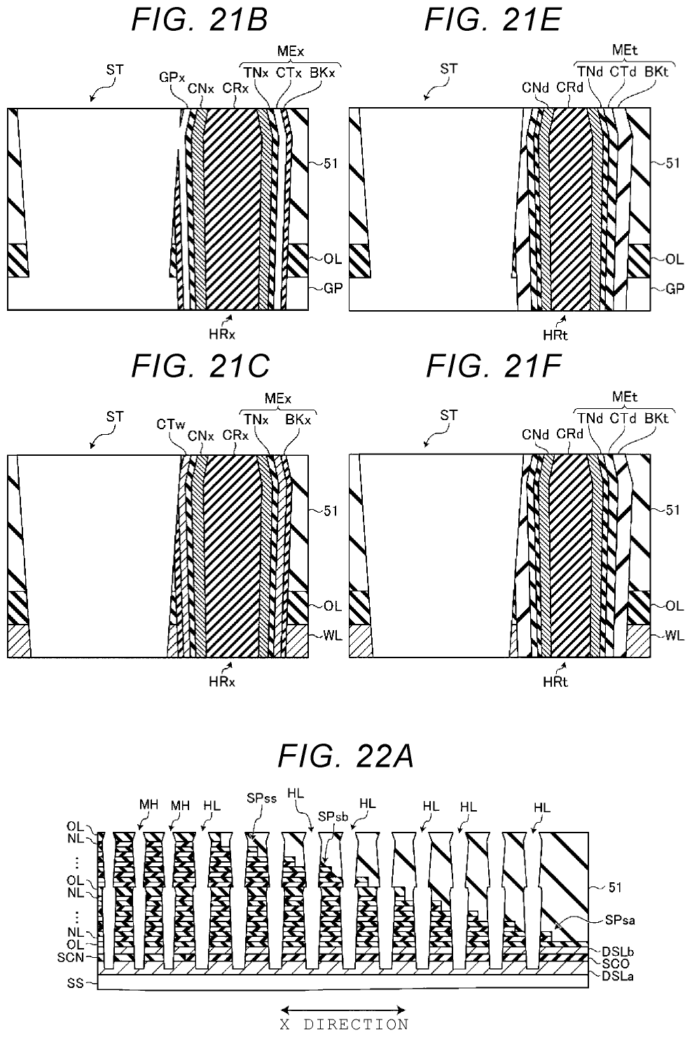

Next, a semiconductor storage device 1c of Modified Example 2 of the first embodiment will be described with reference to FIGS. 20 to 21F. The semiconductor storage device 1c of Modified Example 2 is different from the first embodiment described above in that the columnar portions HRt are dispersed and located over the entire stepped portion SPb.

In the following drawings, the same configurations as those in the first embodiment described above are denoted by the same reference numerals, and the description thereof may be omitted.

In the first embodiment described above, the plate-like portion PT is expanded in the Y direction, and the columnar portion HRs is disposed at the position adjacent to the plate-like portion PT in the stepped portions SPb and SPa where the risk of contact with the plate-like portion PT is high. However, as described above, even with the columnar portion HRt including the relatively thick dummy layer BKt, the problems caused by contact with the plate-like portion PT can be prevented.

Therefore, the columnar portion HRt can also be disposed at the position adjacent to the plate-like portion PT in the stepped portion SPb or in both the stepped portions SPb and SPa.

FIG. 20 is an XY cross-sectional view illustrating a configuration example of the semiconductor storage device 1c according to Modified Example 2 of the first embodiment. More specifically, FIG. 20 is an XY cross-sectional view of a partial region of the stacked body LM at the height position of the select gate line SGD of the semiconductor storage device 1c.

As illustrated in FIG. 20, in the stepped portion SPb, the columnar portions HRs are not disposed at the positions adjacent to the plate-like portion PT, but the columnar portions HRt are dispersed and located over the entire stepped portion SPb.

As such, FIG. 20 illustrates an example where the columnar portion HRs is not disposed in the stepped portion SPb, but is located in the stepped portion SPa where the risk of contact with the plate-like portion PT is highest. However, according to the degree of expansion of the plate-like portion PT, the level of risk of contact with the plate-like portion PT, and the like, the columnar portion HRs is not also disposed in the stepped portion SPa, and the columnar portion HRt can be located over the entire stepped portion SPa.

The semiconductor storage device 1c of Modified Example 2 includes the plurality of columnar portions HRt dispersed and located in the stepped portion SPb including positions adjacent to the plurality of plate-like portions PT on both sides in the Y direction. With such configuration as well, the problems caused by contact between the columnar portion HRt and the slit ST can be prevented. The situation is illustrated in FIGS. 21A to 21F.

FIGS. 21A to 21F are cross-sectional views illustrating an example where the slits ST being in contact with the columnar portions HRt and HRx are formed according to Modified Example 2 of the first embodiment and Comparative Example.

As illustrated in FIG. 21A, when the slit ST is in contact with the columnar portion HRx of Comparative Example, the slit ST breaks through the relatively thin dummy layer BKx of the columnar portion HRx to reach the dummy layer CTx which is a silicon nitride layer or the like.

As illustrated in FIG. 21B, a removing liquid such as hot phosphoric acid is poured into the slit ST to remove the insulating layer NL of the stacked body before replacement. Here, when the dummy layer BKx of the columnar portion HRx and the slit ST are in contact with each other, the removing liquid also removes a portion or the entire dummy layer BKx in the columnar portion HRX. Accordingly, a gap GPx may be formed within the columnar portion HRX.

As illustrated in FIG. 21C, a raw material gas of a conductive material is injected into the slit ST to fill the gap layer GP formed by removing the insulating layer NL. Accordingly, the word line WL and the like is formed. Here, when the columnar portion HRx and the slit ST are in contact with each other, and the gap GPx from which the dummy layer BKx is removed is formed within the columnar portion HRx, a conductive layer CTw is also formed in the gap GPx. Such conductive layer CTw extends in the depth direction within the columnar portion HRx across the height positions of the plurality of word lines WL. Therefore, the breakdown voltage will be insufficient between the plurality of word lines WL.

As illustrated in FIG. 21D, the columnar portion HRt of Modified Example 2 includes the relatively thick dummy layer BKt, similarly to the columnar portion HRt of the first embodiment described above. Therefore, even when the slit ST is in contact with the columnar portion HRt, the slit ST remains within the relatively thick dummy layer BKt of the columnar portion HRt, and thus can be prevented from reaching the dummy layer CTd.

As illustrated in FIG. 21E, a removing liquid such as hot phosphoric acid is poured into the slit ST to remove the insulating layer NL of the stacked body before replacement. Here, when the slit ST does not reach the dummy layer CTd of the columnar portion HRt, the dummy layer CTd is not removed.

As illustrated in FIG. 21F, a raw material gas of a conductive material is injected into the slit ST to fill the gap layer GP formed by removing the insulating layer NL. Here, since no gaps or the like are formed within the columnar portion HRt, and since the slit ST does not even reach the dummy layer CTd of the columnar portion HRt, the conductive layer is not formed within the columnar portion HRt. Therefore, the breakdown voltage between the plurality of word lines WL is maintained.

According to the semiconductor storage device 1c of Modified Example 2, the same effects as the semiconductor storage device 1 of the first embodiment described above are achieved.

### Modified Example 3

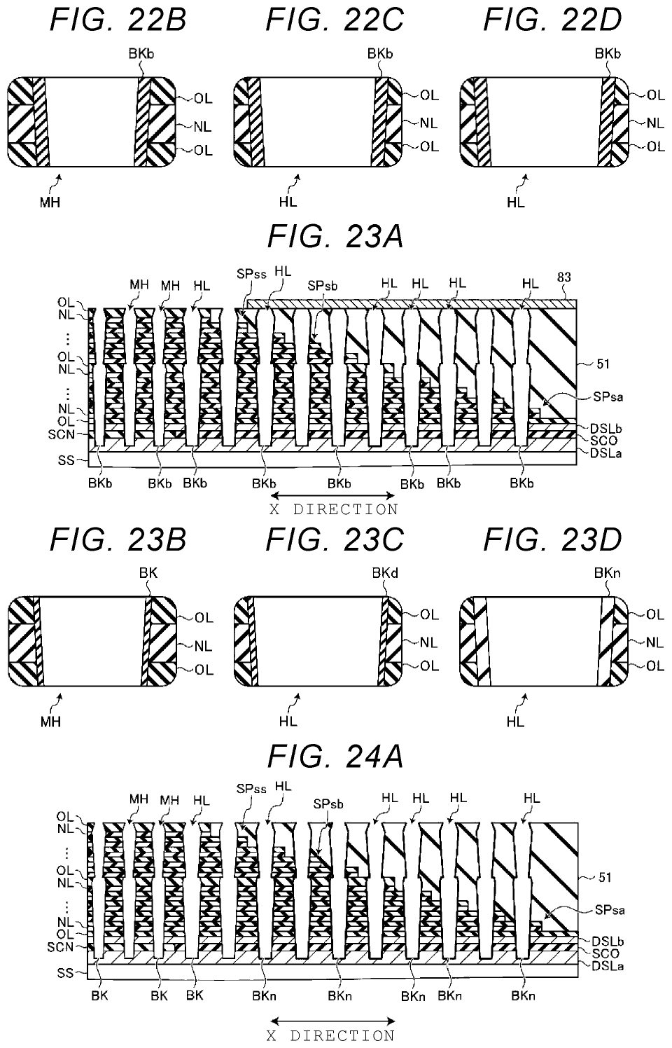

Next, a semiconductor storage device according to Modified Example 3 of the first embodiment will be described with reference to FIGS. 22A to 24Ed. The semiconductor storage device of Modified Example 3 is different from that of the first embodiment described above in the manufacturing method.

In the following drawings, the same configurations as those in the first embodiment described above are denoted by the same reference numerals, and the description thereof may be omitted.

In the first embodiment described above, silicon oxide is additionally formed when forming the dummy layer BKt of the columnar portion HRt. However, even when simply skipping the slimming of the insulating layer BKb without additionally forming silicon oxide, a columnar portion including a dummy layer that is thicker than the block insulating layer BK of the pillar PL on the outer periphery can be formed. A detailed flow of the manufacturing method is illustrated below.

FIGS. 22A to 24Ed are diagrams sequentially illustrating a portion of a procedure of a method for manufacturing a semiconductor storage device according to Modified Example 3 of the first embodiment.

FIGS. 22A and 23A are cross-sectional views along the X direction of regions that later become the memory region MR and the stepped region SR. FIGS. 22B to 22D and FIGS. 23B to 23D are enlarged cross-sectional views in the Y direction of the memory hole MH, the hole HL to be processed into the columnar portion HRm, and the hole HL as the second hole to be processed into a columnar portion HRn, respectively, at the freely selected height position of the insulating layer NL.

The columnar portion HRn is the structure that the semiconductor storage device of Modified Example 3 includes instead of the columnar portion HRt of the first embodiment described above.

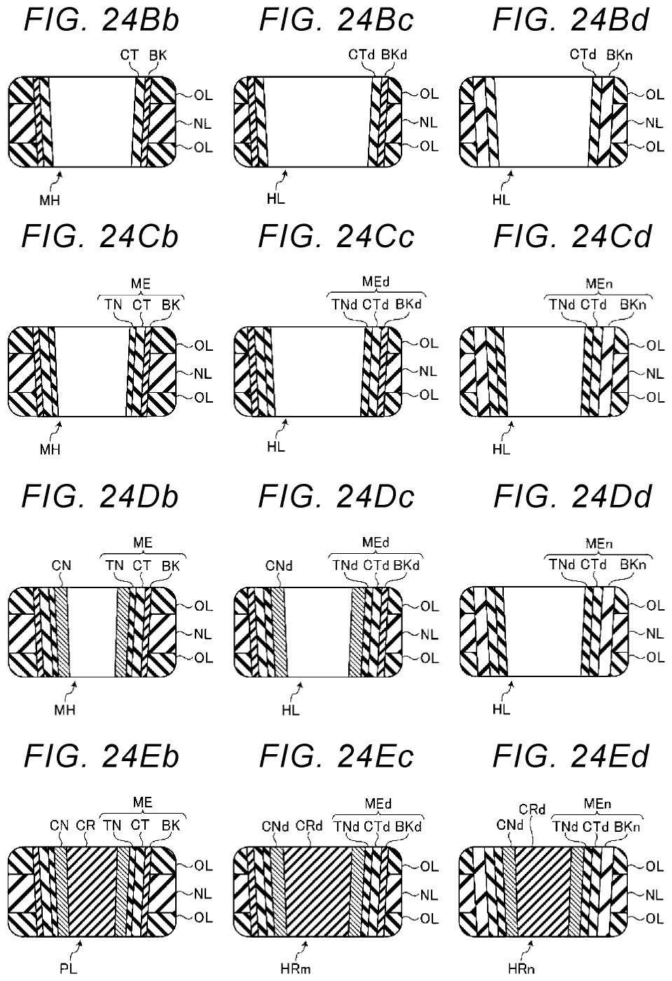

Similarly, FIG. 24A is a cross-sectional view along the X direction of the regions that later become the memory region MR and the stepped region SR. FIGS. 24Bb to 24Eb, FIGS. 24Bc to 24Ec, and FIGS. 24Bd to 24Ed are enlarged cross-sectional views in the Y direction of the memory hole MH, the hole HL to be processed into the columnar portion HRm, and the hole HL to be processed into the columnar portion HRn, respectively, at the freely selected height positions of the insulating layer NL.

FIG. 22A corresponds to FIG. 9A of the above-described first embodiment, and the holes HL formed in the stepped portions SPss, SPsb, and SPsa and the memory hole formed in the region that later becomes the memory region MR are opened on the upper surfaces of the stacked body LMsb and the insulating layer 51, respectively.

As illustrated in FIGS. 22B to 22D, the insulating layer BKb such as a silicon oxide layer is formed on the sidewalls of the memory hole MH and the hole HL opened on the upper surface of the stacked body LMsb.

As illustrated in FIG. 23A, the CVD-carbon layer 83 covering the holes HL formed in the stepped portions SPsb and SPsa is formed. The plurality of memory holes MH and the hole HL formed in the stepped portion SPss are exposed from the CVD-carbon layer 83.

As illustrated in FIGS. 23B and 23C, the insulating layer BKb on the sidewalls of the memory hole MH exposed from the CVD-carbon layer 83 and the hole HL formed in the stepped portion SPss and exposed from the CVD-carbon layer 83 is slimmed to be thinned.

Accordingly, the block insulating layer BK is formed on the sidewall of the memory hole MH. The dummy layer BKd is formed on the sidewall of the hole HL of the stepped portion SPss.

As illustrated in FIG. 23D, the holes HL formed in the stepped portions SPsb and SPsa and covered with the CVD-carbon layer 83 are not subjected to the slimming process of the insulating layer BKb. Therefore, the insulating layer BKb is maintained with the original layer thickness in the holes HL of the stepped portions SPsb and SPsa. That is, in the columnar portion HRn, the insulating layer BKb directly becomes a dummy layer BKn.

After that, the CVD-carbon layer 83 is removed by, for example, ashing using oxygen plasma.

As described above, due to the slimming process of the insulating layer BKb in the memory hole MH and the hole HL of the stepped portion SPss, the predetermined layer thickness difference is generated between the dummy layer BKn, the block insulating layer BK, and the dummy layer BKd.

As an example, when the diameter of the lower end of the hole HLb penetrating the stacked body LMsb is 110 nm, similarly to the first embodiment described above, it is preferable that the dummy layer BKn is thicker than the block insulating layer BK and the dummy layer BKd in a range of 5 nm or more and 10 nm or less.

As illustrated in FIG. 24A, after the CVD-carbon layer 83 is removed, the memory hole MH in which the block insulating layer BK is formed and the hole HL in which the dummy layers BKd and BKn are formed, respectively, open again on the upper surface of the stacked body LMsb.

As illustrated in FIGS. 24Bb to 24Bd, a silicon nitride layer or the like is formed on each of the sidewalls of the memory hole MH and the hole HL. Accordingly, the charge storage layer CT is formed on the sidewall of the memory hole MH while interposing the block insulating layer BK therebetween. The dummy layer CTd is formed on the sidewall of the hole HL while interposing the dummy layer BKd or the dummy layer BKn therebetween, respectively.

As illustrated in FIGS. 24Cb to 24Cd, a silicon oxide layer or the like is formed on the sidewall of each of the memory hole MH and the hole HL.

Accordingly, the tunnel insulating layer TN is formed on the sidewall of the memory hole MH while interposing the block insulating layer BK and the charge storage layer CT therebetween. Accordingly, the memory layer ME including the block insulating layer BK, the charge storage layer CT, and the tunnel insulating layer TN is formed on the sidewall of the memory hole MH.

The dummy layer TNd is formed on the sidewall of the hole HL while interposing the dummy layer BKd or the dummy layer BKn, and the dummy layer CTd therebetween. Accordingly, each of the dummy layer MEd and a dummy layer MEn including the dummy layer BKd or the dummy layer BKn, the dummy layer CTd, and the dummy layer TNd is formed on the sidewall of the hole HL.

As illustrated in FIGS. 24Db to 24Dd, a semiconductor layer such as a polysilicon layer or an amorphous silicon layer is formed on each of the sidewalls of the memory hole MH and the hole HL. Accordingly, the channel layer CN is formed on the sidewall of the memory hole MH while interposing the memory layer ME therebetween. The dummy layer CNd is formed on the sidewall of the hole HL while interposing the dummy layer MEd or the dummy layer Men therebetween, respectively.

As illustrated in FIGS. 24Eb to 24Ed, the gaps remaining in the memory hole MH and the hole HL are filled with a silicon oxide layer or the like.

By the above processing, the core layer CR is formed within the memory hole MH, and the dummy layer CRd is formed within the hole HL.

After that, by performing the process illustrated in FIGS. 14A to 14C on the memory hole MH and the hole HL, the pillar PL including the cap CP at the upper end and the columnar portions HRm and HRn each including the dummy layer CPd at the upper end are formed

However, in Modified Example 3 as well, the formation of the dummy layer CPd in the hole HL may be skipped, and the columnar portions HRm and HRn may be formed without the dummy layer CPd.

It should be noted that in Modified Example 3, the dummy layer BKn of the columnar portion HRn is formed without additionally forming a silicon oxide layer or the like. Therefore, in the process illustrated in FIGS. 22B to 22D described above, the insulating layer BKb may be thicker than that in the first embodiment described above. Even then, when the dummy layers CTd, TNd, CNd, and the like are sequentially formed in the hole HL in which the thicker dummy layer BKn is formed, the lower end of the hole HLb is closed, and thus, the voids or the like are not formed within the hole HLa.

As such, by thickly forming the insulating layer BKb in FIG. 22B, and performing slimming to obtain the block insulating layer BK having the predetermined thickness for the memory hole MH or the like, the layer thickness difference between the dummy layer BKd of the block insulating layer BK of the pillar PL and the columnar portion HRm, and the dummy layer BKn of the columnar portion HRn can be easily maintained at a desired value.

According to the semiconductor storage device of Modified Example 3, the same effects as the semiconductor storage device 1 of the above-described first embodiment are achieved.

### Second Embodiment

A second embodiment will be described in detail below with reference to the drawings. The second embodiment is different from the first embodiment in that columnar portions include the dummy layers of the outermost periphery corresponding to the block insulating layer BK of the pillar PL each having different thicknesses, and are disposed in each of the stepped portions SPs, SPb, and SPa.

In the following drawings, the same configurations as those in the first embodiment described above are denoted by the same reference numerals, and the description thereof may be omitted.

### (Configuration Example of Semiconductor Storage Device)

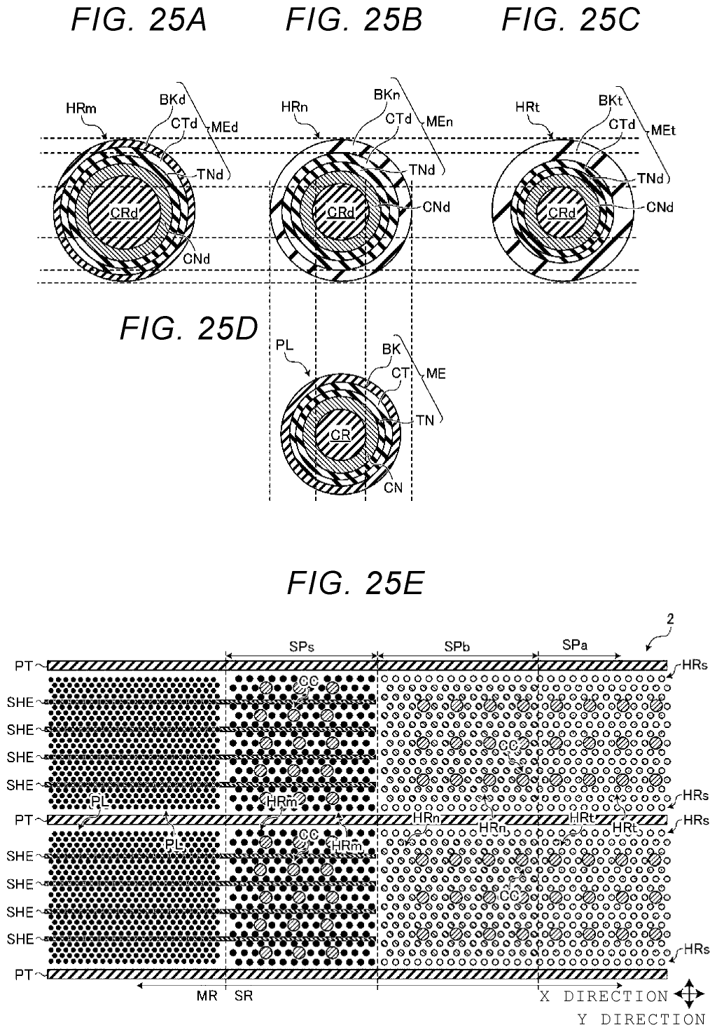

FIGS. 25A to 25E are diagrams illustrating a configuration example of a semiconductor storage device 2 according to the second embodiment.

More specifically, FIG. 25A is an XY cross-sectional view of the columnar portion HRm at the freely selected height position of the word line WL. FIG. 25B is an XY cross-sectional view of the columnar portion HRn at the same height position as the cross section illustrated in FIG. 25A. FIG. 25C is an XY cross-sectional view of the columnar portion HRt at the same height position as the cross sections illustrated in FIGS. 25A and 25B.

FIG. 25D is an XY cross-sectional view of the pillar PL at the same height position as the cross sections illustrated in FIGS. 25A to 25C.

FIG. 25E is an XY cross-sectional view of a partial region of the stacked body LM at the height of the select gate line SGD.

The semiconductor storage device 2 of the second embodiment has the same schematic configuration as that of the semiconductor storage device 1 of the first embodiment illustrated in FIG. 3 described above. The semiconductor storage device 2 has the same configuration as the semiconductor storage device 1 of the above-described first embodiment in the memory region MR. The semiconductor storage device 2 has the configuration similar to that of the semiconductor storage device 1 of the above-described first embodiment, except that the stepped region SR includes the columnar portion HRn in addition to the above-described columnar portions HRm, HRt, and HRs.

As illustrated in FIG. 25E, the semiconductor storage device 2 of the second embodiment includes the columnar portions HRm, HRn, HRt, and HRs located in the stepped region SR.

Similarly to the first embodiment described above, the columnar portions HRm are dispersed and located over, for example, the entire stepped portion SPs. Similarly to the first embodiment described above, the columnar portions HRs are located, for example, at positions adjacent to the plate-like portions PT on both sides of the plate-like portions PT in the Y direction, extending within the stepped portions SPb and SPa. The columnar portions HRt are dispersed and located over the entire stepped portion SPa except for the positions adjacent to the plate-like portion PT.

The columnar portions HRn serving as fifth pillars are dispersed and located over the entire stepped portion SPb except for the position adjacent to the plate-like portion PT. Here, the plurality of columnar portions HRn are located in, for example, a grid shape or a staggered shape when viewed from the stacking direction of the stacked body LM while avoiding interference with the contacts CC. Each columnar portion HRn has, for example, a circular shape, an elliptical shape, an oval shape, or the like as a cross-sectional shape in the direction along the XY plane.

Similarly to the other columnar portions HRm, HRt, and HRs, the columnar portion HRn also penetrates the insulating layer 51, the stacked bodies LMb and LMa, the upper source line DSLb, and the intermediate insulating layer SCO, to reach the lower source line DSLa.

The columnar portion HRn has a taper shape in which the diameter and cross-sectional area decrease from the upper layer side to the lower layer side in the portion penetrating the stacked body LMa and the portion penetrating the stacked body LMb, respectively. Alternatively, the columnar portion HRn has a bowing shape in which the diameter and cross-sectional area are maximized at a predetermined position between the upper layer side and the lower layer side in the portion penetrating the stacked body LMa and the portion penetrating the stacked body LMb, respectively.

As illustrated in FIGS. 25A to 25D, the pillar PL and the columnar portions HRm and HRt are configured similarly to the above-described first embodiment, and the thickness of each layer provided in the columnar portions HRm and HRt for each layer provided in the pillar PL are also the same as explained in the above-described first embodiment.

The columnar portion HRn disposed in the stepped portion SPb includes the dummy layer MEn corresponding to the memory layer ME of the pillar PL, the dummy layer CNd such as a semiconductor layer corresponding to the channel layer CN of the pillar PL, and the dummy layer CRd such as a silicon oxide layer corresponding to the core layer CR of the pillar PL in this order from the outer peripheral side. The columnar portion HRn may include a dummy layer such as a semiconductor layer corresponding to the cap layer CP of the pillar PL.

The dummy layer MEn of the columnar portion HRn includes the dummy layer BKn such as a silicon oxide layer corresponding to the block layer BK of the pillar PL, the dummy layer CTd such as a silicon nitride layer corresponding to the charge storage layer CT of the pillar PL, and the dummy layer TNd such as a silicon oxide layer corresponding to the tunnel insulating layer TN of the pillar PL in this order from the outer peripheral side.

The cross-sectional area and diameter of the columnar portion HRn in the direction along the XY plane are substantially equal to the cross-sectional area and diameter of the columnar portions HRm and HRt in the direction along the XY plane at the same height position of the stacked body LM. Therefore, the cross-sectional area and diameter of the columnar portion HRn in the direction along the XY plane are larger than the cross-sectional area and diameter of the pillar PL in the direction along the XY plane at the same height position of the stacked body LM.

The respective thicknesses of the dummy layers CTd, TNd, and CNd of the columnar portions HRn are substantially equal to the respective thicknesses of the corresponding dummy layers CTd, TNd, and CNd of the columnar portions HRm and HRt. Therefore, the respective thicknesses of the dummy layers CTd, TNd, and CNd of the columnar portion HRn are substantially equal to the respective thicknesses of the corresponding charge storage layer CT, tunnel insulating layer TN, and channel layer CN of the pillar PL.

On the other hand, the thickness of the dummy layer BKn as the third insulating layer of the columnar portion HRn is thicker than the thicknesses of the corresponding block insulating layer BK of the pillar PL and the corresponding dummy layer BKd of the columnar portion HRm, and is thinner than the thickness of the dummy layer BKt of the columnar portion HRt.

Herein, as an example, when the diameter of the lower end of the portion of the columnar portion HRn penetrating the stacked body LMb is 110 nm, it is preferable that the dummy layer BKn has the layer thickness difference with respect to the block insulating layer BK and the dummy layer BKd in a range of 5 nm or more and 10 nm or less and also have a predetermined layer thickness difference with respect to the dummy layer BKt.

Therefore, the cross-sectional area and diameter of the dummy layer CRd of the columnar portion HRt in the direction along the XY plane are smaller than the cross-sectional area and diameter of the core layer CR of the pillar PL and the dummy layer CRd of the columnar portion HRm, and is larger than the cross-sectional area and diameter of the dummy layer CRd of the columnar portion HRt.

As such, in the semiconductor storage device 2 of the second embodiment, among the stepped portions SPs, SPb, and SPa, when closer to the lower layer side where the risk of contact with the contact CC increases, the thicknesses of the dummy layers BKd, BKn, and BKt of the columnar portions HRm, HRn, and HRt disposed therein increases.

### (Method of Manufacturing Semiconductor Storage Device)

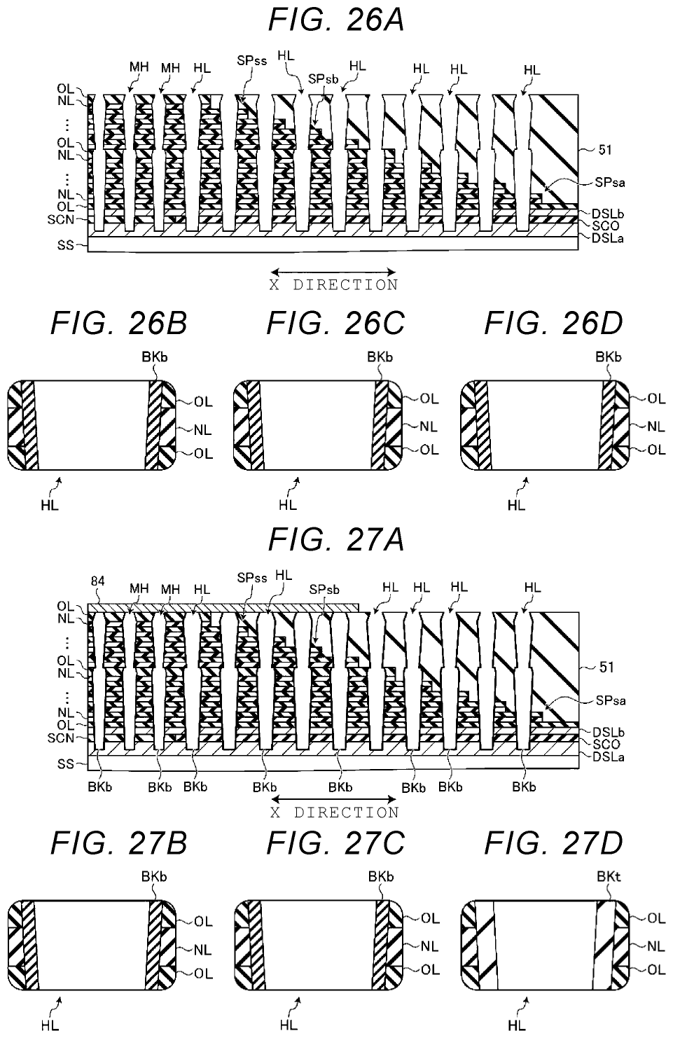

Next, the method of manufacturing the semiconductor storage device 2 of the second embodiment will be described with reference to FIGS. 26A to 29Ed.

The above-described columnar portions HRm, HRn, and HRt in which the respective dummy layers BKd, BKn, and BKt have different thicknesses can be formed by appropriately applying the methods illustrated in the above-described first embodiment and Modified Example 3. That is, according to the first embodiment and Modified Example 3 described above, the method of forming the dummy layer by slimming, the method of forming the dummy layer without slimming, and the method of forming the dummy layer by additionally forming a silicon oxide layer or the like without slimming may be adopted.

In the examples illustrated in FIGS. 26A to 29Ed below, the columnar portion HRm is formed by applying the method of forming the dummy layer by slimming, the columnar portion HRn is formed by applying the method of forming the dummy layer without slimming, and the columnar portion HRt is formed by forming the dummy layer by additionally forming a silicon oxide layer or the like without slimming.

FIGS. 26A to 29Ed are diagrams sequentially illustrating a portion of a procedure of a method for manufacturing the semiconductor storage device 2 according to the second embodiment.

FIGS. 26A, 27A and 28A are cross-sectional views along the X direction of regions that later become the memory region MR and the stepped region SR. FIGS. 26B to 26D, FIGS. 27B to 27D, and FIGS. 28B to 28D are enlarged cross-sectional views of the hole HL to be processed into the columnar portions HRm, the hole HL as a fifth hole to be processed into the columnar portion HRn, and the hole HL to be processed into the columnar portions HRt, respectively, in the Y direction at the freely selected height positions of the insulating layer NL, respectively.

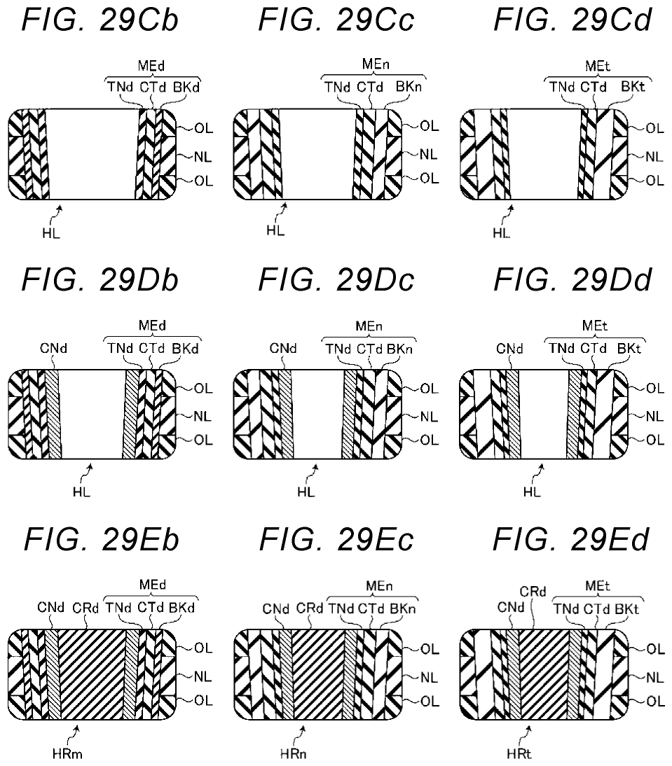

Similarly, FIG. 29A is a cross-sectional view along the X direction of the regions that later become the memory region MR and the stepped region SR. FIGS. 29Bb to 29Eb, FIGS. 29Bc to 29Ec, and FIGS. 29Bd to 29Ed are enlarged cross-sectional views of the hole HL to be processed into the columnar portion HRm, the hole HL to be processed into the columnar portion HRn, and the hole HL to be processed into the columnar portion HRt, respectively, t the freely selected respective height positions of the insulating layer NL.

FIG. 26A corresponds to FIG. 9A of the above-described first embodiment in which the holes HL formed in the stepped portions SPss, SPsb, and SPsa and the memory hole MH formed in the region that later becomes the memory region MR are opened on the upper surfaces of the stacked body LMsb and the insulating layer 51, respectively.

As illustrated in FIGS. 26B to 26D, the insulating layer BKb such as a silicon oxide layer is formed on the sidewall of the hole HL opened on the upper surface of the stacked body LMsb. Here, the insulating layer BKb is also formed on the sidewall of the memory hole MH (not illustrated).

As illustrated in FIG. 27A, a CVD-carbon layer 84 covers the plurality of memory holes MH and the holes HL formed in the stepped portions SPss and SPsb. The hole HL formed in the stepped portion SPsa is exposed from the CVD-carbon layer 84.

As illustrated in FIG. 27D, a silicon oxide layer or the like is further formed on the sidewall of the hole HL formed in the stepped portion SPsa and exposed from the CVD-carbon layer 84, and the dummy layer BKt thicker than the above-described insulating layer BKb is formed.

As illustrated in FIGS. 27A to 27C, additional silicon oxide layer or the like is not formed in the holes HL of the stepped portions SPss and SPsb covered with the CVD-carbon layer 84, and in the holes HL, the insulating layer BKb is maintained with the original layer thickness. Here, the insulating layer BKb with the original layer thickness is maintained also in the memory hole MH (not illustrated).

After that, the CVD-carbon layer 84 is removed by, for example, ashing using oxygen plasma.

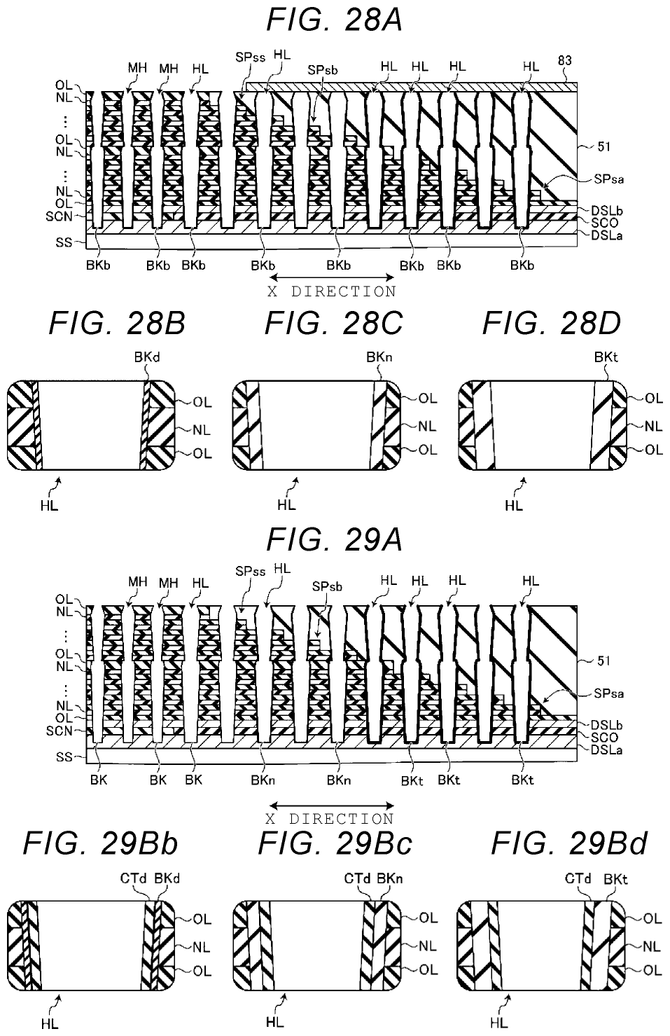

As illustrated in FIG. 28A, the CVD-carbon layer 83 covering the holes HL formed in the stepped portions SPsb and SPsa is formed. The plurality of memory holes MH and the hole HL formed in the stepped portion SPss are exposed from the CVD-carbon layer 83.

As illustrated in FIG. 28B, the insulating layer BKb on the sidewall of the hole HL formed in the stepped portion SPss and exposed from the CVD-carbon layer 83 is slimmed to be thinned. Here, the insulating layer BKb on the sidewall of the memory hole MH (not illustrated) is also slimmed.

Accordingly, the block insulating layer BK is formed on the sidewall of the memory hole MH. The dummy layer BKd is formed on the sidewall of the hole HL of the stepped portion SPss.

As illustrated in FIGS. 28C and 28D, the holes HL formed in the stepped portions SPsb and SPsa and covered with the CVD-carbon layer 83 are not subjected to the slimming process of the insulating layer BKb.

Therefore, the insulating layer BKb is maintained with the original layer thickness within the hole HL of the stepped portion SPsb. That is, in the columnar portion HRn, the insulating layer BKb directly becomes the dummy layer BKn. The dummy layer BKt, which is thicker than the insulating layer BKb, is maintained with the original layer thickness within the hole HL of the stepped portion SPsa.

After that, the CVD-carbon layer 83 is removed by, for example, ashing using oxygen plasma.

As described above, by the slimming process of the insulating layer BKb in the memory hole MH and the hole HL of the stepped portion SPss, the predetermined layer thickness difference occurs between the dummy layer BKn of the hole HL of the stepped portion SPsb, and the block insulating layer BK and the dummy layer BKd. Due to the additional formation of a silicon oxide layer and the like in the hole HL of the stepped portion SPsa, the predetermined layer thickness difference also occurs between the dummy layer BKn of the hole HL of the stepped portion SPsb and the dummy layer BKt of the hole HL of the stepped portion SPsa.

As an example, when the diameter of the lower end of the hole HLb penetrating the stacked body LMsb is 110 nm, it is preferable that the dummy layers BKn and BKt have a layer thickness difference in common with respect to the block insulating layer BK and the dummy layer BKd in a range of 5 nm or more and 10 nm or less, and a predetermined layer thickness difference occurs also between the dummy layers BKn and BKt.

As illustrated in FIG. 29A, after the CVD-carbon layer 83 is removed, the memory hole MH in which the block insulating layer BK is formed and the hole HL in which the dummy layers BKd, BKn, and BKt are formed are opened again on the upper surface of the stacked body LMsb.

As illustrated in FIGS. 29Bb to 29Bd, a silicon nitride layer or the like is formed on each of the sidewalls of the holes HL. Accordingly, the dummy layer CTd is formed on the sidewall of the hole HL while interposing the dummy layer BKd, the dummy layer BKn, or the dummy layer BKt therebetween, respectively. Here, the charge storage layer CT is formed on the sidewall of the memory hole MH (not illustrated) while interposing the block insulating layer BK therebetween.

As illustrated in FIGS. 29Cb to 29Cd, a silicon oxide layer or the like is formed on each of the sidewalls of the holes HL. Here, a silicon oxide layer or the like is also formed on the sidewall of the memory hole MH (not illustrated).

Accordingly, the tunnel insulating layer TN is formed on the sidewall of the memory hole MH while interposing the block insulating layer BK and the charge storage layer CT therebetween. Accordingly, the memory layer ME including the block insulating layer BK, the charge storage layer CT, and the tunnel insulating layer TN is formed on the sidewall of the memory hole MH.

The dummy layer TNd is formed on the sidewall of the hole HL while interposing the dummy layer BKd, the dummy layer BKn, or the dummy layer BKt, and the dummy layer CTd therebetween. Accordingly, the dummy layer MEd, the dummy layer MEn, or the dummy layer MEt including the dummy layer BKd, the dummy layer BKn, or the dummy layer BKt, the dummy layer CTd, and the dummy layer TNd are formed on the sidewall of the hole HL.

As illustrated in FIGS. 29Db to 29Dd, a semiconductor layer such as a polysilicon layer or an amorphous silicon layer is formed on each of the sidewalls of the holes HL. Here, the semiconductor layer is also formed on the sidewall of the memory hole MH (not illustrated).

Accordingly, the channel layer CN is formed on the sidewall of the memory hole MH while interposing the memory layer ME therebetween. The dummy layer CNd is formed on the sidewall of the hole HL while interposing the dummy layer MEd, the dummy layer MEn, or the dummy layer MEt therebetween.

As illustrated in FIGS. 29Eb to 29Ed, the gaps remaining within the holes HL are filled with a silicon oxide layer or the like. Here, the gap remaining within the memory hole MH (not illustrated) is also filled with a silicon oxide layer or the like.

By the above processing, the core layer CR is formed within the memory hole MH, and the dummy layer CRd is formed within the hole HL.

After that, by performing the process illustrated in FIGS. 14A to 14C on the memory hole MH and the hole HL, the pillar PL including the cap CP at the upper end and the columnar portions HRm, HRn, and HRt each including the dummy layer CPd at the upper end are formed.

However, also in the second embodiment, the formation of the dummy layer CPd for the hole HL may be skipped, and the columnar portions HRm, HRn, and HRt not including the dummy layer CPd may be formed.

It should be noted that in the second embodiment, the dummy layer BKt of the columnar portion HRt is formed by additionally forming a silicon oxide layer or the like. Therefore, to prevent the hole HL including the dummy layer BKt from being blocked, it is preferable that, in the process illustrated in FIG. 26B described above, the insulating layer BKb is not formed as thickly as, for example, Modified Example 3 of the first embodiment described above.

Accordingly, the layer thickness difference between the block insulating layer BK of the pillar PL and the dummy layer BKd of the columnar portion HRm, and the dummy layer BKn of the columnar portion HRn may smaller than the layer thickness difference between the block insulating layer BK and the dummy layer BKd, and the dummy layer BKt of the columnar portion HRt.

### (Overview)

According to the semiconductor storage device 2 of the second embodiment, the columnar portion HRn includes the dummy layer BKn that is thinner than the dummy layer BKt of the columnar portion HRt and thicker than the dummy layer BKd of the columnar portion HRm.

Accordingly, the columnar portions HRm, HRn, and HRt including the dummy layers BKd, BKn, and BKt of desired layer thickness can be disposed, for example, according to the level of risk of contact with the contact CC in each of the stepped portions SPs, SPb, and SPa. Accordingly, the formation defects of the contact CC due to contact between the contact CC and the columnar portions HRn and HRt can be prevented.

Also in the second embodiment, the arrangement positions of the columnar portions HRm, HRn, and HRt in the stepped portions SPs, SPb, and SPa can be changed as appropriate, for example, as in Modified Example 1 of the first embodiment described above.

In the second embodiment, the arrangement range of the columnar portions HRs located at positions adjacent to the plate-like portion PT among the stepped portions SPs, SPb, and SPa can be changed as appropriate, for example, in Modified Example 2 of the first embodiment described above.

### Third Embodiment

A third embodiment will be described in detail below with reference to the drawings. The third embodiment is different from the first embodiment described above in that there is a columnar portion in which the thickness of the dummy layer of the outermost periphery corresponding to the block insulating layer BK of the pillar PL is different between the portion penetrating the stacked body LMa and the portion penetrating the stacked body LMb.

In the following drawings, the same configurations as those in the first embodiment described above are denoted by the same reference numerals, and the description thereof may be omitted.

### (Configuration Example of Semiconductor Storage Device)

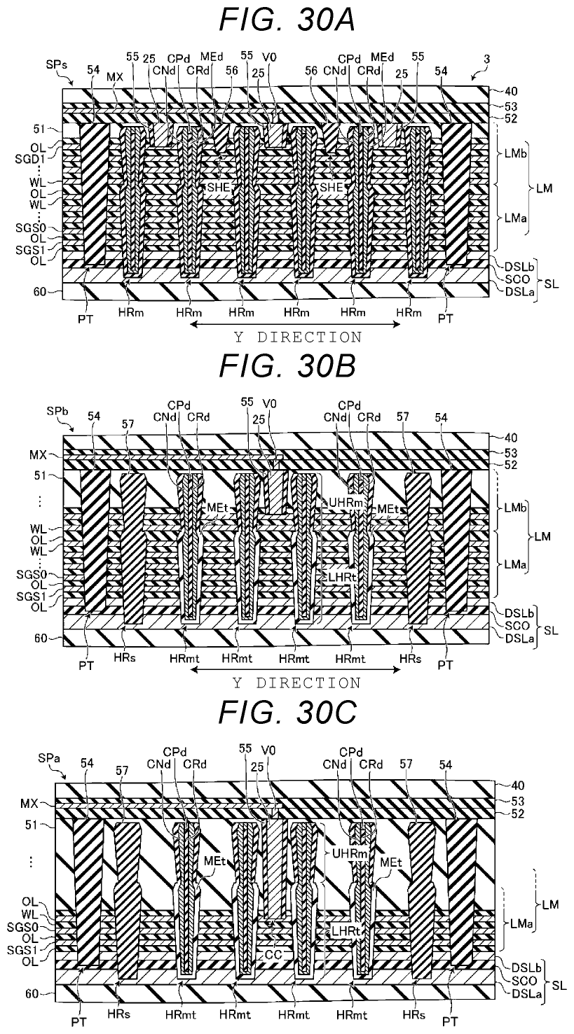

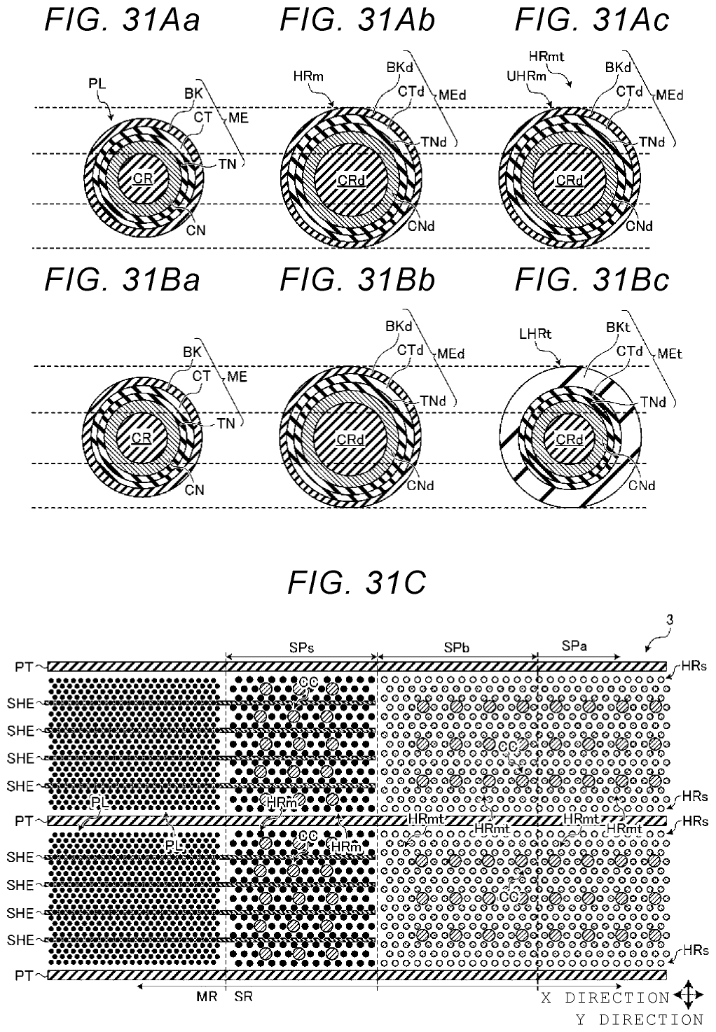

FIGS. 30A to 31C are diagrams illustrating a configuration example of a semiconductor storage device 3 according to the third embodiment.

More specifically, FIGS. 30A to 30C are cross-sectional views along the Y direction including the stepped region SR of the semiconductor storage device 3. FIG. 30A is a cross-sectional view at the stepped portion SPs. FIG. 30B illustrates the cross section at the stepped portion SPb. FIG. 30C illustrates the cross section at the stepped portion SPa. It should be noted that, in FIGS. 30A to 30C, the structures below the insulating layer 60 and above the insulating layer 40 are omitted.

FIG. 31Aa is an XY cross-sectional view of the pillar PL at the height position of the freely selected word line WL of the stacked body LMb. FIG. 31Ba is an XY cross-sectional view of the pillar PL at the height position of the freely selected word line WL of the stacked body LMa.

FIG. 31Ab is an XY cross-sectional view of the columnar portion HRm at the same height position as the cross section illustrated in FIG. 31Aa. FIG. 31Bb is an XY cross-sectional view of the columnar portion HRm at the same height position as the cross section illustrated in FIG. 31Ba.

FIG. 31Ac is an XY cross-sectional view of a columnar portion HRmt at the same height position as the cross sections illustrated in FIGS. 31Aa and 31Ab. FIG. 31Bc is an XY cross-sectional view of the columnar portion HRmt at the same height position as the cross sections illustrated in FIGS. 31Ba and 31Bb.

FIG. 31C is an XY cross-sectional view of a partial region of the stacked body LM at the height position of the select gate line SGD.

It should be noted that the drawings illustrated in FIGS. 30A to 31C are schematic diagrams, and the number and layout illustrated in the respective cross-sectional views of FIGS. 30A to 30C and the XY cross-sectional view of FIG. 31C do not necessarily match.

The semiconductor storage device 3 of the third embodiment has a schematic configuration similar to that of the semiconductor storage device 1 of the first embodiment illustrated in FIG. 3 described above. The semiconductor storage device 3 has the same configuration as the semiconductor storage device 1 of the above-described first embodiment in the memory region MR.

As illustrated in FIGS. 30A and 31C, similarly to the first embodiment described above, the plurality of columnar portions HRm penetrating the insulating layer 51, the stacked body LMb and LMa, the upper source line DSLb, and the intermediate insulating layer SCO to reach the lower source line DSLa are dispersed and located in the stepped portion SPs.

As illustrated in FIGS. 30B, 30C, and 31C, the columnar portions HRmt and HRs penetrating the insulating layer 51, the stacked bodies LMb and LMa, the upper source line DSLb, and the intermediate insulating layer SCO to reach the lower source line DSLa are located in the stepped portions SPb and SPa.

The plurality of columnar portions HRs are located at positions adjacent to the plate-like portion PT on both sides of the plate-like portion PT in the Y direction, similarly to the first embodiment described above.

The plurality of columnar portions HRmt serving as second pillars are dispersed and located over the entire stepped portions SPb and SPa except for the position adjacent to the plate-like portion PT. Here, the plurality of columnar portions HRmt are located in, for example, a grid shape or a staggered shape when viewed from the stacking direction of the stacked body LM while avoiding interference with the contacts CC. Each columnar portion HRmt has, for example, a circular shape, an elliptical shape, an oval shape, or the like as a cross-sectional shape in the direction along the XY plane.

The columnar portion HRmt includes a columnar portion LHRt as the first sub-pillar penetrating the stacked body LMa and a columnar portion UHRm as the second sub-pillar penetrating the stacked body LMb. Both of the columnar portions LHRt and UHRm have a taper shape in which the diameter and cross-sectional area decrease from the upper layer side to the lower layer side. Alternatively, each of the columnar portions LHRt and UHRm has a bowing shape in which the diameter and cross-sectional area are maximized at a predetermined position between the upper layer side and the lower layer side.

Each of the columnar portions LHRt and UHRm also has the same layer structure as the pillar PL described above. The columnar portions LHRt and UHRm are also in the floating state as a whole and have no electrical function in the semiconductor storage device 3, as described above.

The columnar portion LHRt has the same layer structure as the pillar PL, and includes the dummy layers MEt, CNd, and CRd extending in the stacking direction within the stacked body LMa. The columnar portion UHRm includes the dummy layers MEd, CNd, and CRd extending in the stacking direction within the stacked body LMb.

As illustrated in FIGS. 31Ac and 31Bc, the dummy layer MEd has a multilayer structure in which the dummy layers BKd, CTd, and TNd are stacked in this order from the outer peripheral side of a columnar portion UHRm, and the dummy layer MEt has a multilayer structure in which the dummy layers BKt, CTd, and TNd are stacked in this order from the outer peripheral side of the columnar portion LHRt.

As illustrated in FIGS. 31Aa to 31Ac, the cross-sectional area and diameter of the columnar portion UHRm in the direction along the XY plane are substantially equal to the cross-sectional area and diameter of the columnar portion HRm in the direction along the XY plane at the same height position of the stacked body LMb and larger than the cross-sectional area and diameter of the pillar PL in the direction along the XY plane at the same height position of the stacked body LMb.

The respective thicknesses of the dummy layers BKd, CTd, TNd, and CNd of the columnar portion UHRm are substantially equal to the respective thicknesses of the block insulating layer BK, the charge storage layer CT, the tunnel insulating layer TN, and the channel layer CN of the corresponding pillar PL and the respective thicknesses of the dummy layers BKd, CTd, TNd, and CNd of the columnar portion HRm.

At the same height position of the stacked body LMb, the cross-sectional area and diameter of the dummy layer CRd of the columnar portion UHRm in the direction along the XY plane are larger than the cross-sectional area and diameter of the corresponding core layer CR of the pillar PL and are substantially equal to the cross-sectional area and diameter of the dummy layer CRd of the columnar portion HRm.

As such, the columnar portion HRmt has substantially the same configuration as the columnar portion HRm in the columnar portion UHRm penetrating the stacked body LMb.

As illustrated in FIGS. 31Ba to 31Bc, the cross-sectional area and diameter of the columnar portion LHRt in the direction along the XY plane are substantially equal to the cross-sectional area and diameter of the columnar portion HRm in the direction along the XY plane at the same height position of the stacked body LMa and larger than the cross-sectional area and diameter of the pillar PL in the direction along the XY plane at the same height position of the stacked body LMa.

The respective thicknesses of the dummy layers CTd, TNd, and CNd of the columnar portion LHRt are substantially equal to the respective thicknesses of the charge storage layer CT, the tunnel insulating layer TN, and the channel layer CN of the corresponding pillar PL and the respective thicknesses of the dummy layers CTd, TNd, and CNd of the columnar portion HRm.

On the other hand, the dummy layer BKt of the columnar portion LHRt is thicker than the corresponding block insulating layer BK of the pillar PL and the dummy layer BKd of the columnar portion HRm and the columnar portion UHRm.

Accordingly, at the same height position of the stacked body LMa, the cross-sectional area and diameter of the dummy layer CRd of the columnar portion LHRt in the direction along the XY plane are smaller than the cross-sectional area and diameter of the corresponding dummy layer CRd of the columnar portion HRm and substantially equal to the cross-sectional area and diameter of the core layer CR of the pillar PL, for example.

As such, the columnar portion HRmt has substantially the same configuration as the columnar portion HRt of the above-described first embodiment in the columnar portion LHRt penetrating the stacked body LMa.

As described above, the risk of contact with the contact CC increases toward the lower side of the columnar portion HRmt. Therefore, by thickening the dummy layer BKt in the columnar portion LHRt penetrating the stacked body LMa among the columnar portion UHRm penetrating the stacked body LMb and the columnar portion LHRt penetrating the stacked body LMa of the columnar portion HRmt, the problems caused by contact with the contact CC can be prevented.

### (Method for Manufacturing Semiconductor Storage Device)

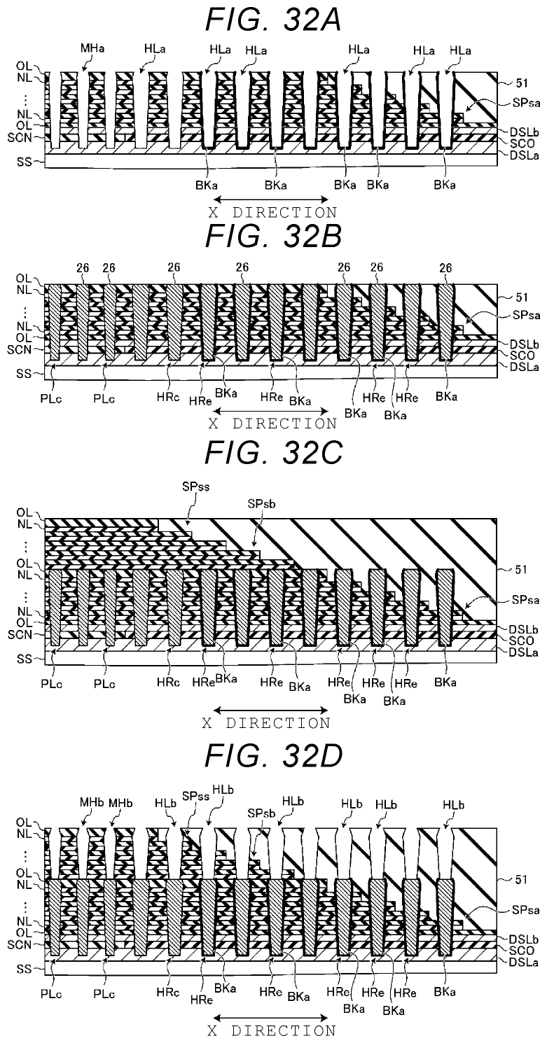

Next, a method for manufacturing the semiconductor storage device 3 of the third embodiment will be described with reference to FIGS. 32A to 35Bg. FIGS. 32A to 35Bg are diagrams sequentially illustrating a portion of a procedure of the method for manufacturing the semiconductor storage device 3 according to the third embodiment.

First, FIGS. 32A to 32D illustrate an aspect where various configurations are formed in the stacked bodies LMsa and LMsb. FIGS. 32A to 32D are cross-sectional views along the X direction of the regions that later become the memory region MR and the stepped region SR.

As illustrated in FIG. 32A, the lower source line DSLa, the intermediate sacrifice layer SCN or the intermediate insulating layer SCO, and the upper source line DSLb are formed in this order on the supporting substrate SS. The stacked body LMsa is formed on the upper source line DSLb. The stepped portion SPsa is formed in a partial region of the stacked body LMsa. The insulating layer 51 covers the stepped portion SPsa and reach the height of the upper surface of the stacked body LMsa.

The plurality of memory holes MHa extending in the stacking direction of the stacked body LMsa are formed in the region that later becomes the memory region MR, and the plurality of memory holes MHa extending in the stacking direction of the stacked body LMsa are formed collectively with, for example, the memory holes MHa in the region that later becomes the stepped region SR.

An insulating layer BKa as a seventh insulating film which becomes a portion of the dummy layer BKt is formed on the sidewalls and bottom surfaces of the holes HLa as the first sub-holes among the plurality of holes HLa in the region that later becomes the stepped portion SPsb and in the stepped portion SPa.

As illustrated in FIG. 32B, the memory hole MHa and the hole HLa are filled with the sacrifice layer 26 such as an amorphous silicon layer.

Accordingly, the pillar PLC in which the plurality of memory holes MHa are filled with the sacrifice layer 26 is formed in the region that later becomes the memory region MR. The columnar portion HRc in which the plurality of holes HLa are filled with the sacrifice layer 26 is formed in the region that later becomes the stepped portion SPs.

In the region that later becomes the stepped portion SPb and in the stepped portion SPsa, a columnar portion HRe is formed in which the insulating layer BKa and the sacrifice layer 26 are formed in the plurality of holes HLa.

As illustrated in FIG. 32C, the stacked body LMsb is formed on the stacked body LMsa, and the stepped portions SPsb and SPss are formed in a partial region of the stacked body LMsb. The insulating layer 51 is formed covering the stepped portions SPsb, SPss, and SPsa and reaching the height of the upper surface of the stacked body LMsb.

The plurality of memory holes MHb penetrating the stacked body LMsb to reach the upper ends of the pillars PLC formed in the stacked body LMsa, respectively, are formed in the region that later becomes the memory region MR. The plurality of holes HLb penetrating the insulating layer 51 and the stacked body LMsb to reach the upper ends of the columnar portions HRc and HRe formed in the stacked body LMsa, respectively, are formed collectively with, for example, the memory hole MHb in the region that later becomes the stepped region SR.

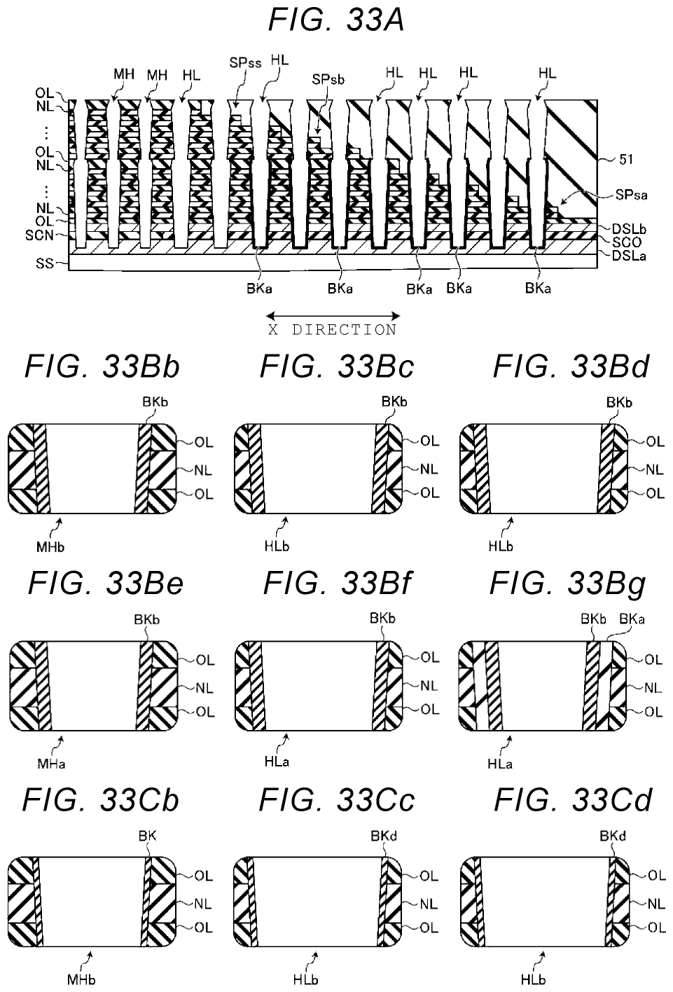

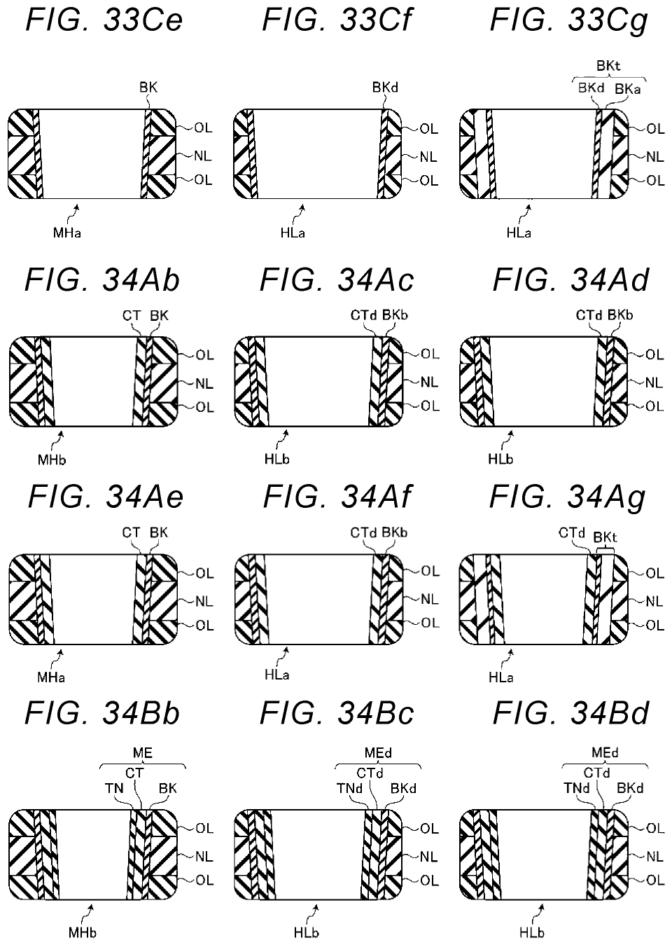

Next, FIGS. 33A to 35Bg illustrate an aspect where a multilayer structure is formed in the memory hole MH and the remaining hole HL.

Similarly to FIGS. 32A to 32D described above, FIG. 33A is a cross-sectional view along the X direction of the regions that later become the memory region MR and the stepped region SR.

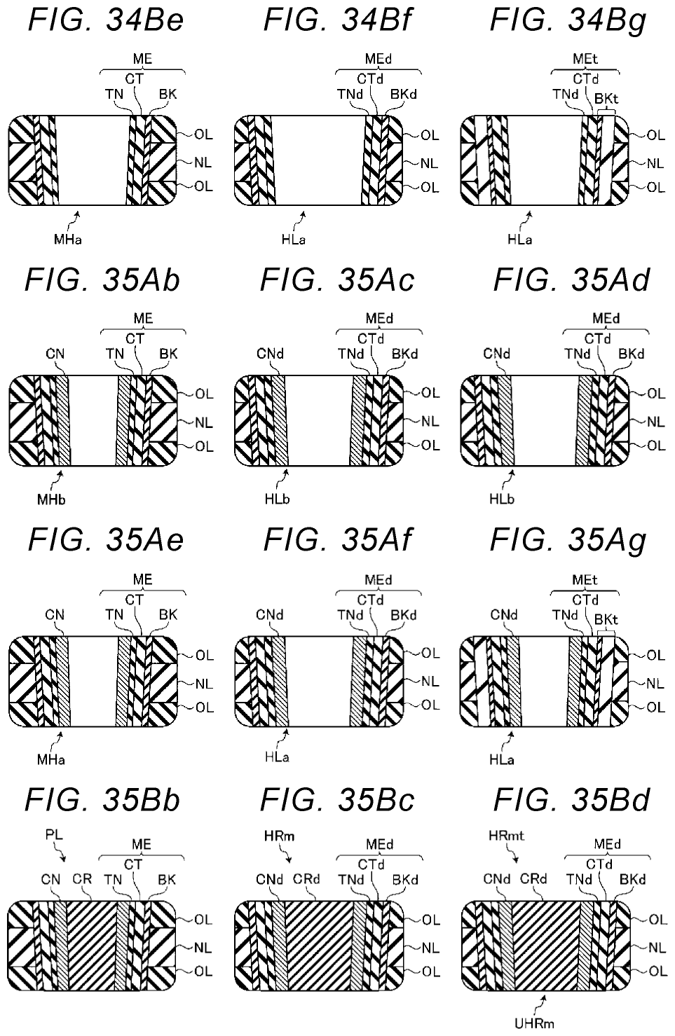

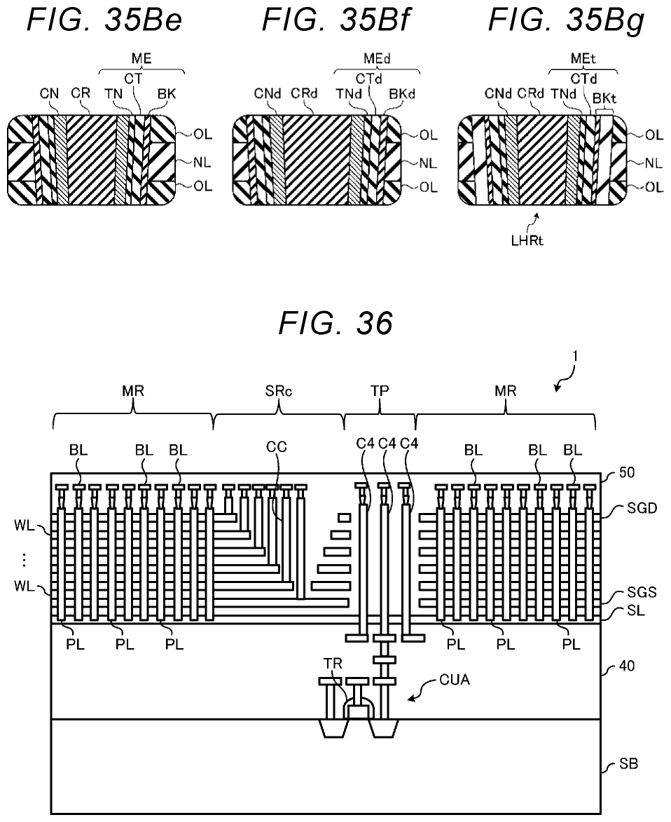

FIGS. 33Bb to 33Bd and FIGS. 33Cb to 33Cd, FIGS. 34Ab to 34Ad and FIGS. 34Bb to 34Bd, and FIGS. 35Ab to 35Ad and FIGS. 35Bb to 35Bd are enlarged cross-sectional views in the Y direction of the memory hole MH, the hole HL to be processed into the columnar portion HRm, and the hole HL as the second hole to be processed into the columnar portion HRmt, respectively, at the freely selected height position of the insulating layer NL of the stacked body LMsb.

FIGS. 33Be to 33Bg and FIGS. 33Ce to 33Cg, FIGS. 34Ae to 34Ag and FIGS. 34Be to 34Bg, and FIGS. 35Ae to 35Ag and FIGS. 35Be to 35Bg are enlarged cross-sectional views in the Y direction of the memory hole MH, the hole HL to be processed into the columnar portion HRm, and the hole HL to be processed into the columnar portion HRmt, respectively, at the freely selected height position of the insulating layer NL of the stacked body LMsa.

As illustrated in FIG. 33A, the sacrifice layer 26 of the pillar PLC and the columnar portions HRc and HRe connected to the lower ends of the memory hole MHb and the hole HLb, respectively, are removed through the memory hole MHb and the hole HLb, respectively.

Accordingly, the memory holes MHa are opened at the bottoms of the plurality of memory holes MHb, so that the plurality of memory holes MH are formed. The holes HLa are opened at the bottoms of the plurality of holes HLb, so that the plurality of holes HL are formed. The insulating layer BKa is formed within the hole HLa that is the lower structure of the holes HL formed in the stepped portions SPsb and SPsa among the holes HL.

It should be noted that from now on, similar processing is performed on the entire memory holes MH and holes HL.

As illustrated in FIGS. 33Bb to 33Bg, the insulating layer BKb such as a silicon oxide layer is formed on the sidewalls of the memory hole MH and the hole HL. The insulating layer BKb is thicker than the block insulating layer BK that is eventually provided in the pillar PL.

Here, the insulating layer BKb is formed on the sidewall of the hole Hla, which is the lower structure of the hole HL formed in the stepped portions SPsb and SPsa, while interposing the already formed insulating layer BKa therebetween. Accordingly, the insulating layers BKa and BKb are formed on the sidewall of the hole HLa on the lower layer side, to be thicker than the insulating layer BKb of the hole HLb as the second sub-hole on the upper layer side.

As illustrated in FIGS. 33Cb to 33Cg, the insulating layer BKb on the sidewalls of the memory hole MH and the hole HL is slimmed to be thinned. Accordingly, the block insulating layer BK is formed on the sidewall of the memory hole MH, and the dummy layer BKd is formed on the sidewall of the hole HL.

Here, in the holes HLa that are the lower structure of the holes HL formed in the stepped portions SPsb and SPsa, the insulating layer BKb covering the insulating layer BKa is slimmed while maintaining the layer thickness of the already formed insulating layer BKa. Accordingly, the insulating layer BKa and the dummy layer BKd are formed in the hole HLa, and the insulating layer BKa and the dummy layer BKd become the dummy layer BKt.

As such, by forming the insulating layer BKa in advance in the hole HLa which is the lower structure of the hole HL formed in the stepped portions SPsb and SPsa, the dummy layer BKt can be thicker than the block insulating layer BK of the pillar PL and the dummy layer BKd of the columnar portion HRm. Here, since the thick dummy layer BKt is formed only in the hole HLa on the lower layer side, the dummy layer BKt can be a desired thickness without being restricted by the diameter of the lower end of the hole HLb penetrating the stacked body LMsb portion.

As illustrated in FIGS. 34Ab to 34Ag, a silicon nitride layer or the like is formed on each of the sidewalls of the memory holes MH and the holes HL. Accordingly, the charge storage layer CT is formed on the sidewall of the memory hole MH while interposing the block insulating layer BK therebetween. The dummy layer CTd is formed on the sidewalls of the hole HL of the stepped portion SPss and the holes HLb on the upper layer side of the stepped portions SPsb and SPsa while interposing the dummy layer BKd therebetween.

The dummy layer CTd is formed on the sidewall of the hole HLa on the lower layer side among the holes HL of the stepped portions SPsb and SPsa while interposing the dummy layer BKt therebetween.

As illustrated in FIGS. 34Bb to 34Bg, a silicon oxide layer and the like is formed on each of the sidewalls of the memory holes MH and the holes HL.

Accordingly, the tunnel insulating layer TN is formed on the sidewall of the memory hole MH while interposing the block insulating layer BK and the charge storage layer CT therebetween, and the memory layer ME including the layers is formed. The dummy layer TNd is formed on the sidewalls of the hole HL of the stepped portion SPss and the hole HLb on the upper layer side of the stepped portions SPsb and SPsa, respectively, while interposing the dummy layer BKd and the dummy layer CTd therebetween, and the dummy layer MEd including the layers is formed.

The dummy layer TNd is formed on the sidewall of the hole HLa which is the lower layer side among the holes HL of the stepped portions SPsb and SPsa while interposing the dummy layers BKt and CTd therebetween. Accordingly, the dummy layer MEt including the dummy layer BKt, the dummy layer CTd, and the dummy layer TNd is formed on the sidewall of the hole HLa.

As illustrated in FIGS. 35Ab to 35Ag, a semiconductor layer such as a polysilicon layer or an amorphous silicon layer is formed on each of the sidewalls of the memory hole MH and the hole HL. Accordingly, the channel layer CN is formed on the sidewall of the memory hole MH while interposing the memory layer ME therebetween. The dummy layer CNd is formed on each of the sidewalls of the hole HL of the stepped portion SPss and the hole HLb on the upper layer side of the stepped portions SPsb and SPsa while interposing the dummy layer MEd therebetween.

The dummy layer CNd is formed on the sidewall of the hole HLa on the lower layer side among the holes HL of the stepped portions SPsb and SPsa while interposing the dummy layer MEt therebetween.

As illustrated in FIGS. 35Bb to 35Bg, the gaps remaining in the memory hole MH and the hole HL are filled with a silicon oxide layer or the like. Accordingly, the core layer CR is formed in the memory hole MH, and the dummy layer CRd is formed in the hole HL.

After that, by performing the process illustrated in FIGS. 14A to 14C on the memory hole MH and the hole HL, the pillar PL including the cap CP at the upper end and the columnar portions HRm and HRmt each including the dummy layer CPd at the upper end are formed.

However, also in the third embodiment, the formation of the dummy layer CPd for the hole HL may be skipped, and the columnar portions HRm and HRmt may be formed without the dummy layer CPd.

### (Overview)

According to the semiconductor storage device 3 of the third embodiment, the columnar portion LHRt which is the lower structure of the columnar portion HRmt includes the dummy layer BKt that is thicker than the dummy layer BKd of the columnar portion UHRm which is the upper structure of the columnar portion HRmt. With such configuration, the problems caused by contact between the columnar portion HRmt and the slit ST can be prevented.

### OTHER EMBODIMENTS

In the first to third embodiments and Modified Examples 1 to 3 described above, the pillar PL is connected to the source line SL on the side surface of the channel layer CN, but the present disclosure is not limited thereto. For example, the pillar may be configured such that the memory layer at the bottom surface of the pillar is removed to connect the pillar to the source line in the lower end of the channel layer.

In the first to third embodiments and Modified Examples 1 to 3 described above, the stacked body LM has a 2-tier structure including the two stacked bodies LMa and LMb. However, the number of tiers of the stacked bodies may be 1-tier or may be 3-tier or more.

In the first to third embodiments and Modified Examples 1 to 3 described above, the stepped region SR is disposed at the end of the stacked body LM in the X direction. However, the stepped region may be disposed at the center of the stacked body when viewed from the stacking direction by penetrating the center of the stacked body into a stepped shape. The configurations of the first to third embodiments and Modified Examples 1 to 3 described above can be applied to such a stepped region as well.

In the first to third embodiments and Modified Examples 1 to 3 described above, the peripheral circuit CBA is disposed above the stacked body LM. However, the peripheral circuit may be disposed below the stacked body or on the same level as the stacked body.

When the peripheral circuit is disposed below the stacked body, the source line and the stacked body can be formed, for example, on the insulating layer of the semiconductor substrate including the peripheral circuit covered with the insulating layer. When the peripheral circuit is disposed on the same level as the stacked body, the stacked body can be formed at a different position 1 from the position on the semiconductor substrate where the peripheral circuit is formed.

Hereinafter, FIG. 36 illustrates a semiconductor storage device including the stepped region in the center of the stacked body and a peripheral circuit below the stacked body as another configuration example of the semiconductor storage device.

FIG. 36 is a cross-sectional view illustrating a schematic configuration example of a semiconductor storage device according to another embodiment. However, in FIG. 36, hatching is omitted considering the ease of viewing the drawing.

As illustrated in FIG. 36, the semiconductor storage device of the other embodiment includes a peripheral circuit CUA, the plurality of word lines WL, and the like in this order on the substrate SB.

The substrate SB is, for example, a semiconductor substrate such as a silicon substrate. The peripheral circuits CUA such as the above-described row decoder 520 and sense amplifier module 530 (refer to FIG. 1), including transistors TR, wiring, and the like, are disposed on the substrate SB.

The peripheral circuit CUA is covered with the insulating layer 40 such as a silicon oxide film. The source line SL is disposed on the insulating layer 40. The plurality of word lines WL and the select gate lines SGD and SGS are stacked above the source line SL.

The plurality of word lines WL and the like are covered with the insulating layer 50. The insulating layer 50 also spreads around the plurality of word lines WL.

The plurality of memory regions MR, a stepped region SRC, and a through contact region TP are disposed in the plurality of word lines WL and the like.

The plurality of pillars PL penetrating the plurality of word lines WL and the like in the stacking direction are located in the memory region MR. The plurality of memory cells MC (refer to FIG. 2) are formed at the intersection of the pillar PL and the word line WL. Accordingly, the semiconductor storage device of another embodiment is also configured as a three-dimensional nonvolatile memory in which the plurality of memory cells MC are located three-dimensionally.

The stepped region SRc includes a plurality of stepped portions in which the plurality of word lines WL and the like are penetrated in a mortar shape in the stacking direction. Each step of the stepped portion is configured with the word lines WL and the like of each level. The word line WL and the select gate lines SGD and SGS of each level maintain electrical connection on both sides of the stepped region SRc in the X direction via the ends of the stepped region SRc on the Y direction side.

The contacts CC connected to the word line WL and the select gate lines SGD and SGS of each level are located in the terrace portion of each step of at least one of the plurality of stepped portion. The contacts CC are electrically connected to the peripheral circuit CUA via an upper layer wiring further above the select gate line SGD and the like.

A through contact C4 penetrating the plurality of word lines WL and the like is located in the through contact region TP. The through contact C4 connects the peripheral circuit CUA disposed on the lower substrate SB and the contacts CC provided in the plurality of word lines WL. Various voltages applied from the contact CC to the memory cell MC are controlled by the peripheral circuit CUA via the through contact C4 and the like.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a stacked body having a plurality of conductive layers and a plurality of first insulating layers stacked alternately, the stacked body including a first region and a second region;
one or more first pillars extending, in a stacking direction of the stacked body, within the first region of the stacked body; and
a second pillar extending, in the stacking direction, within the second region of the stacked body, wherein
each of the first and second pillars includes a semiconductor layer, a second insulating layer, a third insulating layer, and a fourth insulating layer,
the fourth insulating layer interposed between the second and third insulating layers,
the second insulating layer covering a sidewall of the semiconductor layer,
the fourth insulating layer covering a sidewall of the second insulating layer, the fourth insulating layer containing a different material from the second and third insulating layers,
the third insulating layer covering a sidewall of the fourth insulating layer,
an intersection of at least one of the plurality of conductive layers or the first pillar functions as a memory cell, and
the third insulating layer of the second pillar is thicker than the third insulating layer of the first pillar in a plane perpendicular to the stacking direction.

2. The semiconductor storage device according to claim 1, wherein the plurality of conductive layers have a stepped shape within the second region of the stacked body.

3. The semiconductor storage device according to claim 1, further comprising a contact extending in the stacking direction within the second region of the stacked body.

4. The semiconductor storage device according to claim 1, wherein the third insulating layer of the second pillar is thicker in a range of 5 nm or more and 10 nm or less than the third insulating layer of the first pillar in the plane perpendicular to the stacking direction.

5. The semiconductor storage device according to claim 2, further comprising:
a separation layer penetrating one or more conductive layers including an uppermost conductive layer of the stacked body among the plurality of conductive layers, extending within the stacked body in a first direction intersecting the stacking direction, the separation layer separating the one or more conductive layers in a second direction intersecting the stacking direction and the first direction; and
a third pillar extending in the stacking direction through a region of the second region in which the one or more conductive layers have a stepped shape, wherein
the second pillar is disposed in a region of the second region in which the conductive layer lower than the one or more conductive layers that have the a stepped shape,
the third pillar including the semiconductor layer, the second insulating layer, the third insulating layer, and the fourth insulating layer, and
the third insulating layer of the third pillar is thinner than the third insulating layer of the second pillar in the plane perpendicular to the stacking direction.

6. The semiconductor storage device according to claim 5, further comprising:
a plate-like portion dividing the stacked body into a first portion and a second portion that extend in the stacking direction and the first direction intersecting the stacking direction, the first portion and the second portion aligned in the second direction intersecting the stacking direction and the first direction; and
a plurality of fourth pillars arranged in the first direction in the first portion and the second portion, wherein
the fourth pillar includes a fifth insulating layer penetrating the stacked body in the stacking direction, and
a distance between the plate-like portion and the fourth pillar is shorter than a distance between the plate-like portion and the second pillar.

7. The semiconductor storage device according to claim 2, further comprising a fifth pillar extending in the second region in the stacking direction, wherein
the stacked body includes:
a first stacked body including a lower conductive layer among the plurality of conductive layers and a lower first insulating layer among the plurality of first insulating layers, the first stacked body having a first stepped portion in which the lower conductive layer has a stepped shape, and
a second stacked body including an upper conductive layer among the plurality of conductive layers and an upper first insulating layer among the plurality of first insulating layers, the second stacked body being disposed above the first stacked body, and having a second stepped portion in which the upper conductive layer has a stepped shape,
the second pillar is disposed in the first stepped portion,
the fifth pillar includes the semiconductor layer, the second insulating layer, the third insulating layer, and the fourth insulating layer,
the fifth pillar is disposed in the second stepped portion except for a region in which the one or more conductive layers have a stepped shape, and
in the plane perpendicular to the stacking direction, the third insulating layer of the fifth pillar is thinner than the third insulating layer of the second pillar and is thicker than the third insulating layer of the third pillar.

8. The semiconductor storage device according to claim 2, wherein
the stacked body includes:
a first stacked body including a lower conductive layer among the plurality of conductive layers and a lower first insulating layer among the plurality of first insulating layers, the first stacked body having a first stepped portion in which the lower conductive layer has a stepped shape; and
a second stacked body including an upper conductive layer among the plurality of conductive layers and an upper first insulating layer among the plurality of first insulating layers, the second stacked body being disposed above the first stacked body, and having a second stepped portion in which the upper conductive layer has a stepped shape,
the second pillar including:
a first sub-pillar extending in the stacking direction at a height position of the first stacked body, and
a second sub-pillar extending in the stacking direction at a height position of the second stacked body and being connected to an upper end of the first sub-pillar at a lower end, and
the third insulating layer of the first sub-pillar is thicker than the third insulating layer of the second sub-pillar.

9. A semiconductor storage device comprising:
a stacked body having a plurality of conductive layers and a plurality of first insulating layers stacked alternately and including a first region and a second region;
one or more first pillars extending in a stacking direction of the stacked body within the first region of the stacked body;
a second pillar extending in the stacking direction within the second region of the stacked body; and
a contact extending in the first direction within the second region of the stacked body, wherein
each of the first pillars including a semiconductor layer, a tunnel insulating layer, a block insulating layer, and a charge storage layer interposed between the tunnel insulating layer and the block insulating layer,
the semiconductor layer extending in the stacking direction,
the tunnel insulating layer covering a sidewall of the semiconductor layer,
the charge storage layer covering a sidewall of the tunnel insulating layer and containing a different material from the tunnel insulating layer and the block insulating layer,
the block insulating layer covering a sidewall of the charge storage layer,
each of the second pillars including the semiconductor layer, a second insulating layer, a third insulating layer, and a fourth insulating layer interposed between the second and third insulating layers,
the semiconductor layer extending in the stacking direction,
the second insulating layer covering the sidewall of the semiconductor layer,
the fourth insulating layer covering a sidewall of the second insulating layer and containing a different material from the second and third insulating layers,
the third insulating layer covering a sidewall of the fourth insulating layer,
an intersection of at least one of the plurality of conductive layers and the first pillar functions as a memory cell, and
the third insulating layer is thicker than the block insulating layer in a plane perpendicular to the stacking direction.

10. The semiconductor storage device according to claim 9, wherein the plurality of conductive layers are formed in a stepped shape within the second region of the stacked body.

11. The semiconductor storage device according to claim 9, wherein the third insulating layer of the second pillar is thicker in a range of 5 nm or more and 10 nm or less than the block insulating layer of the first pillar in the plane perpendicular to the first direction.

12. A method for manufacturing a semiconductor storage device, the method comprising:
forming a stacked body having a plurality of first insulating layers and a plurality of second insulating layers stacked alternately in a first direction, the stacked body including a first region and a second region in which the plurality of first insulating layers are formed in a stepped shape;
forming a first hole extending in the first direction within the first region and a second hole extending in the first direction within the second region;
forming third insulating layers covering respective sidewalls of the first and second holes;
reducing a thickness of the third insulating layer covering the sidewall of the first hole in a second direction perpendicular to the first direction so that a thickness of the third insulating layer of the second hole is larger than the thickness of the third insulating layer of the first hole;
forming a fourth insulating layer covering respective side walls of the first and second holes while interposing the third insulating layer of the first hole in which the thickness in the second direction is reduced and the third insulating layer of the second hole therebetween;
forming a fifth insulating layer containing a different material from the third and fourth insulating layers and being interposed between the third and fourth insulating layers in each of the first and second holes; and
forming a semiconductor layer covering each of the sidewalls of the first and second holes while interposing the third to fifth insulating layers formed in the respective first and second holes therebetween.

13. The method for manufacturing the semiconductor storage device according to claim 12, the method further comprising forming a contact extending in the stacking direction within the second region of the stacked body.

14. The method for manufacturing the semiconductor storage device according to claim 12, the method further comprising:
when forming the third insulating layer within the first and second holes,
even after forming the third insulating layer within the first hole, continuing to form the third insulating layer within the second hole to form the third insulating layer within the second hole to be thicker than the third insulating layer within the first hole.

15. The method for manufacturing the semiconductor storage device according to claim 12, the method further comprising:
forming a third hole extending in the stacking direction in a region of the stepped portion in which one or more first insulating layers including an uppermost first insulating layer of the stacked body are processed into a stepped shape among the plurality of first insulating layers;
when forming the third insulating layer within the first and second holes, also forming the third insulating layer on the sidewall of the third hole;
when reducing a thickness of the third insulating layer of the first hole, also reducing the thickness of the third insulating layer covering the sidewall of the third hole;
when forming the fourth insulating layer within the first and second holes, also forming the fourth insulating layer on the sidewall of the third hole while interposing the third insulating layer of the third hole in which the thickness is reduced therebetween;
when forming the fifth insulating layer within the first and second holes, also forming the fifth insulating layer interposed between the third and fourth insulating layers in the third hole; and
when forming the semiconductor layer within the first and second holes, also forming the semiconductor layer on the sidewall of the third hole while interposing the third to fifth insulating layers formed in the third hole therebetween.

16. The method for manufacturing the semiconductor storage device according to claim 15, the method further comprising:
when forming the stacked body,
forming a first stacked body including lower first and second insulating layers among the plurality of first and second insulating layers and having a first stepped portion in which the lower first insulating layer is processed into a stepped shape, and
forming the stacked body having the first stacked body and a second stacked body by forming the second stacked body including upper first and second insulating layers among the plurality of first and second insulating layers, being disposed above the first stacked body, and having a second stepped portion in which the upper first insulating layer is processed into a stepped shape;
when forming the first and second holes,
forming a plurality of the second holes dispersed in the first stepped portion, and
forming a fifth hole extending in the stacking direction in the second stepped portion, except for a region in which one or more first insulating layers including the uppermost first insulating layer are processed into a stepped shape;
when forming the third insulating layer within the first and second holes,
also forming the third insulating layer on a sidewall of the fifth hole, and
after forming the third insulating layer within the first, third, and fifth holes, continuing to form the third insulating layer within the second hole to form the third insulating layer within the second hole to be thicker than the third insulating layer within the first, third, and fifth holes;
when forming the fourth insulating layer within the first and second holes,
also forming the fourth insulating layer on the sidewall of the fifth hole while interposing the third insulating layer of the fifth hole therebetween;
when forming the fifth insulating layer within the first and second holes,
also forming the fifth insulating layer interposed between the third and fourth insulating layers in the fifth hole; and
when forming the semiconductor layer within the first and second holes,
also forming the semiconductor layer on the sidewall of the fifth hole while interposing the third to fifth insulating layers formed in the fifth hole therebetween.

17. The method for manufacturing the semiconductor storage device according to claim 15, the method further comprising:
when forming the stacked body,
forming a first stacked body including lower first and second insulating layers among the plurality of first and second insulating layers, the first stacked body having a first stepped portion in which the lower first insulating layer is processed into a stepped shape, and
forming the stacked body having the first stacked body and a second stacked body by forming the second stacked body including upper first and second insulating layers among the plurality of first and second insulating layers, being disposed above the first stacked body, and having a second stepped portion in which the upper first insulating layer is processed into a stepped shape;
when forming the second hole,
forming a first sub-hole extending in the stacking direction at a height position of the first stacked body, and
forming the second hole having the first sub-hole and a second sub-hole by forming the second sub-hole extending in the stacking direction at a height position of the second stacked body and being connected to an upper end of the first sub-hole at a lower end;
when forming the first sub-hole,
forming a sixth insulating layer covering a sidewall of the first sub-hole; and
when forming the third insulating layer within the first and second holes,
forming the third insulating layer within the first sub-hole while interposing the sixth insulating layer therebetween.
